(19) United States
(12) Patent Application Publication
(10) Pub. No.: US 2024/0136339 A1
(43) Pub. Date: Apr. 25, 2024

(54) MICRO-DISPLAY PANEL FOR NEAR-EYE DISPLAY

(71) Applicant: Meta Platforms Technologies, LLC, Menlo Park, CA (US)

(72) Inventors: Shenghui LEI, Castleknock (IE); Yong Tae MOON, Plymouth (GB); Ali SENGÜL, Zurich (CH)

(21) Appl. No.: 18/535,119

(22) Filed: Dec. 11, 2023

(51) Int. Cl. H01L 25/075; H01L 27/12; H01L 33/58

(52) U.S. Cl. CPC H01L 25/0753; H01L 27/124; H01L 33/58

(57) ABSTRACT

Disclosed herein are light sources (e.g., micro-LEDs and μOLEDs), display electronics, and tiled display panels for high luminance, high resolution display panels used in near-eye display systems. Techniques for three-dimensional integration of multi-color LEDs, micro-LED surface loss reduction using band engineered sidewall passivation structures, micro-LED heat spreading materials and structures, and micro-LED light extraction efficiency improvement using etched outwardly tilted sidewall minors are described. Techniques for drive circuit supply voltage tracking and compensation, dynamic burn-in compensation using interpolation of compensation parameters, and digital misalignment calibration of tiled display panels are also described.

### BACKGROUND

An artificial reality system, such as a head-mounted display (HMD) or heads-up display (HUD) system, generally includes a near-eye display (e.g., in the form of a headset or a pair of glasses) configured to present content to a user via an electronic or optic display within, for example, about 10 to 20 mm in front of the user's eyes. The near-eye display may display virtual objects or combine images of real objects with virtual objects, as in virtual reality (VR), augmented reality (AR), or mixed reality (MR) applications. For example, in an AR system, a user may view both images of virtual objects (e.g., computer-generated images (CGIs)), and the surrounding environment by, for example, seeing through transparent display glasses or lenses (often referred to as optical see-through) or viewing displayed images of the surrounding environment captured by a camera (often referred to as video see-through).

A near-eye display may include an optical system configured to form an image of a computer-generated image on an image plane. The optical system of the near-eye display may relay the image generated by an image source (e.g., a display panel) to create a virtual image that appears to be away from the image source and further than just a few centimeters away from the user's eyes. For example, the optical system may collimate the light from the image source or otherwise convert spatial information of the displayed virtual objects into angular information to create a virtual image that may appear to be far away. The optical system may also magnify the image source to make the image appear larger than the actual size of the image source. It is generally desirable that the near-eye display has a small size, a low weight, a large field of view, a large eye box, a high efficiency, and a low cost.

The image source of a near-eye display may include, for example, a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. Light emitting diodes (LEDs) convert electrical energy into optical energy, and offer many benefits over other light sources, such as reduced size, improved durability, and increased efficiency. LEDs can be used as light sources in many display systems, such as televisions, computer monitors, laptop computers, tablets, smartphones, projection systems, and wearable electronic devices. Micro-LEDs (“μLEDs”) based on III-V semiconductors, such as alloys of AN, GaN, InN, AlGaInP, other ternary and quaternary nitride, phosphide, and arsenide compositions, have begun to be developed for various display applications due to their small size (e.g., with a linear dimension less than 100 lam, less than 50 lam, less than 10 lam, or less than 5 μm), high packing density (and hence higher resolution), and high brightness. For example, micro-LEDs that emit light of different colors (e.g., red, green, and blue) can be used to form the sub-pixels of a display system, such as a television or a near-eye display system. For micro-LEDs with reduced physical dimensions, the quantum efficiencies and the light extraction efficiencies may be very low.

Improving the efficiencies of the micro-LEDs can be challenging.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 illustrates an example of an optical see-through augmented reality system including a waveguide display according to certain embodiments.

FIG. 5A illustrates an example of a near-eye display device including a waveguide display according to certain embodiments.

FIG. 5B illustrates an example of a near-eye display device including a waveguide display according to certain embodiments.

FIG. 6 illustrates an example of an image source assembly in an augmented reality system according to certain embodiments.

FIG. 7A illustrates an example of a light emitting diode (LED) having a vertical mesa structure according to certain embodiments.

FIG. 7B is a cross-sectional view of an example of an LED having a parabolic mesa structure according to certain embodiments.

FIGS. 8A-8D illustrate an example of a method of hybrid bonding for arrays of LEDs according to certain embodiments.

FIG. 9 illustrates an example of an LED array with secondary optical components fabricated thereon according to certain embodiments.

FIG. 10A illustrates an example of a method of die-to-wafer bonding for arrays of LEDs according to certain embodiments.

FIG. 10B illustrates an example of a method of wafer-to-wafer bonding for arrays of LEDs according to certain embodiments.

FIGS. 11A-11F illustrate an example of a method of fabricating a micro-LED device using alignment-free metal-to-metal bonding and post-bonding mesa formation.

FIGS. 12A-12E illustrate an example of a process of fabricating a micro-LED device according to certain embodiments.

FIG. 13A includes a top view and a cross-sectional view of an example of a display device that includes three LED dies bonded to a backplane according to a two-dimensional layout.

FIG. 13B includes a top view and a cross-sectional view of an example of a display device that includes three LED dies in a die stack on a backplane according to certain embodiments.

FIG. 14 includes a top view and a cross-sectional view of an example of a display device that includes three arrays of LEDs in a die stack on a backplane according to certain embodiments.

FIG. 15 is a cross-sectional view of an area of an example of a display device that includes an LED die stack on a backplane according to certain embodiments.

FIG. 16 is a cross-sectional view of another example of an area of a display device that includes an LED die stack on a backplane according to certain embodiments.

FIG. 17A illustrates an example of bonding two LED wafers by room temperature hybrid bonding and localized laser annealing according to certain embodiments.

FIG. 17B illustrates an example of bonding three LED wafers by room temperature hybrid bonding and localized laser annealing according to certain embodiments.

FIG. 18A illustrates an example of a micro-LED including a charge storage structure at the mesa sidewall according to certain embodiments.

FIG. 18B illustrates an example of injecting electrons into the charge storage structure of the micro-LED of FIG. 18A according to certain embodiments.

FIG. 19A illustrates an example of a micro-LED device including an array of micro-LEDs having charge storage structures at the mesa sidewalls according to certain embodiments.

FIG. 19B illustrates an example of a micro-LED in the micro-LED device of FIG. 19A.

FIG. 20 illustrates an example of a micro-LED device including an array of micro-lenses on an array of micro-LEDs.

FIG. 21A illustrates an example of a micro-LED device including a heat-spreading layer between an array of micro-lenses and an array of micro-LEDs according to certain embodiments device.

FIG. 21B illustrates an example of a micro-LED device including an array of micro-lenses made in a heat-spreading material layer on an array of micro-LEDs according to certain embodiments.

FIGS. 22A-22D illustrate an example of a process of fabricating an example of a micro-LED device including a heat-spreading layer between an array of micro-lenses and an array of micro-LEDs according to certain embodiments.

FIGS. 23A-23D illustrate an example of a process of fabricating an example of a micro-LED device including an array of micro-lenses made in a heat-spreading material layer on an array of micro-LEDs according to certain embodiments.

FIG. 24A illustrates an example of a wafer stack including individual mesa structures on a micro-LED wafer that is bonded to a backplane wafer.

FIG. 24B is a transmission electron microscopy (TEM) image of an example of a mesa structure formed by etching the semiconductor epitaxial layers of a micro-LED wafer as described above with respect to, for example, FIG. 24A.

FIG. 25A illustrates an example of a wafer stack including individual mesa structures on a micro-LED wafer that is bonded to a backplane wafer, where gaps between the individual mesa structures are filled with reflective material.

FIG. 25B is a TEM image of a region of a micro-LED wafer showing that the sidewall mirror for each mesa structure is inwardly tilted with respect to the mesa structure.

FIGS. 26A and 26B illustrate an example of a process of forming sidewall minors with outwardly tilted reflective surfaces along the light emitting direction of micro-LEDs according to certain embodiments.

FIG. 26C illustrates an example of a region of the wafer stack after depositing a transparent material into gaps between the remaining reflective material and mesa structures according to certain embodiments.

FIG. 26D illustrates another example of a region of the wafer stack after depositing a transparent material into gaps between the remaining reflective material and mesa structures according to certain embodiments.

FIG. 26E illustrates yet another example of a region of the wafer stack after depositing a transparent material into gaps between the remaining reflective material and mesa structures according to certain embodiments.

FIG. 27 includes a flowchart illustrating an example of a process for fabricating micro-LED sidewall reflectors according to certain embodiments disclosed herein.

FIG. 28A illustrates IR drop in an example of an OLED display.

FIG. 28B illustrates an example of a portion of an OLED display panel that includes demultiplexers (DMUXes) to reduce the number of pads.

FIG. 29A illustrates an example of an OLED display that includes circuits for tracking supply voltage drop.

FIG. 29B shows examples of supply voltage drop at different locations of an OLED display.

FIG. 30A includes a diagram illustrating an example of ELVDD tracking and

compensation in an example of a display panel that uses DMUXes.

FIG. 30B includes an image illustrating an example of the mura effect caused by improper ELVDD values used for reference voltage and/or signal voltage compensation.

FIG. 31 includes a diagram illustrating an example of ELVDD tracking and compensation in an OLED display according to certain embodiments.

FIG. 32 includes an example of a timing diagram illustrating an example of sensing ELVDD once in each horizontal line time period using a sensing clock signal that is synchronized with the horizontal line timing according to certain embodiments.

FIGS. 33A-33D illustrate examples of sensing ELVDD at different time instants in each horizontal line time period according to certain embodiments.

FIG. 34A is a cross-sectional view of an example of a tiled display panel according to certain embodiments.

FIG. 34B is a top view of an example of a tiled display panel according to certain embodiments.

FIG. 34C is a top view of an example of a tiled display panel according to certain embodiments.

FIG. 35 includes a flowchart illustrating an example of a method of digital misalignment compensation for a tiled display panel according to certain embodiments.

FIG. 36 is a block diagram of a display system usable for implementing one or more embodiments.

FIG. 37 is a block diagram of a display system, according to certain embodiments.

FIG. 38 shows an example of output images produced with and without compensation.

FIG. 39A shows example luminance curves illustrating differences in the relative brightness of pixels that are subjected to higher stress compared to pixels that are subjected to lower stress.

FIG. 39B shows example luminance curves for a group of pixels over the course of several compensation operations.

FIG. 40A shows example gamma curves representing brightness as a function of the input value to a pixel.

FIG. 40B shows an example of gamma curve rescaling.

FIG. 41 shows an example of artifacts that may be produced as a result of compensation using block-averaging.

FIG. 42 shows example luminance curves for a group of pixels over the course of several compensation operations.

FIG. 43 shows an example of compensation parameter interpolation, according to certain embodiments.

FIG. 44 shows examples of different compensation window configurations, according to certain embodiments.

FIGS. 45A and 45B show an example of block-based interpolation, according to certain embodiments.

FIG. 46 is a flow diagram of a process for determining block-based compensation parameters, according to certain embodiments.

FIG. 47 is a flow diagram of a process for burn-in compensation through interpolation of block-based compensation parameters, according to certain embodiments.

FIG. 48 is a simplified block diagram of an electronic system of an example of a near-eye display according to certain embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to display panels for near-eye display. More specifically, and without limitation, techniques disclosed herein relate to light sources (e.g., micro-LEDs and μOLEDs), display electronics, and tiled display panels for near-eye display. Various inventive embodiments are described herein, including devices, systems, methods, structures, materials, processes, and the like.

Augmented reality (AR) and virtual reality (VR) applications may use near-eye displays that include display panels having tiny monochrome light emitters, such as micro-LEDs or μOLEDs. In light emitting diodes (LEDs), photons may be generated through the recombination of electrons and holes within an active region (e.g., including one or more semiconductor layers that may form one or more quantum wells). The proportion of the carriers (e.g., electrons or holes) injected into the active region of an LED among the carriers that pass through the LED is referred to as the carrier injection efficiency. The ratio between the number of emitted photons and the number of carriers injected into the active region is referred to as the internal quantum efficiency (IQE) of the LED. Light emitted in the active region may be extracted from the LED at a certain light extraction efficiency (LEE). The ratio between the number of emitted photons extracted from the LED and the number of electrons passing through the LED is referred to as the external quantum efficiency (EQE) of the LED, which describes how efficiently the LED converts injected carriers into photons that are extracted from the LED. The EQE may be a product of the carrier injection efficiency, the IQE, and the LEE. In LEDs for near-eye displays, only light that is emitted into certain directions and/or within a certain emission angle range (e.g., within about ±18.5°) may be collected by the display optics of the near-eye displays. The proportion of the emitted photons that are extracted from the LED and are collected by the display optics may be referred to herein as the collected LEE.

Display electronics may be needed in display panels to control the light sources to emit light of the desired color and intensity.

The micro-LEDs and display electronics described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using an LED-based display subsystem.

As used herein, the term “light emitting diode (LED)” refers to a light source that includes at least an n-type semiconductor layer, a p-type semiconductor layer, and a light-emitting region (i.e., active region) between the n-type semiconductor layer and the p-type semiconductor layer. The light-emitting region may include one or more semiconductor layers that form one or more heterostructures, such as quantum wells. In some embodiments, the light-emitting region may include multiple semiconductor layers that form one or more multiple-quantum-wells (MQWs), each including multiple (e.g., about 2 to 8) quantum wells.

As used herein, the term “micro-LED” or “μLED” refers to an LED that has a chip where a lateral linear dimension (e.g., the diameter or a side) of the active region of the chip is less than about 200 lam, such as less than 100 lam, less than 50 lam, less than 20 lam, less than 10 lam, or smaller. For example, the linear dimension of a micro-LED may be as small as 6 μm, 5 μm, 4 μm, 2 μm, or smaller. Some micro-LEDs may have active regions (e.g., mesas) with a linear dimension (e.g., length or diameter) comparable to the minority carrier diffusion length. However, the disclosure herein is not limited to micro-LEDs, and may also be applied to mini-LEDs. As used herein, the lateral linear size of a micro-LED may refer to the lateral linear dimension of the active region or the mesa structure of the micro-LED, such as the diameter or side of the mesa structure or the active region.

As used herein, the term “bonding” may refer to various methods for physically and/or electrically connecting two or more devices and/or wafers, such as adhesive bonding, metal-to-metal bonding, metal oxide bonding, wafer-to-wafer bonding, die-to-wafer bonding, hybrid bonding, soldering, under-bump metallization, and the like. For example, adhesive bonding may use a curable adhesive (e.g., an epoxy) to physically bond two or more devices and/or wafers through adhesion. Metal-to-metal bonding may include, for example, wire bonding or flip chip bonding using soldering interfaces (e.g., pads or balls), conductive adhesive, or welded joints between metals. Metal oxide bonding may form a metal and oxide pattern on each surface, bond the oxide sections together, and then bond the metal sections together to create a conductive path. Wafer-to-wafer bonding may bond two wafers (e.g., silicon wafers or other semiconductor wafers) without any intermediate layers and is based on chemical bonds between the surfaces of the two wafers. Wafer-to-wafer bonding may include wafer cleaning and other preprocessing, aligning and pre-bonding at room temperature, and annealing at elevated temperatures, such as about 250° C. or higher. Die-to-wafer bonding may use bumps on one wafer to align features of a pre-formed chip with drivers of a wafer. Hybrid bonding may include, for example, wafer cleaning, high-precision alignment of contacts of one wafer with contacts of another wafer, dielectric bonding of dielectric materials within the wafers at room temperature, and metal bonding of the contacts by annealing at, for example, 250-300° C. or higher. As used herein, the term “bump” may refer generically to a metal interconnect used or formed during bonding.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

### I. Near-Eye Display

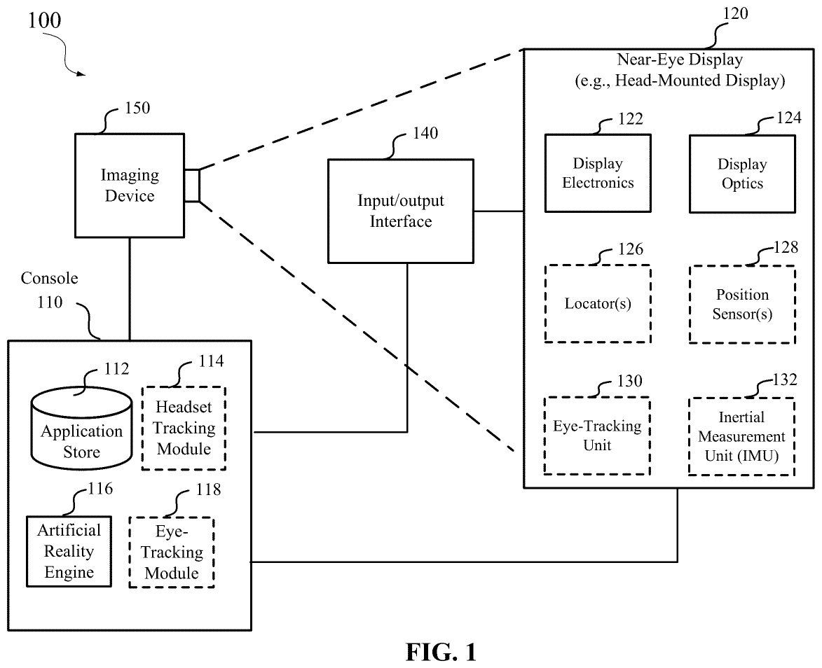

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

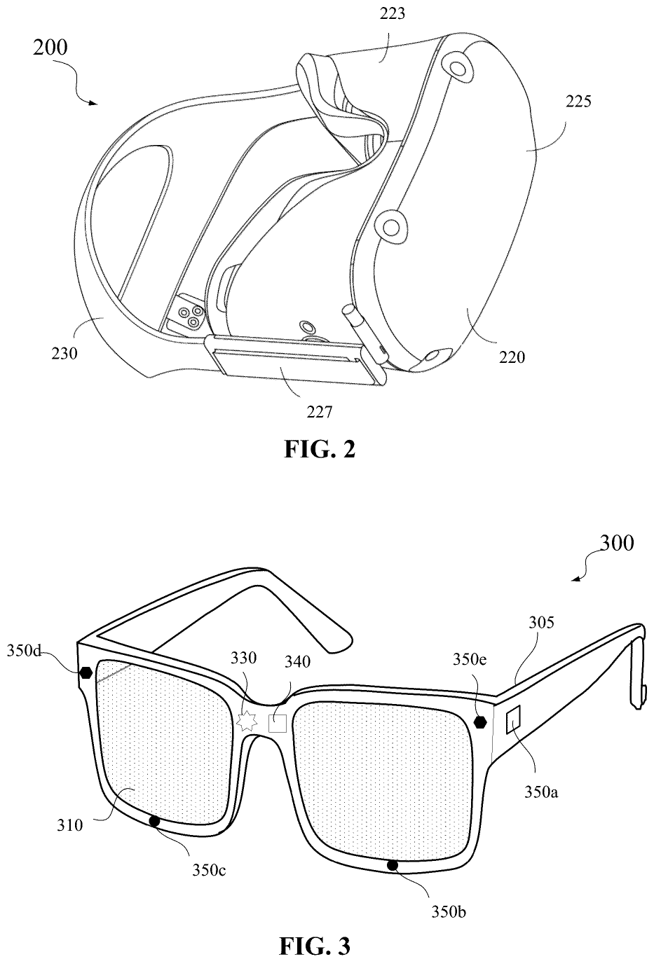

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an antireflective coating, a reflective coating, a filtering coating, or a combination of different optical coatings.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be an LED, a corner cube reflector, a reflective marker, a type of light source that contrasts with an environment in which near-eye display 120 operates, or any combination thereof. In embodiments where locators 126 are active components (e.g., LEDs or other types of light emitting devices).

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120.

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. Artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to determine the eye's orientation more accurately.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

### II. Waveguide Display

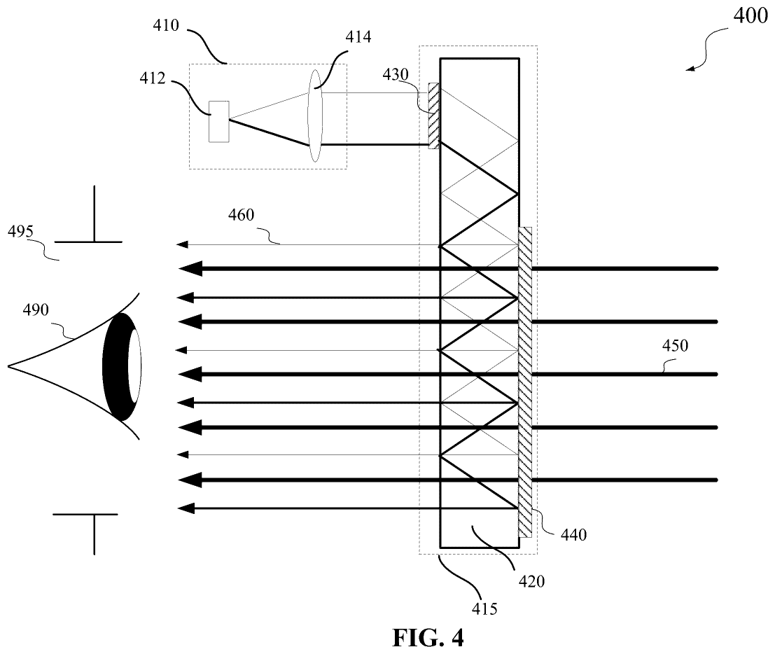

FIG. 4 illustrates an example of an optical see-through augmented reality system 400 including a waveguide display according to certain embodiments. Augmented reality system 400 may include a projector 410 and a combiner 415. Projector 410 may include a light source or image source 412 and projector optics 414. In some embodiments, light source or image source 412 may include one or more micro-LED devices described above. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, an LED, and/or a micro-LED described above. In some embodiments, image source 412 may include a plurality of light sources (e.g., an array of micro-LEDs described above), each emitting a monochromatic image light corresponding to a primary color (e.g., red, green, or blue). In some embodiments, image source 412 may include three two-dimensional arrays of micro-LEDs, where each two-dimensional array of micro-LEDs may include micro-LEDs configured to emit light of a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, minors, apertures, and/or gratings. For example, in some embodiments, image source 412 may include one or more one-dimensional arrays or elongated two-dimensional arrays of micro-LEDs, and projector optics 414 may include one or more one-dimensional scanners (e.g., micro-mirrors or prisms) configured to scan the one-dimensional arrays or elongated two-dimensional arrays of micro-LEDs to generate image frames. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Input coupler 430 may include a volume holographic grating, a diffractive optical element (DOE) (e.g., a surface-relief grating), a slanted surface of substrate 420, or a refractive coupler (e.g., a wedge or a prism). For example, input coupler 430 may include a reflective volume Bragg grating or a transmissive volume Bragg grating. Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440, each configured to extract at least a portion of the light guided by and propagating within substrate 420 from substrate 420, and direct extracted light 460 to an eyebox 495 where an eye 490 of the user of augmented reality system 400 may be located when augmented reality system 400 is in use. The plurality of output couplers 440 may replicate the exit pupil to increase the size of eyebox 495 such that the displayed image is visible in a larger area. As input coupler 430, output couplers 440 may include grating couplers (e.g., volume holographic gratings or surface-relief gratings), other diffraction optical elements (DOEs), prisms, etc. For example, output couplers 440 may include reflective volume Bragg gratings or transmissive volume Bragg gratings. Output couplers 440 may have different coupling (e.g., diffraction) efficiencies at different locations. Substrate 420 may also allow light 450 from the environment in front of combiner 415 to pass through with little or no loss. Output couplers 440 may also allow light 450 to pass through with little loss. For example, in some implementations, output couplers 440 may have a very low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 in certain desired directions (i.e., diffraction angles) with little loss. As a result, the user may be able to view combined images of the environment in front of combiner 415 and images of virtual objects projected by projector 410.

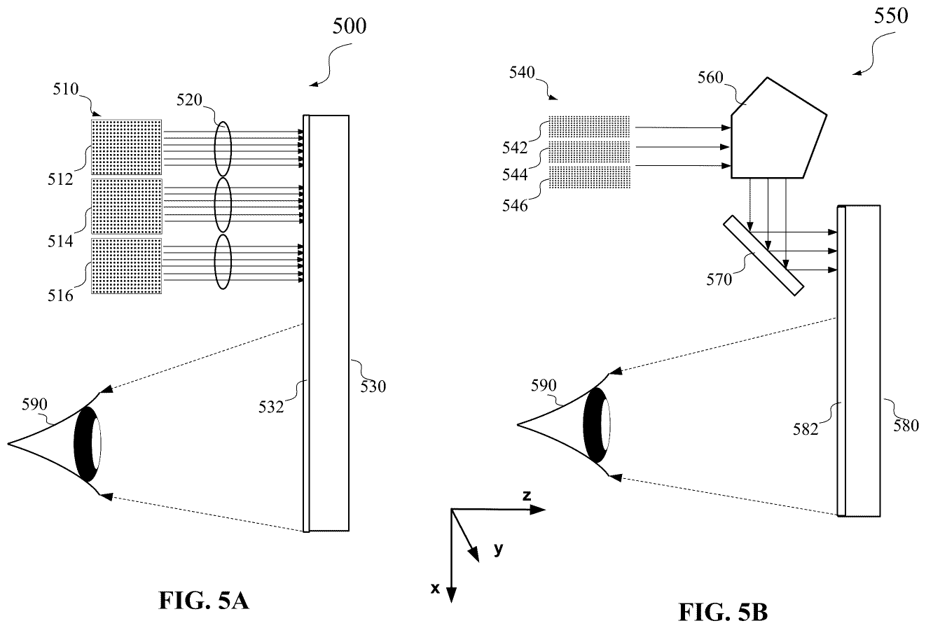

FIG. 5A illustrates an example of a near-eye display (NED) device 500 including a waveguide display 530 according to certain embodiments. NED device 500 may be an example of near-eye display 120, augmented reality system 400, or another type of display device. NED device 500 may include a light source 510, projection optics 520, and waveguide display 530. Light source 510 may include multiple panels of light emitters for different colors, such as a panel of red light emitters 512, a panel of green light emitters 514, and a panel of blue light emitters 516. The red light emitters 512 are organized into an array; the green light emitters 514 are organized into an array; and the blue light emitters 516 are organized into an array. The dimensions and pitches of light emitters in light source 510 may be small. For example, each light emitter may have a diameter less than 2 μm (e.g., about 1.2 μm) and the pitch may be less than 2 μm (e.g., about 1.5 μm). As such, the number of light emitters in each red light emitters 512, green light emitters 514, and blue light emitters 516 can be equal to or greater than the number of pixels in a display image, such as 960×720, 1280×720, 1440×1080, 1920×1080, 2160×1080, or 2560×1080 pixels. Thus, a display image may be generated simultaneously by light source 510. A scanning element may not be used in NED device 500.

Before reaching waveguide display 530, the light emitted by light source 510 may be conditioned by projection optics 520, which may include a lens array. Projection optics 520 may collimate or focus the light emitted by light source 510 to waveguide display 530, which may include a coupler 532 for coupling the light emitted by light source 510 into waveguide display 530. The light coupled into waveguide display 530 may propagate within waveguide display 530 through, for example, total internal reflection as described above with respect to FIG. 4. Coupler 532 may also couple portions of the light propagating within waveguide display 530 out of waveguide display 530 and towards user's eye 590.

FIG. 5B illustrates an example of a near-eye display (NED) device 550 including a waveguide display 580 according to certain embodiments. In some embodiments, NED device 550 may use a scanning mirror 570 to project light from a light source 540 to an image field where a user's eye 590 may be located. NED device 550 may be an example of near-eye display 120, augmented reality system 400, or another type of display device. Light source 540 may include one or more rows or one or more columns of light emitters of different colors, such as multiple rows of red light emitters 542, multiple rows of green light emitters 544, and multiple rows of blue light emitters 546. For example, red light emitters 542, green light emitters 544, and blue light emitters 546 may each include N rows, each row including, for example, 2560 light emitters (pixels). The red light emitters 542 are organized into an array; the green light emitters 544 are organized into an array; and the blue light emitters 546 are organized into an array. In some embodiments, light source 540 may include a single line of light emitters for each color. In some embodiments, light source 540 may include multiple columns of light emitters for each of red, green, and blue colors, where each column may include, for example, 1080 light emitters. In some embodiments, the dimensions and/or pitches of the light emitters in light source 540 may be relatively large (e.g., about 3-5 μm) and thus light source 540 may not include sufficient light emitters for simultaneously generating a full display image. For example, the number of light emitters for a single color may be fewer than the number of pixels (e.g., 2560×1080 pixels) in a display image. The light emitted by light source 540 may be a set of collimated or diverging beams of light.

Before reaching scanning mirror 570, the light emitted by light source 540 may be conditioned by various optical devices, such as collimating lenses or a freeform optical element 560. Freeform optical element 560 may include, for example, a multi-facet prism or another light folding element that may direct the light emitted by light source 540 towards scanning minor 570, such as changing the propagation direction of the light emitted by light source 540 by, for example, about 90° or larger. In some embodiments, freeform optical element 560 may be rotatable to scan the light. Scanning mirror 570 and/or freeform optical element 560 may reflect and project the light emitted by light source 540 to waveguide display 580, which may include a coupler 582 for coupling the light emitted by light source 540 into waveguide display 580. The light coupled into waveguide display 580 may propagate within waveguide display 580 through, for example, total internal reflection as described above with respect to FIG. 4. Coupler 582 may also couple portions of the light propagating within waveguide display 580 out of waveguide display 580 and towards user's eye 590.

Scanning mirror 570 may include a microelectromechanical system (MEMS) mirror or any other suitable mirrors. Scanning mirror 570 may rotate to scan in one or two dimensions. As scanning mirror 570 rotates, the light emitted by light source 540 may be directed to a different area of waveguide display 580 such that a full display image may be projected onto waveguide display 580 and directed to user's eye 590 by waveguide display 580 in each scanning cycle. For example, in embodiments where light source 540 includes light emitters for all pixels in one or more rows or columns, scanning minor 570 may be rotated in the column or row direction (e.g., x or y direction) to scan an image. In embodiments where light source 540 includes light emitters for some but not all pixels in one or more rows or columns, scanning mirror 570 may be rotated in both the row and column directions (e.g., both x and y directions) to project a display image (e.g., using a raster-type scanning pattern).

NED device 550 may operate in predefined display periods. A display period (e.g., display cycle) may refer to a duration of time in which a full image is scanned or projected. For example, a display period may be a reciprocal of the desired frame rate. In NED device 550 that includes scanning mirror 570, the display period may also be referred to as a scanning period or scanning cycle. The light generation by light source 540 may be synchronized with the rotation of scanning mirror 570. For example, each scanning cycle may include multiple scanning steps, where light source 540 may generate a different light pattern in each respective scanning step.

In each scanning cycle, as scanning minor 570 rotates, a display image may be projected onto waveguide display 580 and user's eye 590. The actual color value and light intensity (e.g., brightness) of a given pixel location of the display image may be an average of the light beams of the three colors (e.g., red, green, and blue) illuminating the pixel location during the scanning period. After completing a scanning period, scanning mirror 570 may revert back to the initial position to project light for the first few rows of the next display image or may rotate in a reverse direction or scan pattern to project light for the next display image, where a new set of driving signals may be fed to light source 540. The same process may be repeated as scanning mirror 570 rotates in each scanning cycle. As such, different images may be projected to user's eye 590 in different scanning cycles.

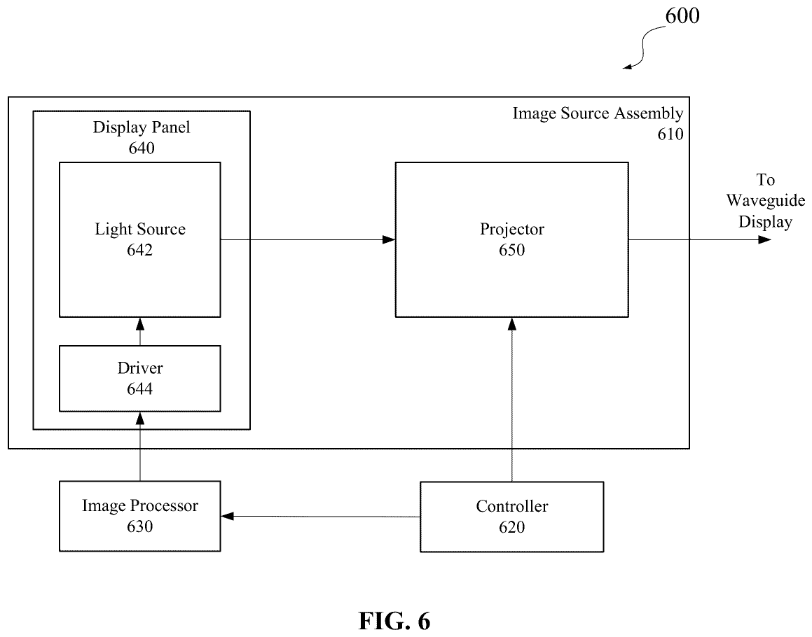

FIG. 6 illustrates an example of an image source assembly 610 in a near-eye display system 600 according to certain embodiments. Image source assembly 610 may include, for example, a display panel 640 that may generate display images to be projected to the user's eyes, and a projector 650 that may project the display images generated by display panel 640 to a waveguide display as described above with respect to FIGS. 4-5B. Display panel 640 may include a light source 642 and a drive circuit 644 for light source 642. Light source 642 may include, for example, light source 510 or 540. Projector 650 may include, for example, freeform optical element 560, scanning mirror 570, and/or projection optics 520 described above. Near-eye display system 600 may also include a controller 620 that synchronously controls light source 642 and projector 650 (e.g., scanning minor 570). Image source assembly 610 may generate and output an image light to a waveguide display (not shown in FIG. 6), such as waveguide display 530 or 580. As described above, the waveguide display may receive the image light at one or more input-coupling elements, and guide the received image light to one or more output-coupling elements. The input and output coupling elements may include, for example, a diffraction grating, a holographic grating, a prism, or any combination thereof. The input-coupling element may be chosen such that total internal reflection occurs with the waveguide display. The output-coupling element may couple portions of the total internally reflected image light out of the waveguide display.

As described above, light source 642 may include a plurality of light emitters arranged in an array or a matrix. Each light emitter may emit monochromatic light, such as red light, blue light, green light, infra-red light, and the like. While RGB colors are often discussed in this disclosure, embodiments described herein are not limited to using red, green, and blue as primary colors. Other colors can also be used as the primary colors of near-eye display system 600. In some embodiments, a display panel in accordance with an embodiment may use more than three primary colors. Each pixel in light source 642 may include three subpixels that include a red micro-LED, a green micro-LED, and a blue micro-LED. A semiconductor LED generally includes an active light emitting layer within multiple layers of semiconductor materials. The multiple layers of semiconductor materials may include different compound materials or a same base material with different dopants and/or different doping densities. For example, the multiple layers of semiconductor materials may include an n-type material layer, an active region that may include hetero-structures (e.g., one or more quantum wells), and a p-type material layer. The multiple layers of semiconductor materials may be grown on a surface of a substrate having a certain orientation.

Controller 620 may control the image rendering operations of image source assembly 610, such as the operations of light source 642 and/or projector 650. For example, controller 620 may determine instructions for image source assembly 610 to render one or more display images. The instructions may include display instructions and scanning instructions. In some embodiments, the display instructions may include an image file (e.g., a bitmap file). The display instructions may be received from, for example, a console, such as console 110 described above with respect to FIG. 1. The scanning instructions may be used by image source assembly 610 to generate image light. The scanning instructions may specify, for example, a type of a source of image light (e.g., monochromatic or polychromatic), a scanning rate, an orientation of a scanning apparatus, one or more illumination parameters, or any combination thereof. Controller 620 may include a combination of hardware, software, and/or firmware not shown here so as not to obscure other aspects of the present disclosure.

In some embodiments, controller 620 may be a graphics processing unit (GPU) of a display device. In other embodiments, controller 620 may be other kinds of processors. The operations performed by controller 620 may include taking content for display and dividing the content into discrete sections. Controller 620 may provide to light source 642 scanning instructions that include an address corresponding to an individual source element of light source 642 and/or an electrical bias applied to the individual source element. Controller 620 may instruct light source 642 to sequentially present the discrete sections using light emitters corresponding to one or more rows of pixels in an image ultimately displayed to the user. Controller 620 may also instruct projector 650 to perform different adjustments of the light. For example, controller 620 may control projector 650 to scan the discrete sections to different areas of a coupling element of the waveguide display (e.g., waveguide display 580) as described above with respect to FIG. 5B. As such, at the exit pupil of the waveguide display, each discrete portion is presented in a different respective location. While each discrete section is presented at a different respective time, the presentation and scanning of the discrete sections occur fast enough such that a user's eye may integrate the different sections into a single image or series of images.

Image processor 630 may be a general-purpose processor and/or one or more application-specific circuits that are dedicated to performing the features described herein. In one embodiment, a general-purpose processor may be coupled to a memory to execute software instructions that cause the processor to perform certain processes described herein. In another embodiment, image processor 630 may be one or more circuits that are dedicated to performing certain features. While image processor 630 in FIG. 6 is shown as a stand-alone unit that is separate from controller 620 and drive circuit 644, image processor 630 may be a sub-unit of controller 620 or drive circuit 644 in other embodiments. In other words, in those embodiments, controller 620 or drive circuit 644 may perform various image processing functions of image processor 630. Image processor 630 may also be referred to as an image processing circuit.

In the example shown in FIG. 6, light source 642 may be driven by drive circuit 644, based on data or instructions (e.g., display and scanning instructions) sent from controller 620 or image processor 630. In one embodiment, drive circuit 644 may include a circuit panel that connects to and mechanically holds various light emitters of light source 642. Light source 642 may emit light in accordance with one or more illumination parameters that are set by the controller 620 and potentially adjusted by image processor 630 and drive circuit 644. An illumination parameter may be used by light source 642 to generate light. An illumination parameter may include, for example, source wavelength, pulse rate, pulse amplitude, beam type (continuous or pulsed), other parameter(s) that may affect the emitted light, or any combination thereof. In some embodiments, the source light generated by light source 642 may include multiple beams of red light, green light, and blue light, or any combination thereof.

Projector 650 may perform a set of optical functions, such as focusing, combining, conditioning, or scanning the image light generated by light source 642. In some embodiments, projector 650 may include a combining assembly, a light conditioning assembly, or a scanning mirror assembly. Projector 650 may include one or more optical components that optically adjust and potentially re-direct the light from light source 642. One example of the adjustment of light may include conditioning the light, such as expanding, collimating, correcting for one or more optical errors (e.g., field curvature, chromatic aberration, etc.), some other adjustments of the light, or any combination thereof. The optical components of projector 650 may include, for example, lenses, minors, apertures, gratings, or any combination thereof.

Projector 650 may redirect image light via its one or more reflective and/or refractive portions so that the image light is projected at certain orientations toward the waveguide display. The location where the image light is redirected toward the waveguide display may depend on specific orientations of the one or more reflective and/or refractive portions. In some embodiments, projector 650 includes a single scanning minor that scans in at least two dimensions. In other embodiments, projector 650 may include a plurality of scanning minors that each scan in directions orthogonal to each other. Projector 650 may perform a raster scan (horizontally or vertically), a bi-resonant scan, or any combination thereof. In some embodiments, projector 650 may perform a controlled vibration along the horizontal and/or vertical directions with a specific frequency of oscillation to scan along two dimensions and generate a two-dimensional projected image of the media presented to user's eyes. In other embodiments, projector 650 may include a lens or prism that may serve similar or the same function as one or more scanning mirrors. In some embodiments, image source assembly 610 may not include a projector, where the light emitted by light source 642 may be directly incident on the waveguide display.

III. Micro-LED Structures and Fabrication

In semiconductor LEDs, photons are usually generated at a certain internal quantum efficiency through the recombination of electrons and holes within an active region (e.g., one or more semiconductor layers), where the internal quantum efficiency is the proportion of the radiative electron-hole recombination in the active region that emits photons. The generated light may then be extracted from the LEDs in a particular direction or within a particular solid angle. The ratio between the number of emitted photons extracted from an LED and the number of electrons passing through the LED is referred to as the external quantum efficiency, which describes how efficiently the LED converts injected electrons to photons that are extracted from the device. The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device. For LEDs, and in particular, micro-LEDs with reduced physical dimensions, improving the internal and external quantum efficiency and/or controlling the emission spectrum may be challenging.

The internal quantum efficiency of an LED may depend on the relative rates of competitive radiative (light producing) recombination and non-radiative (lossy) recombination that occur in the active region of the LED. Non-radiative recombination processes in the active region include Shockley-Read-Hall (SRH) recombination at defect sites, and electron-electron-hole (eeh) and/or electron-hole-hole (ehh) Auger recombination. The Auger recombination is a non-radiative process involving three carriers, which affects all sizes of LEDs. In micro-LEDs, because the lateral size of each micro-LED may be comparable to the minority carrier diffusion length, a larger proportion of the total active region may be within a minority carrier diffusion length from the LED sidewall surfaces where the defect density and the defect-induced non-radiative recombination rate may be high. Therefore, a larger proportion of the injected carriers may diffuse to the regions near the sidewall surfaces, where the carriers may be subjected to a higher SRH recombination rate. This may cause the efficiency of the LED to decrease (in particular, at low current injection), cause the peak efficiency of the LED to decrease, and/or cause the peak efficiency operating current to increase. Increasing the injected current may cause the efficiencies of the micro-LEDs to drop due to the higher eeh or ehh Auger recombination rate at a higher current density, and may also cause spectral shift of the emitted light. As the physical sizes of LEDs are further reduced, efficiency losses due to surface recombination near the etched sidewall facets that include surface imperfections may become much more significant. Techniques for improving the internal quantum efficiency and thus the external quantum efficiency of micro-LEDs, in particular, micro-LEDs with small sizes (e.g., with a width of the mesa structure less than about 10 μm, 5 μm, 4 μm, 2 μm, or smaller), may be desired.

At the light-emitting surface of an LED, such as the interface between the LED and air, some incident light with incident angles smaller than the critical angle for total internal reflection (TIR) may be refracted to exit the LED, but incident light with incident angles greater than the critical angle may be reflected back to the LED due to total internal reflection. Light incident on the back reflector and mesa sidewall reflectors may be specularly reflected. Some light may be reflected by the back reflector and mesa sidewall reflectors towards the light-emitting surface, but some light may be trapped in the LED due to the geometry of the mesa structure and the sidewall reflectors. Because of the specular reflection and the geometry of the LED mesa structure, there may be no light mixing within the LED, which may result in closed orbits for light within the LED. Light trapped in the micro-LED may eventually be absorbed by the LED. For example, some trapped light may be absorbed by the semiconductor materials to generate electron-hole pairs, which may recombine radiatively or non-radiatively. Some trapped light may be absorbed by metals (e.g., metal contacts or reflectors) at the bottom and/or sidewalls of the LED due to, for example, surface plasmon resonance that may be excited by p-polarized light at the interface between a metal layer and a dielectric layer (e.g., the passivation layer) or a semiconductor material layer. Therefore, techniques for improving the light extraction efficiency of the LED may also be desired.

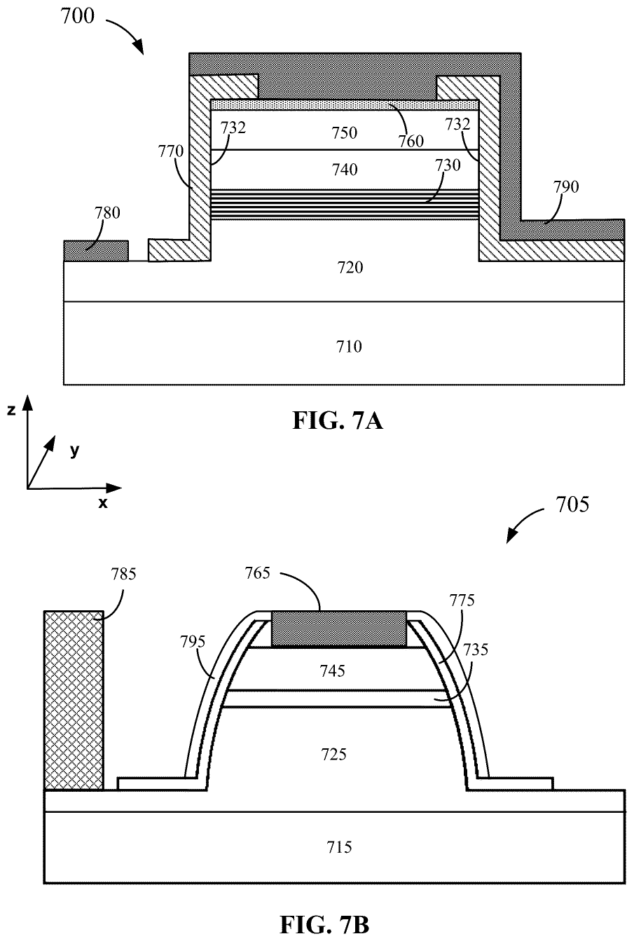

FIG. 7A illustrates an example of an LED 700 having a vertical mesa structure. LED 700 may be a light emitter in light source 510, 540, or 642. LED 700 may be a micro-LED made of inorganic materials, such as multiple layers of semiconductor materials. The layered semiconductor light emitting device may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb). When the Group V element of the III-V semiconductor material includes nitrogen, the III-V semiconductor material is referred to as a III-nitride material. The layered semiconductor light emitting device may be manufactured by growing multiple epitaxial layers on a substrate using techniques such as vapor-phase epitaxy (VPE), liquid-phase epitaxy (LPE), molecular beam epitaxy (MBE), or metalorganic chemical vapor deposition (MOCVD). For example, the layers of the semiconductor materials may be grown layer-by-layer on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane as the growth surface.

In the example shown in FIG. 7A, LED 700 may include a substrate 710, which may include, for example, a sapphire substrate or a GaN substrate. A semiconductor layer 720 may be grown on substrate 710. Semiconductor layer 720 may include a III-V material, such as GaN, and may be p-doped (e.g., with Mg, Ca, Zn, or Be) or n-doped (e.g., with Si or Ge). One or more active layers 730 may be grown on semiconductor layer 720 to form an active region. Active layer 730 may include III-V materials, such as one or more InGaN layers, one or more AlInGaP layers, and/or one or more GaN layers, which may form one or more heterostructures, such as one or more quantum wells or MQWs. A semiconductor layer 740 may be grown on active layer 730. Semiconductor layer 740 may include a III-V material, such as GaN, and may be p-doped (e.g., with Mg, Ca, Zn, or Be) or n-doped (e.g., with Si or Ge). One of semiconductor layer 720 and semiconductor layer 740 may be a p-type layer and the other one may be an n-type layer. Semiconductor layer 720 and semiconductor layer 740 sandwich active layer 730 to form the light emitting region. For example, LED 700 may include a layer of InGaN situated between a layer of p-type GaN doped with magnesium and a layer of n-type GaN doped with silicon or oxygen. In some embodiments, LED 700 may include a layer of AlInGaP situated between a layer of p-type AlInGaP doped with zinc or magnesium and a layer of n-type AlInGaP doped with selenium, silicon, or tellurium.

In some embodiments, an electron-blocking layer (EBL) (not shown in FIG. 7A) may be grown to form a layer between active layer 730 and at least one of semiconductor layer 720 or semiconductor layer 740. The EBL may reduce the electron leakage current and improve the efficiency of the LED. In some embodiments, a heavily-doped semiconductor layer 750, such as a P⁺ or P⁺⁺ semiconductor layer, may be formed on semiconductor layer 740 and act as a contact layer for forming an ohmic contact and reducing the contact impedance of the device. In some embodiments, a conductive layer 760 may be formed on heavily-doped semiconductor layer 750. Conductive layer 760 may include, for example, an indium tin oxide (ITO) or Al/Ni/Au film. In one example, conductive layer 760 may include a transparent ITO layer.

To make contact with semiconductor layer 720 (e.g., an n-GaN layer) and to more efficiently extract light emitted by active layer 730 from LED 700, the semiconductor material layers (including heavily-doped semiconductor layer 750, semiconductor layer 740, active layer 730, and semiconductor layer 720) may be etched to expose semiconductor layer 720 and to form a mesa structure that includes layers 720-760. The mesa structure may confine the carriers within the device. Etching the mesa structure may lead to the formation of mesa sidewalls 732 that may be orthogonal to the growth planes. A passivation layer 770 may be formed on mesa sidewalls 732 of the mesa structure. Passivation layer 770 may include an oxide layer, such as a SiO₂ layer, and may act as a reflector to reflect emitted light out of LED 700. A contact layer 780, which may include a metal layer, such as Al, Au, Ni, Ti, or any combination thereof, may be formed on semiconductor layer 720 and may act as an electrode of LED 700. In addition, another contact layer 790, such as an Al/Ni/Au metal layer, may be formed on conductive layer 760 and may act as another electrode of LED 700.

When a voltage signal is applied to contact layers 780 and 790, electrons and holes may recombine in active layer 730, where the recombination of electrons and holes may cause photon emission. The wavelength and energy of the emitted photons may depend on the energy bandgap between the valence band and the conduction band in active layer 730. For example, InGaN active layers may emit green or blue light, AlGaN active layers may emit blue to ultraviolet light, while AlInGaP active layers may emit red, orange, yellow, or green light. The emitted photons may be reflected by passivation layer 770 and may exit LED 700 from the top (e.g., conductive layer 760 and contact layer 790) or bottom (e.g., substrate 710).

In some embodiments, LED 700 may include one or more other components, such as a lens, on the light emission surface, such as substrate 710, to focus or collimate the emitted light or couple the emitted light into a waveguide. In some embodiments, an LED may include a mesa of another shape, such as planar, conical, semi-parabolic, or parabolic, and a base area of the mesa may be circular, rectangular, hexagonal, or triangular. For example, the LED may include a mesa of a curved shape (e.g., paraboloid shape) and/or a non-curved shape (e.g., conic shape). The mesa may be truncated or non-truncated.

FIG. 7B is a cross-sectional view of an example of an LED 705 having a parabolic mesa structure Similar to LED 700, LED 705 may include multiple layers of semiconductor materials, such as multiple layers of III-V semiconductor materials. The semiconductor material layers may be epitaxially grown on a substrate 715, such as a GaN substrate or a sapphire substrate. For example, a semiconductor layer 725 may be grown on substrate 715. Semiconductor layer 725 may include a III-V material, such as GaN, and may be p-doped (e.g., with Mg, Ca, Zn, or Be) or n-doped (e.g., with Si or Ge). One or more active layer 735 may be grown on semiconductor layer 725. Active layer 735 may include III-V materials, such as one or more InGaN layers, one or more AlInGaP layers, and/or one or more GaN layers, which may form one or more heterostructures, such as one or more quantum wells. A semiconductor layer 745 may be grown on active layer 735. Semiconductor layer 745 may include a III-V material, such as GaN, and may be p-doped (e.g., with Mg, Ca, Zn, or Be) or n-doped (e.g., with Si or Ge). One of semiconductor layer 725 and semiconductor layer 745 may be a p-type layer and the other one may be an n-type layer.

To make contact with semiconductor layer 725 (e.g., an n-type GaN layer) and to more efficiently extract light emitted by active layer 735 from LED 705, the semiconductor layers may be etched to expose semiconductor layer 725 and to form a mesa structure that includes layers 725-745. The mesa structure may confine carriers within the injection area of the device. Etching the mesa structure may lead to the formation of mesa side walls (also referred to herein as facets) that may be non-parallel with, or in some cases, orthogonal, to the growth planes associated with crystalline growth of layers 725-745.

As shown in FIG. 7B, LED 705 may have a mesa structure that includes a flat top. A dielectric layer 775 (e.g., SiO₂ or SiN) may be formed on the facets of the mesa structure. In some embodiments, dielectric layer 775 may include multiple layers of dielectric materials. In some embodiments, a metal layer 795 may be formed on dielectric layer 775. Metal layer 795 may include one or more metal or metal alloy materials, such as aluminum (Al), silver (Ag), gold (Au), platinum (Pt), titanium (Ti), copper (Cu), or any combination thereof. Dielectric layer 775 and metal layer 795 may form a mesa reflector that can reflect light emitted by active layer 735 toward substrate 715. In some embodiments, the mesa reflector may be parabolic-shaped to act as a parabolic reflector that may at least partially collimate the emitted light.

Electrical contact 765 and electrical contact 785 may be formed on semiconductor layer 745 and semiconductor layer 725, respectively, to act as electrodes. Electrical contact 765 and electrical contact 785 may each include a conductive material, such as Al, Au, Pt, Ag, Ni, Ti, Cu, or any combination thereof (e.g., Ag/Pt/Au or Al/Ni/Au), and may act as the electrodes of LED 705. In the example shown in FIG. 7B, electrical contact 785 may be an n-contact, and electrical contact 765 may be a p-contact. Electrical contact 765 and semiconductor layer 745 (e.g., a p-type semiconductor layer) may form a back reflector for reflecting light emitted by active layer 735 back toward substrate 715. In some embodiments, electrical contact 765 and metal layer 795 include same material(s) and can be formed using the same processes. In some embodiments, an additional conductive layer (not shown) may be included as an intermediate conductive layer between the electrical contacts 765 and 785 and the semiconductor layers.

When a voltage signal is applied across electrical contacts 765 and 785, electrons and holes may recombine in active layer 735. The recombination of electrons and holes may cause photon emission, thus producing light. The wavelength and energy of the emitted photons may depend on the energy bandgap between the valence band and the conduction band in active layer 735. For example, InGaN active layers may emit green or blue light, while AlInGaP active layers may emit red, orange, yellow, or green light. The emitted photons may propagate in many different directions, and may be reflected by the mesa reflector and/or the back reflector and may exit LED 705, for example, from the bottom side (e.g., substrate 715) shown in FIG. 7B. One or more other secondary optical components, such as a lens or a grating, may be formed on the light emission surface, such as substrate 715, to focus or collimate the emitted light and/or couple the emitted light into a waveguide.

One or two-dimensional arrays of the LEDs described above may be manufactured on a wafer to form light sources (e.g., light source 642). Drive circuits (e.g., drive circuit 644) may be fabricated, for example, on a silicon wafer using CMOS processes. The LEDs and the drive circuits on wafers may be diced and then bonded together, or may be bonded on the wafer level and then diced. Various bonding techniques can be used for bonding the LEDs and the drive circuits, such as adhesive bonding, metal-to-metal bonding, metal oxide bonding, wafer-to-wafer bonding, die-to-wafer bonding, hybrid bonding, and the like.

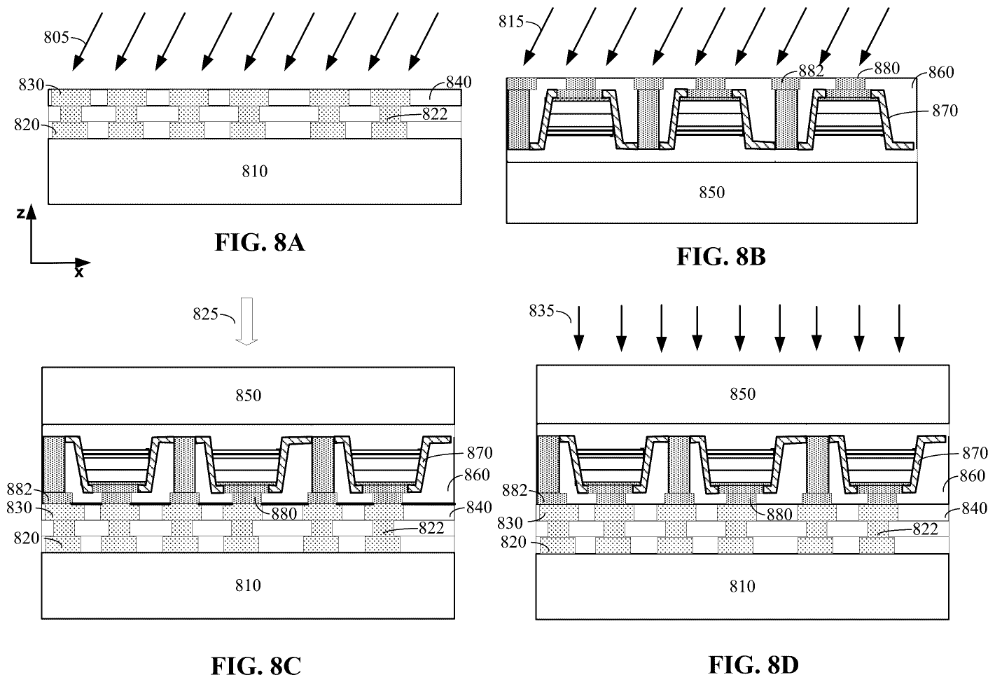

FIGS. 8A-8D illustrate an example of a method of hybrid bonding for arrays of LEDs according to certain embodiments. The hybrid bonding may generally include wafer cleaning and activation, high-precision alignment of contacts of one wafer with contacts of another wafer, dielectric bonding of dielectric materials at the surfaces of the wafers at room temperature, and metal bonding of the contacts by annealing at elevated temperatures. FIG. 8A shows a substrate 810 with passive or active circuits 820 manufactured thereon. As described above with respect to FIGS. 8A-8B, substrate 810 may include, for example, a silicon wafer. Circuits 820 may include drive circuits for the arrays of LEDs. A bonding layer may include dielectric regions 840 and contact pads 830 connected to circuits 820 through electrical interconnects 822. Contact pads 830 may include, for example, Cu, Ag, Au, Al, W, Mo, Ni, Ti, Pt, Pd, or the like. Dielectric materials in dielectric regions 840 may include SiCN, SiO₂, SiN, Al₂O₃, HfO₂, ZrO₂, Ta₂O₅, or the like. The bonding layer may be planarized and polished using, for example, chemical mechanical polishing, where the planarization or polishing may cause dishing (a bowl like profile) in the contact pads. The surfaces of the bonding layers may be cleaned and activated by, for example, an ion (e.g., plasma) or fast atom (e.g., Ar) beam 805. The activated surface may be atomically clean and may be reactive for formation of direct bonds between wafers when they are brought into contact, for example, at room temperature.

FIG. 8B illustrates a wafer 850 including an array of micro-LEDs 870 fabricated thereon as described above with respect to, for example, FIGS. 7A-8B. Wafer 850 may be a carrier wafer and may include, for example, GaAs, InP, GaN, AN, sapphire, SiC, Si, or the like. Micro-LEDs 870 may include an n-type layer, an active region, and a p-type layer epitaxially grown on wafer 850. The epitaxial layers may include various III-V semiconductor materials described above, and may be processed from the p-type layer side to etch mesa structures in the epitaxial layers, such as substantially vertical structures, parabolic structures, conic structures, or the like. Passivation layers and/or reflection layers may be formed on the sidewalls of the mesa structures. P-contacts 880 and n-contacts 882 may be formed in a dielectric material layer 860 deposited on the mesa structures and may make electrical contacts with the p-type layer and the n-type layers, respectively. Dielectric materials in dielectric material layer 860 may include, for example, SiCN, SiO₂, SiN, Al₂O₃, HfO₂, ZrO₂, Ta₂O₅, or the like. P-contacts 880 and n-contacts 882 may include, for example, Cu, Ag, Au, Al, W, Mo, Ni, Ti, Pt, Pd, or the like. The top surfaces of p-contacts 880, n-contacts 882, and dielectric material layer 860 may form a bonding layer. The bonding layer may be planarized and polished using, for example, chemical mechanical polishing, where the polishing may cause dishing in p-contacts 880 and n-contacts 882. The bonding layer may then be cleaned and activated by, for example, an ion (e.g., plasma) or fast atom (e.g., Ar) beam 815. The activated surface may be atomically clean and reactive for formation of direct bonds between wafers when they are brought into contact, for example, at room temperature.

FIG. 8C illustrates a room temperature bonding process for bonding the dielectric materials in the bonding layers. For example, after the bonding layer that includes dielectric regions 840 and contact pads 830 and the bonding layer that includes p-contacts 880, n-contacts 882, and dielectric material layer 860 are surface activated, wafer 850 and micro-LEDs 870 may be turned upside down and brought into contact with substrate 810 and the circuits formed thereon. In some embodiments, compression pressure 825 may be applied to substrate 810 and wafer 850 such that the bonding layers are pressed against each other. Due to the surface activation and the dishing in the contacts, dielectric regions 840 and dielectric material layer 860 may be in direct contact because of the surface attractive force, and may react and form chemical bonds between them because the surface atoms may have dangling bonds and may be in unstable energy states after the activation. Thus, the dielectric materials in dielectric regions 840 and dielectric material layer 860 may be bonded together with or without heat treatment or pressure.

FIG. 8D illustrates an annealing process for bonding the contacts in the bonding layers after bonding the dielectric materials in the bonding layers. For example, contact pads 830 and p-contacts 880 or n-contacts 882 may be bonded together by annealing at, for example, about 200-400° C. or higher. During the annealing process, heat 835 may cause the contacts to expand more than the dielectric materials (due to different coefficients of thermal expansion), and thus may close the dishing gaps between the contacts such that contact pads 830 and p-contacts 880 or n-contacts 882 may be in contact and may form direct metallic bonds at the activated surfaces.

In some embodiments where the two bonded wafers include materials having different coefficients of thermal expansion (CTEs), the dielectric materials bonded at room temperature may help to reduce or prevent misalignment of the contact pads caused by the different thermal expansions. In some embodiments, to further reduce or avoid the misalignment of the contact pads at a high temperature during annealing, trenches may be formed between micro-LEDs, between groups of micro-LEDs, through part or all of the substrate, or the like, before bonding.

After the micro-LEDs are bonded to the drive circuits, the substrate on which the micro-LEDs are fabricated may be thinned or removed, and various secondary optical components may be fabricated on the light emitting surfaces of the micro-LEDs to, for example, extract, collimate, and redirect the light emitted from the active regions of the micro-LEDs. In one example, micro-lenses may be formed on the micro-LEDs, where each micro-lens may correspond to a respective micro-LED and may help to improve the light extraction efficiency and collimate the light emitted by the micro-LED. In some embodiments, the secondary optical components may be fabricated in the substrate or the n-type layer of the micro-LEDs. In some embodiments, the secondary optical components may be fabricated in a dielectric layer deposited on the n-type side of the micro-LEDs. Examples of the secondary optical components may include a lens, a grating, an antireflection (AR) coating, a prism, a photonic crystal, or the like.

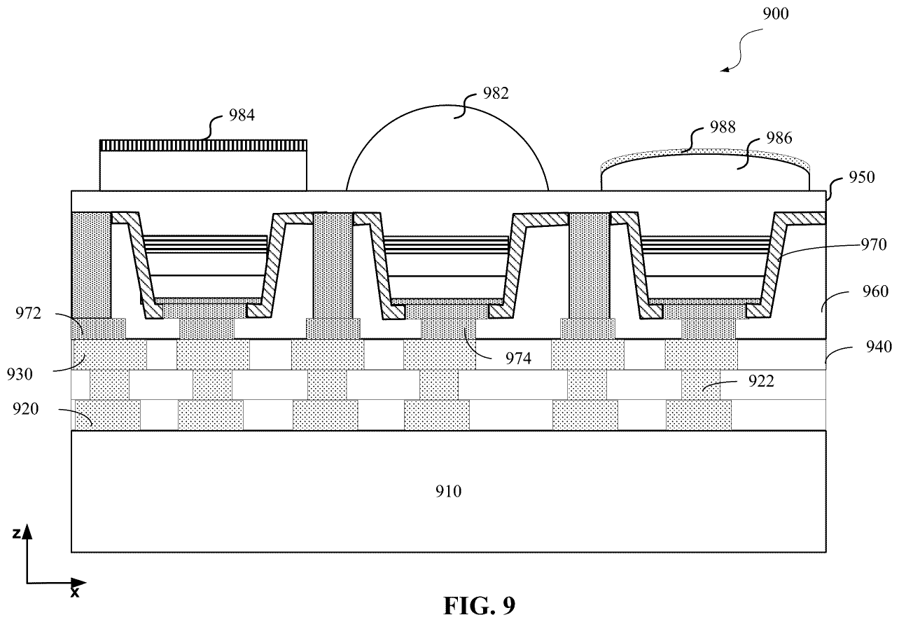

FIG. 9 illustrates an example of an LED array 900 with secondary optical components fabricated thereon according to certain embodiments. LED array 900 may be made by bonding an LED chip or wafer with a silicon wafer including electrical circuits fabricated thereon, using any suitable bonding techniques described above with respect to, for example, FIGS. 8A-8D. In the example shown in FIG. 9, LED array 900 may be bonded using a wafer-to-wafer hybrid bonding technique as described above with respect to FIG. 8A-8D. LED array 900 may include a substrate 910, which may be, for example, a silicon wafer. Integrated circuits 920, such as LED drive circuits, may be fabricated on substrate 910. Integrated circuits 920 may be connected to p-contacts 974 and n-contacts 972 of micro-LEDs 970 through interconnects 922 and contact pads 930, where contact pads 930 may form metallic bonds with p-contacts 974 and n-contacts 972. Dielectric layer 940 on substrate 910 may be bonded to dielectric layer 960 through fusion bonding.

The substrate (not shown) of the LED chip or wafer may be thinned or may be removed to expose the n-type layer 950 of micro-LEDs 970. Various secondary optical components, such as a spherical micro-lens 982, a grating 984, a micro-lens 986, an antireflection layer 988, and the like, may be formed in or on top of n-type layer 950. For example, spherical micro-lens arrays may be etched in the semiconductor materials of micro-LEDs 970 using a gray-scale mask and a photoresist with a linear response to exposure light, or using an etch mask formed by thermal reflowing of a patterned photoresist layer. The secondary optical components may also be etched in a dielectric layer deposited on n-type layer 950 using similar photolithographic techniques or other techniques. For example, micro-lens arrays may be formed in a polymer layer through thermal reflowing of the polymer layer that is patterned using a binary mask. The micro-lens arrays in the polymer layer may be used as the secondary optical components or may be used as the etch mask for transferring the profiles of the micro-lens arrays into a dielectric layer or a semiconductor layer. The dielectric layer may include, for example, SiCN, SiO₂, SiN, Al₂O₃, HfO₂, ZrO₂, Ta₂O₅, or the like. In some embodiments, a micro-LED 970 may have multiple corresponding secondary optical components, such as a micro-lens and an antireflection coating, a micro-lens etched in the semiconductor material and a micro-lens etched in a dielectric material layer, a micro-lens and a grating, a spherical lens and an aspherical lens, and the like. Three different secondary optical components are illustrated in FIG. 9 to show some examples of secondary optical components that can be formed on micro-LEDs 970, which does not necessary imply that different secondary optical components are used simultaneously for every LED array.

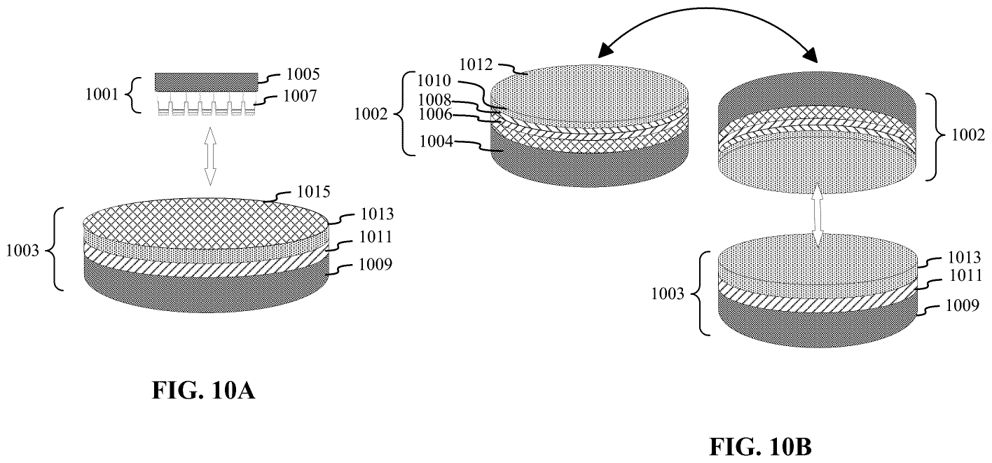

FIG. 10A illustrates an example of a method of die-to-wafer bonding for arrays of LEDs according to certain embodiments. In the example shown in FIG. 10A, an LED array 1001 may include a plurality of LEDs 1007 on a carrier substrate 1005. Carrier substrate 1005 may include various materials, such as GaAs, InP, GaN, AN, sapphire, SiC, Si, or the like. LEDs 1007 may be fabricated by, for example, growing various epitaxial layers, forming mesa structures, and forming electrical contacts or electrodes, before performing the bonding. The epitaxial layers may include various materials, such as GaN, InGaN, (AlGaIn)P, (AlGaIn)AsP, (AlGaIn)AsN, (Eu:InGa)N, (AlGaIn)N, or the like, and may include an n-type layer, a p-type layer, and an active layer that includes one or more heterostructures, such as one or more quantum wells or MQWs. The electrical contacts may include various conductive materials, such as a metal or a metal alloy.

A wafer 1003 may include a base layer 1009 having passive or active integrated circuits (e.g., drive circuits 1011) fabricated thereon. Base layer 1009 may include, for example, a silicon wafer. Drive circuits 1011 may be used to control the operations of LEDs 1007. For example, the drive circuit for each LED 1007 may include a 2T1C pixel structure that has two transistors and one capacitor. Wafer 1003 may also include a bonding layer 1013. Bonding layer 1013 may include various materials, such as a metal, an oxide, a dielectric, CuSn, AuTi, and the like. In some embodiments, a patterned layer 1015 may be formed on a surface of bonding layer 1013, where patterned layer 1015 may include a metallic grid made of a conductive material, such as Cu, Ag, Au, Al, or the like.

LED array 1001 may be bonded to wafer 1003 via bonding layer 1013 or patterned layer 1015. For example, patterned layer 1015 may include metal pads or bumps made of various materials, such as CuSn, AuSn, or nanoporous Au. The metal pads or bumps may be used to align LEDs 1007 of LED array 1001 with corresponding drive circuits 1011 on wafer 1003. In one example, LED array 1001 may be brought toward wafer 1003 until LEDs 1007 come into contact with respective metal pads or bumps corresponding to drive circuits 1011. Some or all of LEDs 1007 may be aligned with drive circuits 1011, and may then be bonded to wafer 1003 via patterned layer 1015 by various bonding techniques, such as metal-to-metal bonding. After LEDs 1007 have been bonded to wafer 1003, carrier substrate 1005 may be removed from LEDs 1007.

For high-resolution micro-LED display panel, due to the small pitches of the micro-LED array and the small dimensions of individual micro-LEDs, it can be challenging to electrically connect the drive circuits to the electrodes of the LEDs. For example, in the face-to-face bonding techniques describe above, it is difficult to precisely align the bonding pads on the micro-LED devices with the bonding pads on the drive circuits and form reliable bonding at the interfaces that may include both dielectric materials (e.g., SiO₂, SiN, or SiCN) and metal (e.g., Cu, Au, or Al) bonding pads. In particular, when the pitch of the micro-LED device is about 2 or 3 microns or lower, the bonding pads may have a linear dimension less than about 1 μm in order to avoid shorting to adjacent micro-LEDs and to improve bonding strength for the dielectric bonding. However, small bonding pads may be less tolerant to misalignments between the bonding pads, which may reduce the metal bonding area, increase the contact resistance (or may even be an open circuit), and/or cause diffusion of metals to the dielectric materials and the semiconductor materials. Thus, precise alignment of the bonding pads on surfaces of the micro-LED arrays and bonding pads on surfaces of CMOS backplane may be needed in the conventional processes. However, the accuracy of die-to-wafer or wafer-to-wafer bonding alignment using state-of-art equipment may be on the order of about 0.5 μm or about 1 μm, which may not be adequate for bonding the small-pitch micro-LED arrays (e.g., with a linear dimension of the bonding pads on the order of 1 μm or shorter) to CMOS drive circuits.

In some implementations, to avoid precise alignment for the bonding, a micro-LED wafer may be bonded to a CMOS backplane after the epitaxial layer growth and before the formation of individual micro-LED on the micro-LED wafer, where the micro-LED wafer and the CMOS backplane may be bonded through metal-to-metal bonding of two solid metal bonding layers on the two wafers. No alignment would be needed to bond the solid contiguous metal bonding layers. After the bonding, the epitaxial layers on the micro-LED wafer and the metal bonding layers may be etched to form individual micro-LEDs. The etching process may have much higher alignment accuracy and thus may form individual micro-LEDs that align with the underlying pixel drive circuits.

FIG. 10B illustrates an example of a method of wafer-to-wafer bonding for arrays of LEDs according to certain embodiments. As shown in FIG. 10B, a first wafer 1002 may include a substrate 1004, a first semiconductor layer 1006, active layers 1008, and a second semiconductor layer 1010. Substrate 1004 may include various materials, such as GaAs, InP, GaN, AlN, sapphire, SiC, Si, or the like. First semiconductor layer 1006, active layers 1008, and second semiconductor layer 1010 may include various semiconductor materials, such as GaN, InGaN, (AlGaIn)P, (AlGaIn)AsP, (AlGaIn)AsN, (AlGaIn)Pas, (Eu:InGa)N, (AlGaIn)N, or the like. In some embodiments, first semiconductor layer 1006 may be an n-type layer, and second semiconductor layer 1010 may be a p-type layer. For example, first semiconductor layer 1006 may be an n-doped GaN layer (e.g., doped with Si or Ge), and second semiconductor layer 1010 may be a p-doped GaN layer (e.g., doped with Mg, Ca, Zn, or Be). Active layers 1008 may include, for example, one or more GaN layers, one or more InGaN layers, one or more AlInGaP layers, and the like, which may form one or more heterostructures, such as one or more quantum wells or MQWs.

In some embodiments, first wafer 1002 may also include a bonding layer. Bonding layer 1012 may include various materials, such as a metal, an oxide, a dielectric, CuSn, AuTi, or the like. In one example, bonding layer 1012 may include p-contacts and/or n-contacts (not shown). In some embodiments, other layers may also be included on first wafer 1002, such as a buffer layer between substrate 1004 and first semiconductor layer 1006. The buffer layer may include various materials, such as polycrystalline GaN or AlN. In some embodiments, a contact layer may be between second semiconductor layer 1010 and bonding layer 1012. The contact layer may include any suitable material for providing an electrical contact to second semiconductor layer 1010 and/or first semiconductor layer 1006.

First wafer 1002 may be bonded to wafer 1003 that includes drive circuits 1011 and bonding layer 1013 as described above, via bonding layer 1013 and/or bonding layer 1012. Bonding layer 1012 and bonding layer 1013 may be made of the same material or different materials. Bonding layer 1013 and bonding layer 1012 may be substantially flat. First wafer 1002 may be bonded to wafer 1003 by various methods, such as metal-to-metal bonding, eutectic bonding, metal oxide bonding, anodic bonding, thermo-compression bonding, ultraviolet (UV) bonding, and/or fusion bonding.

As shown in FIG. 10B, first wafer 1002 may be bonded to wafer 1003 with the A-side (e.g., second semiconductor layer 1010) of first wafer 1002 facing down (i.e., toward wafer 1003). After bonding, substrate 1004 may be removed from first wafer 1002, and first wafer 1002 may then be processed from the n-side. The processing may include, for example, the formation of certain mesa shapes for individual LEDs, as well as the formation of optical components corresponding to the individual LEDs.

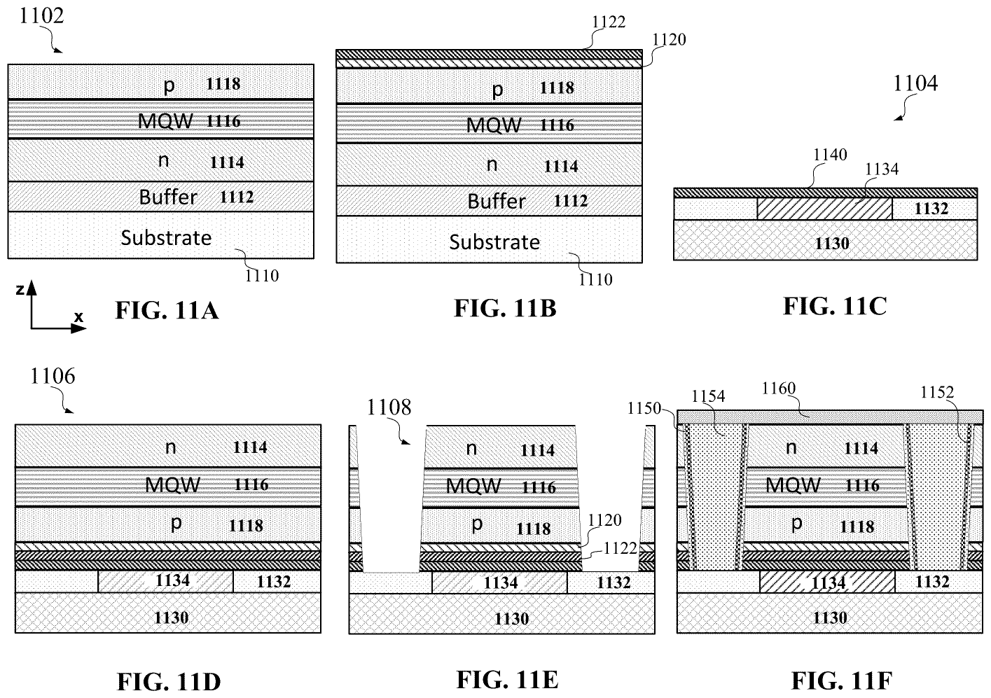

FIGS. 11A-11F illustrate an example of a method of fabricating a micro-LED device using alignment-free metal-to-metal bonding and post-bonding mesa formation processes. FIG. 11A shows a micro-LED wafer 1102 including epitaxial layers grown on a substrate 1110. As described above, substrate 1110 may include, for example, a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane (e.g., a c-plane or a semipolar plane) as the growth surface. In some embodiments, a buffer layer 1112 may be formed on substrate 1110 to improve the lattice matching between the growth substrate and the epitaxial layers, thereby reducing stress and defects in the epitaxial layers. The epitaxial layers may include an n-type semiconductor layer 1114 (e.g., a GaN layer doped with Si or Ge), an active region 1116, and a p-type semiconductor layer 1118 (e.g., a GaN layer doped with Mg, Ca, Zn, or Be). Active region 1116 may include multiple quantum wells or an MQW formed by quantum well layers (e.g., InGaN layer) sandwiched by barrier layers (e.g., GaN layer) as described above. The epitaxial layers may be grown layer-by-layer on substrate 1110 or buffer layer 1112 using techniques such as VPE, LPE, MBE, or MOCVD.

In the epitaxial growth processes, dopants (e.g., Mg) used to dope the p-type semiconductor layer (e.g., Mg-doped GaN layer) may remain in the reactor and/or on the epitaxial surface after the introduction of Mg precursors into the reactor. For example, the source for Mg doping (e.g., bis(cyclopentadienyl) magnesium (Cp₂Mg)) may be adsorbed onto reactor lines and walls and may be released in the gas phase in subsequent processes. A surface riding effect can also contribute to the residual Mg due to a Mg-rich layer formed on the surface of the p-GaN layer. Thus, if the quantum-well layers are grown on the Mg-rich p-GaN layer after the growth of the p-GaN layer with Mg dopants, the quantum-well layers may be contaminated with Mg dopants even after the Mg source is turned off, which may be referred to as the Mg-memory effect and may manifest as a slow decay tail of Mg into subsequent epitaxial layers. Mg can contaminate the MQW layers to form non-radiative recombination centers caused by, for example, Mg-related point defects, Mg interstitials, or Mg-related complexes.

In addition, for p-type GaN layers formed using, for example, MOCVD, the dopants (e.g., Mg) may be passivated due to the incorporation of atomic hydrogen (which exists in the form of H⁺) during growth and the formation of Mg—H complexes. Therefore, a post-growth activation of the dopants is generally performed to release mobile holes. The activation of the dopants in the p-GaN layer may include breaking the Mg—H bonds and driving the H⁺ out of the p-GaN layer at elevated temperatures (e.g., above 700° C.) to activate the Mg dopants. Insufficient activation of the Mg dopants in the p-GaN layer may lead to an open circuit, a poor performance, or a premature punch-through breakdown of the LED device. If p-type GaN layer is grown before the growth of the active region and the n-type layer, to drive out hydrogen, positively charged H⁺ ions need to diffuse across the p-n junction and through the n-GaN layer that is exposed. However, because of the depletion field in the p-n junction (with a direction from the n-type layer to the p-type layer), positively charged H⁺ ions may not be able to diffuse from the p-type layer to the n-type layer across the p-n junction. Furthermore, hydrogen may have a much higher diffusion barrier and thus a much lower diffusivity in n-type GaN compared with in p-type GaN. Thus, the hydrogen ions may not diffuse through the n-type layer to the exposed top surface of the n-type layer. Moreover, the activation may not be performed right after the p-doping and before the growth of the active region either, because the subsequent growth may be performed in the presence of high pressure ammonia (NH 3) in order to avoid decomposition of GaN at the high growth temperatures, and thus a semiconductor layer (e.g., the p-type semiconductor layer) that was activated may be re-passivated due to the presence of ammonia.

Therefore, in general, during the growth of the epitaxial layers, n-type semiconductor layer 1114 may be grown first. P-type semiconductor layer 1118 may be grown after the growth of active region 1116 to avoid contamination of active region 1116 and facilitate activation of the dopants in the p-type semiconductor layer.

FIG. 11B shows a reflector layer 1120 and a bonding layer 1122 formed on p-type semiconductor layer 1118. Reflector layer 1120 may include, for example, a metal layer such as an aluminum layer, a silver layer, or a metal alloy layer. In some embodiments, reflector layer 1120 may include a distributed Bragg reflector formed by conductive materials (e.g., semiconductor materials or conductive oxides) or including conductive vias. In some embodiments, reflector layer 1120 may include one or more sublayers. Reflector layer 1120 may be formed on p-type semiconductor layer 1118 in a deposition process. Bonding layer 1122 may include a metal layer, such as a titanium layer, a copper layer, an aluminum layer, a gold layer, or a metal alloy layer. In some embodiments, bonding layer 1122 may include a eutectic alloy, such as Au—In, Au—Sn, Au—Ge, or Ag—In. Bonding layer 1122 may be formed on reflector layer 1120 by a deposition process and may include one or more sublayers.

FIG. 11C shows a backplane wafer 1104 that includes a substrate 1130 with electrical circuits formed thereon. The electrical circuits may include digital and analog pixel drive circuits for driving individual micro-LEDs. A plurality of metal pads 1134 (e.g., copper or tungsten pads) may be formed in a dielectric layer 1132 (e.g., including SiO₂ or SiN). In some embodiments, each metal pad 1134 may be an electrode (e.g., anode or cathode) for a micro-LED. In some embodiments, pixel drive circuits for each micro-LED may be formed in an area matching the size of a micro-LED (e.g., about 2 μm×2 μm), where the pixel drive circuits and the micro-LED may collectively form a pixel of a micro-LED display panel. Even though FIG. 11C only shows metal pads 1134 formed in one metal layer in one dielectric layer 1132, backplane wafer 1104 may include two or more metal layers formed in dielectric materials and interconnected by, for example, metal vias, as in many CMOS integrated circuits. In some embodiments, a planarization process, such as a CMP process, may be performed to planarize the exposed surfaces of metal pads 1134 and dielectric layer 1132. A bonding layer 1140 may be formed on dielectric layer 1132 and may be in physical and electrical contact with metal pads 1134. As bonding layer 1122, bonding layer 1140 may include a metal layer, such as a titanium layer, a copper layer, an aluminum layer, a gold layer, a metal alloy layer, or a combination thereof. In some embodiments, bonding layer 1140 may include a eutectic alloy. In some embodiments, only one of bonding layer 1140 or bonding layer 1122 may be used.

FIG. 11D shows that micro-LED wafer 1102 and backplane wafer 1104 may be bonded together to form a wafer stack 1106. Micro-LED wafer 1102 and backplane wafer 1104 may be bonded by the metal-to-metal bonding of bonding layer 1122 and bonding layer 1140. The metal-to-metal bonding may be based on chemical bonds between the metal atoms at the surfaces of the metal bonding layers. The metal-to-metal bonding may include, for example, thermo-compression bonding, eutectic bonding, or transient liquid phase (TLP) bonding. The metal-to-metal bonding process may include, for example, surface planarization, wafer cleaning (e.g., using plasma or solvents) at room temperatures, and compression and annealing at elevated temperatures, such as about 250° C. or higher, to cause diffusion of atoms. In eutectic bonding, a eutectic alloy including two or more metals and with a eutectic point lower than the melting point of the two or more metals may be used for low-temperature wafer bonding. Because the eutectic alloy may become a liquid at the elevated temperature, eutectic bonding may be less sensitive to surface flatness irregularities, scratches, particles contamination, and the like. After the bonding, buffer layer 1112 and substrate 1110 may be thinned or removed by, for example, etching, back grinding, or laser lifting, to expose n-type semiconductor layer 1114.

FIG. 11E shows that wafer stack 1106 may be etched from the side of the exposed n-type semiconductor layer 1114 to form mesa structures 1108 for individual micro-LEDs. As shown in FIG. 11E, the etching may include etching through n-type semiconductor layer 1114, active region 1116, p-type semiconductor layer 1118, reflector layer 1120, and bonding layers 1122 and 1140, in order to singulate and electrically isolate mesa structures 1108. Thus, each singulated mesa structure 1108 may include n-type semiconductor layer 1114, active region 1116, p-type semiconductor layer 1118, reflector layer 1120, and bonding layers 1122 and 1140. To perform the etching, an etch mask layer may be formed on n-type semiconductor layer 1114. The etch mask layer may be patterned by aligning a photomask with the backplane wafer (e.g., using alignment marks on backplane wafer 1104) such that the patterned etch mask formed in the etch mask layer may align with metal pads 1134. Therefore, regions of the epitaxial layers and bonding layers above metal pads 1134 may not be etched. Dielectric layer 1132 may be used as the etch-stop layer for the etching. Even though FIG. 11E shows that mesa structures 1108 have substantially vertical sidewalls, mesa structures 1108 may have other shapes as described above, such as a conical shape, a parabolic shape, or a truncated pyramid shape.

FIG. 11F shows that a passivation layer 1150 may be formed on sidewalls of mesa structures 1108, and a sidewall reflector layer 1152 may be formed on passivation layer 1150. Passivation layer 1150 may include a dielectric layer (e.g., SiO₂, SiN, or Al₂O₃) or an undoped semiconductor layer. Sidewall reflector layer 1152 may include, for example, a metal (e.g., Al) or a metal alloy. In some embodiments, gaps between mesa structures 1108 may be filled with a dielectric material 1154 and/or a metal. Passivation layer 1150, sidewall reflector layer 1152, and/or dielectric material 1154 may be formed using suitable deposition techniques, such as chemical vapor deposition (CVD), physical vapor deposition (PVD), plasma-enhanced chemical vapor deposition (PECVD), atomic-layer deposition (ALD), laser metal deposition (LMD), or sputtering. In some embodiments, sidewall reflector layer 1152 may fill the gaps between mesa structures 1108. In some embodiments, a planarization process may be performed after the deposition of passivation layer 1150, sidewall reflector layer 1152, and/or dielectric material 1154. A common electrode layer 1160, such as a transparent conductive oxide (TCO) layer (e.g., an ITO layer) or a thin metal layer that may be transparent to light emitted in active region 1116, may be formed on the n-type semiconductor layer 1114 to form n-contacts and a common-cathode for the micro-LEDs. Even though not shown in FIG. 11F, an array of micro-lenses may be formed on common electrode layer 1160 to extract and collimate light emitted in active region 1116.

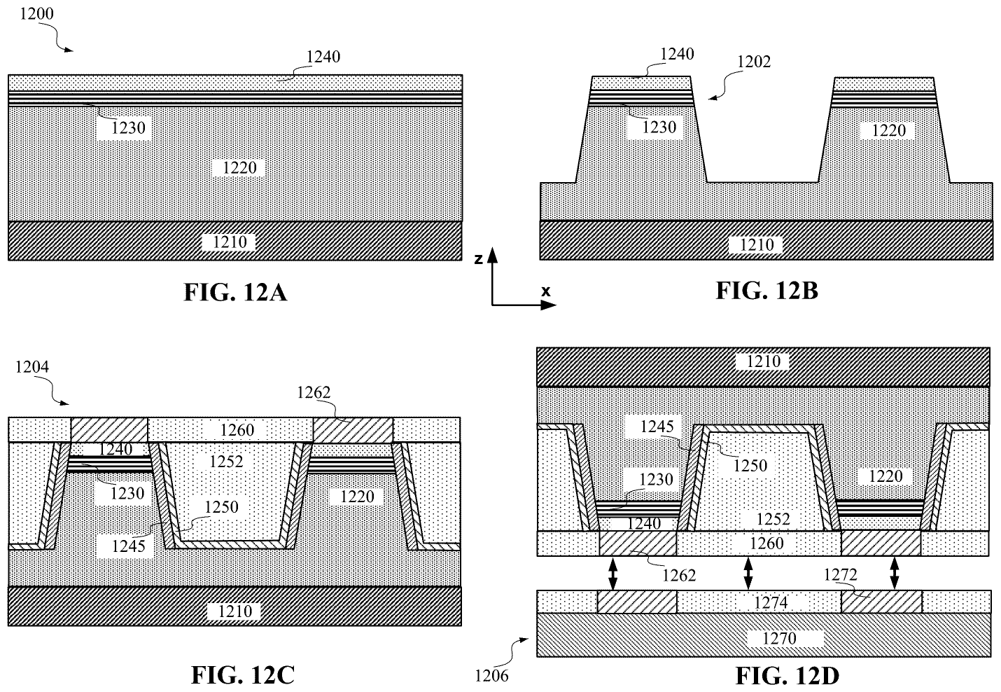

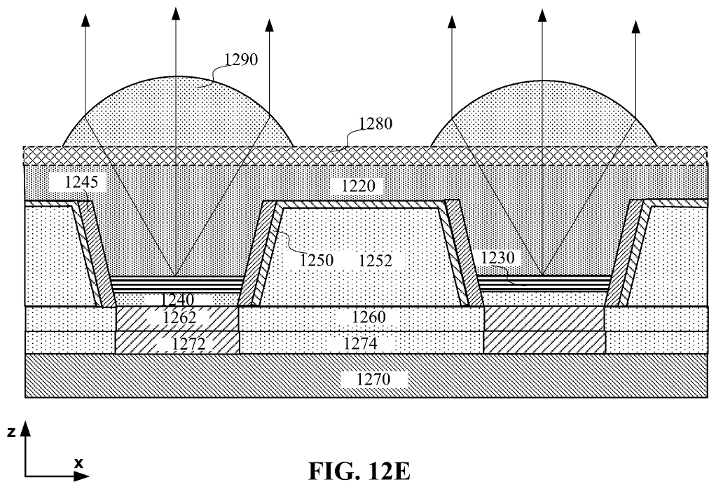

FIGS. 12A-12E illustrate an example of a process of fabricating a micro-LED device according to certain embodiments. FIG. 12A shows a micro-LED wafer 1200 including epitaxial layers grown on a substrate 1210. As described above, substrate 1210 may include, for example, a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane (e.g., a c-plane or a semipolar plane) as the growth surface. In some embodiments, a buffer layer may be formed on substrate 1210 to improve the lattice matching between the growth substrate and the epitaxial layers, thereby reducing stress and defects in the epitaxial layers. The epitaxial layers may include an n-type semiconductor layer 1220 (e.g., an n-doped GaN, AlInP, or AlGaInP layer), an active region 1230, and a p-type semiconductor layer 1240 (e.g., a p-doped GaN, AlInP, or AlGaInP layer). Active region 1230 may include multiple quantum wells or an MQW formed by thin quantum well layers (e.g., InGaN layers or GaInP layers) sandwiched by barrier layers (e.g., GaN layers, AlInP layers, or AlGaInP layers) as described above. The epitaxial layers may be grown layer-by-layer on substrate 1210 or the buffer layer using techniques such as VPE, LPE, MBE, or MOCVD. In some embodiments, n-type semiconductor layer 1220 may be much thicker than p-type semiconductor layer 1240.

FIG. 12B shows that micro-LED wafer 1200 may be etched from the side of p-type semiconductor layer 1240 to form semiconductor mesa structures 1202 for individual micro-LEDs. As shown in FIG. 12B, the etching may include etching through p-type semiconductor layer 1240, active region 1230, and at least a portion of n-type semiconductor layer 1220. Thus, each semiconductor mesa structure 1202 may include p-type semiconductor layer 1240, active region 1230, and a portion of n-type semiconductor layer 1220. To perform the etching, an etch mask layer may be formed on p-type semiconductor layer 1240, and dry or wet etching may be performed from the side of p-type semiconductor layer 1240. Due to the etching from p-type semiconductor layer 1240, semiconductor mesa structure 1202 may have sidewalls that are inwardly tilted in the z direction. For example, the angle between the sidewalls and the surface-normal direction (the z direction) of micro-LED wafer 1200 may be between about 0° to about 30°, such as about 15°. In some embodiments, semiconductor mesa structures 1202 may have a conical shape, a parabolic shape, a truncated pyramid shape, or another shape. In some embodiments, after the etching, sidewalls of the etched semiconductor mesa structures 1202 may be treated, for example, using KOH or an acid, to remove regions that may be damaged by high-energy ions during the dry etching.

FIG. 12C shows that micro-LED wafer 1200 may be further processed from the side of p-type semiconductor layer 1240 to form a wafer 1204 that includes an array of micro-LEDs. In the illustrated example, a passivation layer 1245 may be formed on sidewalls of semiconductor mesa structures 1202. Passivation layer 1245 may include, for example, SiO₂, SiN, Al₂O₃, or a semiconductor material. Passivation layer 1245 may electrically isolate semiconductor mesa structures 1202. A reflective metal layer 1250 (e.g., Al, Au, Ag, Cu, Ti, Ni, Pt, or a combination thereof) may be formed on passivation layer 1245 to optically isolate individual micro-LEDs and improve the light extraction efficiency. In some embodiments, reflective metal layer 1250 may fill regions between semiconductor mesa structures 1202. In some embodiments, a dielectric material 1252 (e.g., SiO₂) may be deposited on reflective metal layer 1250 and regions between semiconductor mesa structures 1202. Passivation layer 1245, reflective metal layer 1250, and dielectric material 1252 may be formed using suitable deposition techniques, such as chemical vapor deposition (CVD), physical vapor deposition (PVD), plasma-enhanced chemical vapor deposition (PECVD), atomic-layer deposition (ALD), laser metal deposition (LMD), or sputtering. A back reflector and p-contact 1262 may be form in a dielectric material 1260 and may contact p-type semiconductor layer 1240 of a corresponding semiconductor mesa structure 1202. Back reflector and p-contact 1262 may include, for example, Au, Ag, Al, Ti, Cu, Ni, ITO, or a combination thereof. Even though not shown in FIG. 12C, in some embodiments, one or more metal interconnect layers may be formed on back reflector and p-contact 1262. The one or more metal interconnect layers may include a bonding layer that includes metal bonding pads in a dielectric layer as described above with respect to, for example, FIG. 8B.

FIG. 12D shows that wafer 1204 may be bonded to a backplane wafer 1206 in a hybrid bonding process. Backplane wafer 1206 may include a substrate 1270 with electrical circuits formed thereon. The electrical circuits may include digital and analog pixel drive circuits for driving individual micro-LEDs. A plurality of metal pads 1272 (e.g., copper or tungsten pads) may be formed in a dielectric layer 1274 (e.g., including SiO₂ or SiN). In some embodiments, each metal pad 1272 may be an electrode (e.g., anode or cathode) for a micro-LED. Even though FIG. 12D only shows metal pads 1272 formed in one metal layer in one dielectric layer 1274, backplane wafer 1206 may include two or more metal layers formed in dielectric materials and interconnected by, for example, metal vias, as in many CMOS integrated circuits.

As described above with respect to, for example, FIGS. 8A-8D, the bonding surfaces of wafer 1204 and backplane wafer 1206 may be planarized, cleaned, and activated before the bonding. Wafer 1204 may be turned upside down and brought into contact with backplane wafer 1206 such that dielectric layer 1274 and dielectric material 1260 may be in direct contact and may be bonded together with or without heat treatment due to the surface activation. In some embodiments, a compression pressure may be applied to wafer 1204 and backplane wafer 1206 such that the bonding layers are pressed against each other. After the bonding of the dielectric materials, an annealing process may be performed at an elevated temperature to bond the metal pads (e.g., back reflector and p-contacts 1262 and metal pads 1272) at the bonding surfaces.

FIG. 12E shows that, after the bonding of wafer 1204 and backplane wafer 1206, substrate 1210 of wafer 1204 may be removed, and a transparent conductive oxide (TCO) layer 1280 (e.g., such as an ITO layer) may optionally be formed on the exposed n-type semiconductor layer 1220. TCO layer 1280 may form a common cathode for the micro-LEDs. In the illustrated example, non-native lenses 1290 may be fabricated in a dielectric material (e.g., SiN or SiO₂) or an organic material, and may be bonded to TCO layer 1280. In some embodiments, non-native lenses 1290 may be fabricated in a dielectric material deposited on TCO layer 1280. In some embodiments, native lenses may be fabricated in n-type semiconductor layer 1220, and the common cathode may be formed on the native lenses and/or may be the portion of n-type semiconductor layer 1220 that has not been etched (which can be heavily doped to reduce the resistance). As shown in FIGS. 12D and 12E, since wafer 1204 is turned upside down and bonded to backplane wafer 1206 and light may exit the micro-LEDs from the side of n-type semiconductor layer 1220, the semiconductor mesa structures of the micro-LEDs may have sidewalls that are outwardly tilted in the light emitting direction (e.g., the z direction).

As described above, in semiconductor LEDs, photons are usually generated at a certain internal quantum efficiency through the recombination of electrons and holes within an active region (e.g., one or more semiconductor layers), where the internal quantum efficiency is the proportion of the radiative electron-hole recombination in the active region that emits photons. The generated light may then be extracted from the LEDs in a particular direction or within a particular solid angle. The ratio between the number of emitted photons extracted from an LED and the number of electrons passing through the LED is referred to as the external quantum efficiency, which describes how efficiently the LED converts injected electrons to photons that are extracted from the device. The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device. For LEDs, and in particular, micro-LEDs including small semiconductor mesa structures formed in epitaxial layers to singulate the micro-LEDs, improving the internal and external quantum efficiency and/or controlling the emission spectrum may be challenging.

The internal quantum efficiency may indicate the proportion of the radiative electron-hole recombination in the active region that emits photons. The internal quantum efficiency of LEDs may depend on the relative rates of competitive radiative (light producing) recombination and non-radiative (lossy) recombination that occur in the active region of the LEDs. Non-radiative recombination processes in the active region may include Shockley-Read-Hall (SRH) recombination at defect sites and eeh/ehh Auger recombination that involves three carriers. The internal quantum efficiency of an LED may be approximately determined by:

$$IQE = \frac{{BN}^{2}}{AN + {BN}^{2} + {CN}^{3}} ,$$

where A, B and C are the rates of SRH recombination, bimolecular (radiative) recombination, and Auger recombination, respectively, and N is the charge-carrier density (i.e., charge-carrier concentration) in the active region.

While the Auger recombination due to a high current density (and high charge carrier density) may be an intrinsic process depending on material properties, non-radiative SRH recombination depends on the characteristics and the quality of material, such as the defect density in the active region. As described above, LEDs may be fabricated by etching mesa structures into the active emitting layers to confine carriers within the mesa structures of the individual LEDs and to expose the n-type material beneath the active emitting layers for electrical contact. When mesa structures are etched (e.g., using high-energy ions such as Art, Cl₂⁺, Cl⁺ or HF⁺) to isolate individual LEDs, the facets of the mesa structure, such as mesa sidewalls 732, may include some defects, such as lattice dislocations, dangling bonds, pores, grain boundaries, vacancies, surface oxides, surfaces modified by plasma atoms, interstitial defects, substitutional defects, inclusion of precipitates, and the like. The defects may create energy levels that otherwise would not exist within the bandgap of the semiconductor material, causing non-radiative electron-hole recombination at or near the facets of the mesa structure. Thus, these imperfections may become the recombination centers where electrons and holes may be confined until they combine non-radiatively. Therefore, the active region in proximity to the exposed sidewalls may have a higher rate of non-radiative SRH recombination, thereby reducing the efficiency of the resulting LED. Due to the small size of the mesa structure, a larger proportion of the injected carriers may diffuse to regions near the mesa sidewalls and may be subjected to a higher non-radiative recombination rate. This may cause the peak efficiency of the LED to decrease significantly and/or cause the peak efficiency operating current to increase.

For traditional, broad area LEDs used in lighting and backlighting applications (e.g., with a lateral device area about 0.1 mm² to about 1 mm²), the sidewalls are at the far ends of the devices. The devices can be designed such that little or no current is injected into regions within a minority carrier diffusion length from the mesa sidewalls, and thus the sidewall surface area to volume ratio and the overall rate of SRH recombination may be low. However, in micro-LEDs, as the size of the LED is reduced to a value comparable to or having a same order of magnitude as the minority carrier diffusion length, the increased surface area to volume ratio may lead to a high carrier surface recombination rate, because a greater proportion of the total active region may fall within the minority carrier diffusion length from the LED sidewalls. Therefore, more injected carriers may be subjected to the higher SRH recombination rate. This can cause the leakage current of the LED to increase and the efficiency of the LED to decrease as the size of the LED decreases, and/or cause the peak efficiency operating current to increase as the size of the LED decreases. For example, for a first LED with a 100 μm×100 μm×2 μm mesa, the side-wall surface area to volume ratio may be about 0.04. However, for a second LED with a 5 μm×5 μm×2 μm mesa, the side wall surface area to volume ratio may be about 0.8, which is about 20 times higher than the first LED. Thus, with a similar surface defect density, the SRH recombination coefficient of the second LED may be about 20 times higher as well. Therefore, the efficiency of the second LED may be significantly lower than the first LED. In addition, at the light-emitting surface of an LED, such as the interface between the LED and air, incident light with incident angles greater than a critical angle may be reflected back to the LED due to total internal reflection (TIR). Because of the geometry of the LED, some light reflected back to the LED may be trapped and eventually be absorbed by the LED. For example, some trapped light may be absorbed by the semiconductor materials to generate electron-hole pairs, which may recombine radiatively or non-radiatively. Some trapped light may be absorbed by metals (e.g., metal contacts or reflectors) at the bottom and/or sidewalls of the LED due to, for example, surface plasmon resonance that may be excited by p-polarized light at the interface between a metal layer and a dielectric layer (e.g., the passivation layer). Because of the high refractive indices of many III-V semiconductor materials (e.g., about 2.4 for GaN, and greater than about 3.0 for GaP, InP, GaInP, and AlGaInP), the critical angle for total internal reflection at the interface between the III-V semiconductor material and an adjacent lower refractive index material (e.g., air or a dielectric) may be small. As such, a large portion of the light emitted in the active region of a III-V material-based LED may be trapped in the LED due to TIR and may eventually be absorbed by the LED. Therefore, the LEE of the micro-LED may be low. In large LEDs, the light extraction efficiency may be improved by using, for example, thin film technology or patterned sapphire substrates with dense, periodic patterns on the substrate surfaces, or rough light emitting surface, to randomize the propagation directions of the photons and increase the possibility of the photons being released from the confinement and exiting the mesa structure. However, these techniques may not be used in micro-LEDs with linear dimensions less than, for example, about 5 μm or about 3 μm, due to the small sizes and high aspect ratios (height vs width) of these micro-LEDs. For example, roughening the light emitting surface using KOH may generate features with sizes about a few microns, which may be comparable to or larger than the size of the mesa structure of a micro-LED, and thus may not randomize the incident light and may divert the incident light differently at different micro-LEDs.

### IV. 3D Stack Inorganic LED Architecture

In near-eye display systems, in order to display color images, light sources that can emit the primary colors (such as red, green, and blue) may be needed. OLED devices that can emit red, green, and blue light may be fabricated directly onto a display substrate. Inorganic LEDs (e.g., semiconductor LEDs) may be manufactured using different materials and processes from OLED devices. For example, as described above, inorganic LED devices may be fabricated by growing epitaxial layers on a crystalline substrate to form an LED wafer, processing the LED wafer through various processes to from individual LED dies, where each LED die may include a two-dimensional array of LEDs. Different material systems and processes may be needed to fabricate LEDs that emit light of different colors. For example, as described above, GaN-based materials may often be used to fabricate blue or green light emitting LEDs, whereas phosphite-based III-V materials may often be used to fabricate red light emitting LEDs. Once fabricated, the LED dies can be transferred to a backplane. The backplane may often be made on a silicon wafer using, for example, CMOS processing technology. The backplane, as well as other components such as peripheral circuits, power circuits, and memory devices, may be attached (e.g., bonded) to a circuit board (e.g., a printed circuit board (PCB)) to form a display device. The circuit board may provide electrical connections among the different components of the display device.

Such arrangements may be undesirable for several reasons. For example, as the components are spaced apart by relatively long distances, the form factor of the display device may increase, which may make it difficult to use the display device in systems with limited spaces, such as a near-eye display system. In addition, long signal traces may be needed to provide the electrical connections among the components. The long signal traces can add substantial delay to the transmission of high speed signals (e.g., high resolution, high refresh rate image data), and thus may significantly degrade the performance of the display device. It may also be difficult and costly to precisely and reliably bond the many components to the backplane. Furthermore, near-eye display systems using such display devices may have higher weight, consume more power, and have large form factors. All these limitations may hamper the applications of the display devices in wearable display systems.

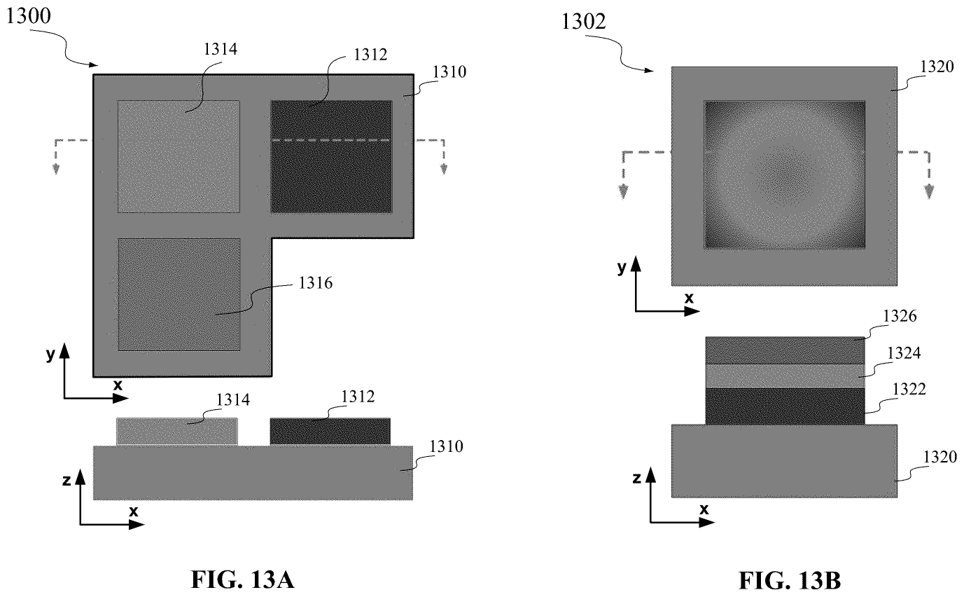

FIG. 13A includes a top view and a cross-sectional view of an example of a display device 1300 that includes three LED dies bonded to a backplane according to a two-dimensional layout. In the illustrated example, display device 1300 may include a backplane 1310 (e.g., including a CMOS backplane and/or PCB) and three LED dies bonded to backplane 1310. Backplane 1310 may include circuits for driving and controlling individual micro-LEDs on the LED dies, and may include different types of materials and devices, such as CMOS circuits formed on a silicon wafer, thin film transistor (TFT) circuits formed on a glass or polymer substrate, polychlorinated biphenyl (PCB), and the like, or a combination thereof. Display device 1300 may include an LED die 1312, an LED die 1314, and an LED die 1316 that are mounted on backplane 1310 via, for example, I/O bumps or bonding pads. LED die 1312 may include an array of LEDs that are configured to emit red light and generate monochromatic images. LED die 1314 may include an array of LEDs that are configured to emit green light and generate monochromatic images. LED die 1316 may include an array of LEDs that are configured to emit blue light and generate monochromatic images. The three monochromatic images may be coupled into a waveguide and projected into an eyebox as described above with respect to, for example, FIGS. 5A and 5B, to combine into color images.

As illustrated, in display device 1300, LED dies 1312, 1314, and 1316 are configured to be co-planar, for example, on an x-y plane. Therefore, the area of display device 1300 may be large, for example, larger than the total area of the three LED dies. As such, the optical system for collecting light from the three LED dies and projecting/replicating the images to the eyebox of the near-eye display system may need to be large too. As a result, the near-eye display system may be large and heavy, and may have lower performance as described above. It is desirable that the LEDs fabricated on a same die or package can emit light of different colors, where each pixel may include one or more LEDs (e.g., micro-LEDs) configured to emit red, green, and blue light of desired intensities, such that color images may be displayed by the LEDs on a die or package. But it can be very difficult to fabricate micro-LEDs that can emit light of different colors on a same die by epitaxial growth and micro-LED singulation processes due to, for example, different material systems used for different micro-LEDs that emit light of different colors.

According to certain embodiments disclosed herein, two or more LED wafers having micro-LEDs configured to emit light of different colors may be bonded using, for example, room temperature hybrid bonding and localized laser annealing, to form a wafer stack. The wafer stack may be diced to singulate die stacks that each include two or more dies having micro-LEDs configured to emit light of different colors, where the two or more dies may be arranged along the light emitting direction (rather than on a plane perpendicular to the light emitting direction) to form a three-dimensional structure (rather than the two-dimensional layout shown in FIG. 13A). Micro-LED dies that emit light of longer wavelengths may be positioned below micro-LED dies that emit light of shorter wavelengths. Because the micro-LED dies that emit light of shorter wavelengths may be fabricated using materials having wider energy bandgaps, the micro-LED dies that emit light of shorter wavelengths may not absorb (and thus are transparent to) the light having longer wavelengths (having lower energy) and emitted by the micro-LED dies below the micro-LED dies that emit light of shorter wavelengths. As such, the 3-D LED die stack may have minimum or no light loss due to absorption by materials on the light path. The 3-D LED die stack can significantly reduce the size of the backplane (thereby reducing the size and cost of the drive circuits and improving the yield of the drive circuits) and the size of the optical system, and can improve the overall performance and efficiency of the display device and the near-eye display system.

FIG. 13B includes a top view and a cross-sectional view of an example of a display device 1302 that includes three LED dies in a die stack on a backplane 1320 according to certain embodiments. Backplane 1320 may be similar to backplane 1310, but may have a much smaller size (e.g., about one third or smaller) in the x-y plane. The LED die stack may include an LED die 1322 that includes individual micro-LEDs configured to emit red light, an LED die 1324 that includes individual micro-LEDs configured to emit green light, and an LED die 1326 that includes individual micro-LEDs configured to emit blue light. As illustrated, LED die 1322 may be at the bottom and bonded to backplane 1320. LED die 1322 may also include additional bonding pads/balls and electrical connectors for electrically connecting to LED dies 1324 and 1326. LED die 1324 may be on top of and bonded to LED die 1322, and may also include additional bonding pads/balls and electrical connectors for electrically connecting to LED die 1326. LED die 1326 may be on top of and bonded to LED die 1324. Because LED dies 1324 and 1326 may include semiconductor materials having wider bandgaps to emit light with shorter wavelengths (higher energy), LED dies 1324 and 1326 may not absorb the red light emitted by LED die 1322 to generate free carriers. Similarly, because LED die 1326 may include semiconductor materials having wider bandgaps to emit light with shorter wavelengths (higher energy) than LED die 1324, LED die 1326 may not absorb the green light emitted by LED die 1324 to generate free carriers. Therefore, the red light emitted by LED die 1322 may not be absorbed by LED dies 1324 and 1326 in the LED die stack, and the green light emitted by LED die 1324 may not be absorbed by LED die 1326 in the LED die stack.

As described above and in more detail below, the LED die stacks may be formed by bonding LED wafers having micro-LEDs configured to emit light of different colors using, for example, room temperature hybrid bonding and localized laser annealing, to form a wafer stack, and dicing the wafer stack to singulate LED die stacks that each include two or more dies having micro-LEDs configured to emit light of different colors. In each LED die stack, two or more micro-LEDs in a same area and arranged along the light emitting direction (e.g., z direction) may be subpixels that form a single pixel, where the subpixels may emit light of different primary colors and desired intensities to generate a desired color in the full color gamut of the display device. In addition, the light from the micro-LEDs of each pixel is mixed before the light is collected and projected by display optics. Therefore, it may be easier to align the display device and the display optics (and the waveguide display). Furthermore, one micro-lens may be used to extract and collimate light emitted from all subpixels of a pixel. Compared with display device 1300, display device 1302 that includes backplane 1320 and the vertical LED die stack may have a much smaller footprint. A near-eye display system using display device 1302 may be compact and light, and may have a higher performance and efficiency.

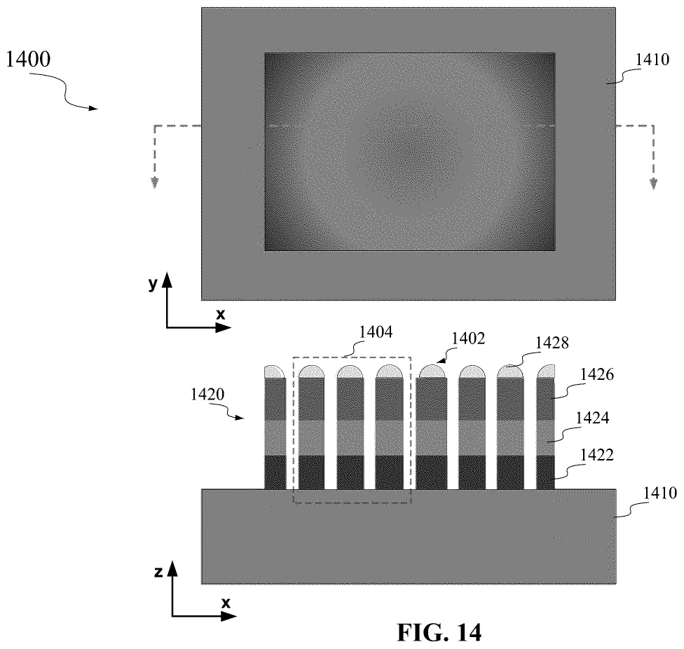

FIG. 14 includes a top view and a cross-sectional view of an example of a display device 1400 that includes three LED dies in a die stack on a backplane according to certain embodiments. FIG. 14 shows the arrangement of individual micro-LEDs in each LED die to form individual pixels of display device 1400. Display device 1400 may be an example of display device 1302, and may include a backplane 1410 and an LED die stack 1420 bonded to backplane 1410. Backplane 1410 may be similar to backplane 1310 or 1320. LED die stack 1420 may include a first LED die 1422 including individual micro-LEDs that emit red light, a second LED die 1424 including individual micro-LEDs that emit green light, and a third LED die 1426 including individual micro-LEDs that emit blue light. The micro-LEDs in LED die stack 1420 may be common-anode micro-LEDs or common-cathode micro-LEDs.

In some embodiments, display device 1400 may be formed by bonding first LED die 1422 to backplane 1410, bonding second LED die 1424 to first LED die 1422, and then bonding third LED die 1426 to second LED die 1424. In some embodiments, display device 1400 may be formed by bonding second LED die 1424 to first LED die 1422 and bonding third LED die 1426 to second LED die 1424 to form LED die stack 1420, and then bonding first LED die 1422 of LED die stack 1420 to backplane 1410. In some embodiments, display device 1400 may be formed by bonding a first LED wafer (e.g., including red light emitting micro-LEDs) to a backplane wafer, bonding a second LED wafer (e.g., including green light emitting micro-LEDs) to the first LED wafer, bonding a third LED wafer (e.g., including blue light emitting micro-LEDs) to the second LED wafer to form a wafer stack, and then dicing the wafer stack to singulate individual display devices 1400. In some embodiments, display device 1400 may be formed by bonding a second LED wafer (e.g., including green light emitting micro-LEDs) to a first LED wafer (e.g., including red light emitting micro-LEDs), bonding a third LED wafer (e.g., including blue light emitting micro-LEDs) to the second LED wafer to form a wafer stack, dicing the wafer stack to singulate individual LED die stack 1420, and bonding an LED die stack 1420 to backplane 1410. In some embodiments, an array of micro-lenses 1428 may be formed on or bonded to third LED die 1426. The array of micro-lenses 1428 may be formed in a semiconductor layer (e.g., a semiconductor layer of the third LED wafer) or a dielectric layer deposited on the third LED wafer.

As illustrated in FIG. 14, each pixel 1402 of display device 1400 may include a red light emitting micro-LED, a green light emitting micro-LED, a blue light emitting micro-LED, a micro-lens 1428, and corresponding drive circuits on backplane 1410. The three micro-LEDs in each pixel may be controlled by the drive circuits to emit light of the desired intensities to generate a desired color at a desired intensity. The emitted light of the desired color at the desired intensity may be extracted and/or collimated by the corresponding micro-lens 1428, such that the light may be more efficiently collected by the display optics to deliver to the user's eyes. Examples of the layer stack-up of an area 1404 of the display device 1400 are described in more detail below.

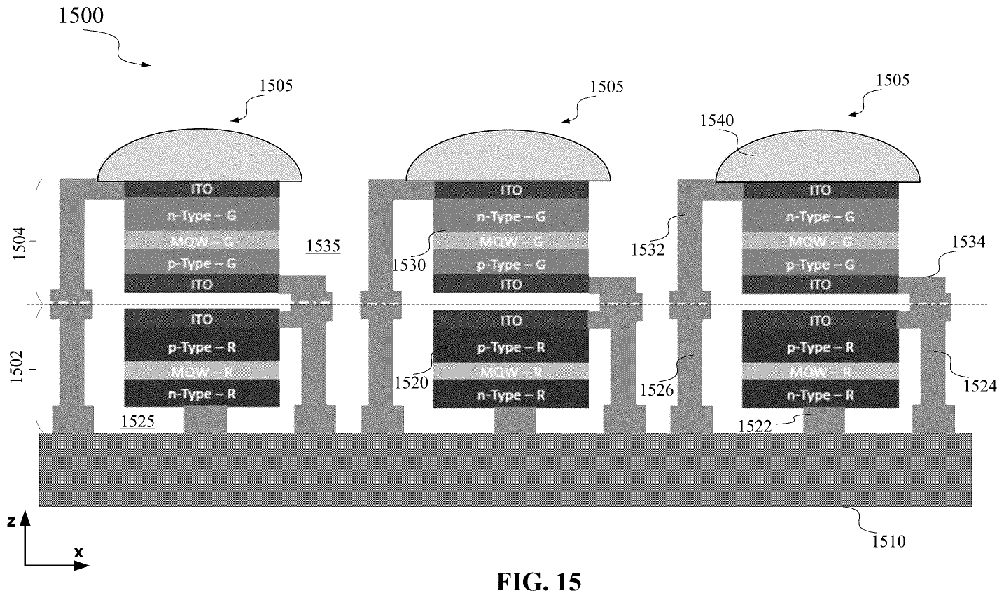

FIG. 15 is a cross-sectional view of an area 1500 of an example of a display device that includes an LED die stack on a backplane according to certain embodiments. Area 1500 of the display device shown in FIG. 15 may be an example of area 1404 of the display device 1400, and may include three pixels 1505. Each pixel 1505 may include a first micro-LED 1520 configured to emit red light, a second micro-LED 1530 configured to emit green light, and corresponding drive circuits on backplane 1510. First micro-LED 1520 may be fabricated on a first LED wafer 1502, and second micro-LED 1530 may be fabricated on a second LED wafer 1504. As described above, first LED wafer 1502 and second LED wafer 1504 may include different material systems. For example, first LED wafer 1502 may include III—P-based materials, while second LED wafer 1504 may include III—N-based materials. The micro-LEDs in the example shown in FIG. 15 may be common-anode micro-LEDs.

In the illustrated example, first micro-LED 1520 may include an n-contact 1522, an n-type semiconductor layer, an active region including a multi-quantum well, a p-type semiconductor layer, and a p-contact layer (e.g., a transparent conductive oxide layer such as an indium tin oxide (ITO) layer) connected to a p-connector 1524 (e.g., including a metal such as Cu or Al, or a metal alloy). A dielectric material 1525 (e.g., including SiO₂, SiN, Al₂O₃, etc.) may electrically isolate adjacent first micro-LEDs 1520 on first LED wafer 1502. In addition, first LED wafer 1502 may also include n-connectors 1526 (e.g., including a metal such as Cu, Al, or a metal alloy) for second micro-LEDs 1530. Even though not shown in FIG. 15, each micro-LED 1520 may also include a passivation layer and a mesa sidewall reflector as described above. N-contact 1522, p-connector 1524, n-connector 1526, and dielectric material 1525 may be bonded to backplane 1510 by a hybrid bonding process as described above, where the dielectric materials at the bonding interface may be bonded together at room temperature, and the metal bonding pads at the bonding interface may be annealed to bond the metal. In some embodiments, the annealing may be performed at an elevated temperature (e.g., >100° C.). In some embodiments, the annealing may be localized annealing using, for example, a laser beam.

Second micro-LED 1530 may include a p-contact layer (e.g., an ITO layer), a p-type semiconductor layer, an active region including a multi-quantum well, an n-type semiconductor layer, and an n-contact layer (e.g., an ITO layer). The p-contact layer may be connected to a p-connector 1534 (e.g., including a metal such as Cu or Al, or a metal alloy) on second LED wafer 1504, and the n-contact layer may be connected to an n-connector 1532 (e.g., including a metal such as Cu or Al, or a metal alloy) on second LED wafer 1504. A dielectric material 1535 (e.g., including SiO₂, SiN, Al₂O₃, etc.) may electrically isolate adjacent second micro-LEDs 1530 on second LED wafer 1504. Even though not shown in FIG. 15, each micro-LED 1530 may also include a passivation layer and a mesa sidewall reflector as described above. N-connector 1532, p-connector 1534, and dielectric material 1535 may be bonded to n-connector 1526, p-connector 1524, and dielectric material 1525, respectively, on first LED wafer 1502, by a hybrid bonding process as described above, where the dielectric materials at the bonding interface may be bonded together at room temperature, and the metal bonding pads at the bonding interface may be annealed to bond the metal. In some embodiments, the annealing may be localized annealing using, for example, a laser beam. Second LED wafer 1504 may include an array of micro-lenses 1540 formed thereon or bonded thereto for extracting and/or collimating the emitted light. Micro-lenses 1540 may be native lenses formed in a semiconductor material layer of second LED wafer 1504, or may be non-native lenses formed in a dielectric material layer or a semiconductor material layer.

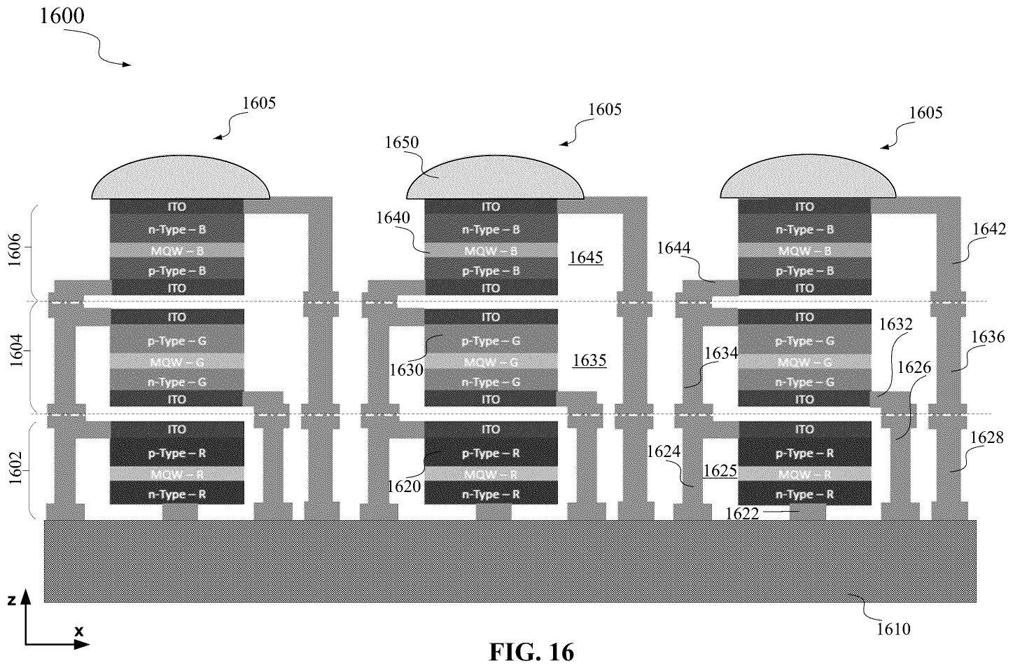

FIG. 16 is a cross-sectional view of another example of an area 1600 of a display device that includes an LED die stack on a backplane according to certain embodiments. Area 1600 of the display device shown in FIG. 16 may be an example of area 1404 of display device 1400, and may include three pixels 1605. Each pixel 1605 may include a first micro-LED 1620 configured to emit red light, a second micro-LED 1630 configured to emit green light, a third micro-LED 1640 configured to emit blue light, and corresponding drive circuits on a backplane 1610. First micro-LED 1620 may be fabricated on a first LED wafer 1602, second micro-LED 1630 may be fabricated on a second LED wafer 1604, and third micro-LED 1640 may be fabricated on a third LED wafer 1606. As described above, first LED wafer 1602, second LED wafer 1604, and third LED wafer 1606 may include different material systems. For example, first LED wafer 1602 may include III—P-based semiconductor materials, while second LED wafer 1604 and third LED wafer 1606 may include III—N-based semiconductor materials. The micro-LEDs in the example shown in FIG. 16 may be common-anode micro-LEDs.

In the illustrated example, first micro-LED 1620 may include an n-contact 1622, an n-type semiconductor layer, an active region including a multi-quantum well, a p-type semiconductor layer, and a p-contact layer (e.g., a transparent conductive oxide layer such as an indium tin oxide (ITO) layer) connected to a p-connector 1624 (e.g., including a metal such as Cu or Al, or a metal alloy). A dielectric material 1625 (e.g., including SiO₂, SiN, Al₂O₃, etc.) may electrically isolate adjacent first micro-LEDs 1620 on first LED wafer 1602. In addition, first LED wafer 1602 may also include n-connectors 1626 (e.g., including a metal such as Cu or Al, or a metal alloy) for second micro-LEDs 1630 and n-connectors 1628 for third micro-LEDs 1640. Even though not shown in FIG. 16, each micro-LED 1620 may also include a sidewall passivation layer and a mesa sidewall reflector as described above. N-contacts 1622, p-connectors 1624, n-connectors 1626, n-connectors 1628, and the dielectric material 1625 may be bonded to backplane 1610 by a hybrid bonding process as described above, where the dielectric materials at the bonding interface may be bonded together at room temperature, and the metal bonding pads at the bonding interface may be annealed to bond the metal bonding pads. In some embodiments, the annealing may be performed at an elevated temperature (e.g., >100° C.). In some embodiments, the annealing may be localized annealing using, for example, a laser beam.

Second micro-LED 1630 may include a p-contact layer (e.g., an ITO layer), a p-type semiconductor layer, an active region including a multi-quantum well, an n-type semiconductor layer, and an n-contact layer (e.g., an ITO layer). The p-contact layer may be connected to a p-connector 1634 (e.g., including a metal such as Cu or Al, or a metal alloy) on second LED wafer 1604, and the n-contact layer may be connected to an n-connector 1632 (e.g., including a metal such as Cu or Al, or a metal alloy) on second LED wafer 1604. In addition, second LED wafer 1604 may also include n-connectors 1636 (e.g., including a metal such as Cu or Al, or a metal alloy) for third micro-LEDs 1640. A dielectric material 1635 (e.g., including SiO₂, SiN, Al₂O₃, etc.) may electrically isolate adjacent second micro-LEDs 1630 on second LED wafer 1604. Even though not shown in FIG. 16, each micro-LED 1630 may also include a sidewall passivation layer and a mesa sidewall reflector as described above. N-connectors 1632, p-connectors 1634, n-connectors 1636, and dielectric material 1635 may be bonded to n-connectors 1626, p-connectors 1624, n-connectors 1628, and dielectric material 1625, respectively, on first LED wafer 1602, by a hybrid bonding process as described above, where the dielectric materials at the bonding interface may be bonded together at room temperature, and the metal bonding pads at the bonding interface may be annealed to bond the metal bonding pads and the connectors. In some embodiments, the annealing may be localized annealing using, for example, a laser beam.

Third micro-LED 1640 may include a p-contact layer (e.g., an ITO layer), a p-type semiconductor layer, an active region including a multi-quantum well, an n-type semiconductor layer, and an n-contact layer (e.g., an ITO layer). The p-contact layer may be connected to a p-connector 1644 (e.g., including a metal such as Cu or Al, or a metal alloy) on third LED wafer 1606, and the n-contact layer may be connected to an n-connector 1642 (e.g., including a metal such as Cu or Al, or a metal alloy) on third LED wafer 1606. A dielectric material 1645 (e.g., including SiO₂, SiN, Al₂O₃, etc.) may electrically isolate adjacent third micro-LEDs 1640 on third LED wafer 1606. Even though not shown in FIG. 16, each micro-LED 1640 may also include a sidewall passivation layer and a mesa sidewall reflector as described above. N-connectors 1642, p-connectors 1644, and dielectric material 1645 may be bonded to n-connectors 1636, p-connectors 1634, and dielectric material 1635, respectively, on second LED wafer 1604, by a hybrid bonding process as described above, where the dielectric materials at the bonding interface may be bonded together at room temperature, and the metal bonding pads at the bonding interface may be annealed to bond the metal. In some embodiments, the annealing may be localized annealing using, for example, a laser beam. Third LED wafer 1606 may include an array of micro-lenses 1650 formed thereon or bonded thereto for extracting and/or collimating the emitted light. Micro-lenses 1650 may be native lenses formed in a semiconductor material layer of third LED wafer 1606, or may be non-native lenses formed in a dielectric material layer or a semiconductor material layer deposited on third LED wafer 1606.

It can be challenging to bond LED wafers using bonding processes that may need to be performed at elevated temperatures. The materials in the LED wafers, such as the semiconductor materials, metal materials, dielectric materials, transparent conductive oxides, and the like, may have different coefficients of thermal expansion (CTEs). Thus, if the LED wafers need to be heated to the elevated temperatures and then cooled down, the mismatch between the CTEs of the different materials may cause cracks, disconnections, short circuits, or other defects in the LED wafers. In addition, annealing the LED wafers at elevated temperature may change certain properties of some materials (e.g., doped semiconductor materials), and thus may change the performance of the micro-LEDs on the LED wafers.

According to certain embodiments, LED wafers may be bonded by room temperature bonding and localized annealing using focused laser beams. Laser bonding and laser annealing can avoid heating the whole wafer and can also help to strengthen the metal bonds and contacts with ITO. The laser beam can be applied to desired locations at desired angles to precisely anneal and bond metal materials at target locations. The laser beam may have a small beam size, may include short pulses at a certain pulse rate, and may be scanned at a certain scanning frequency, to localize the heat.

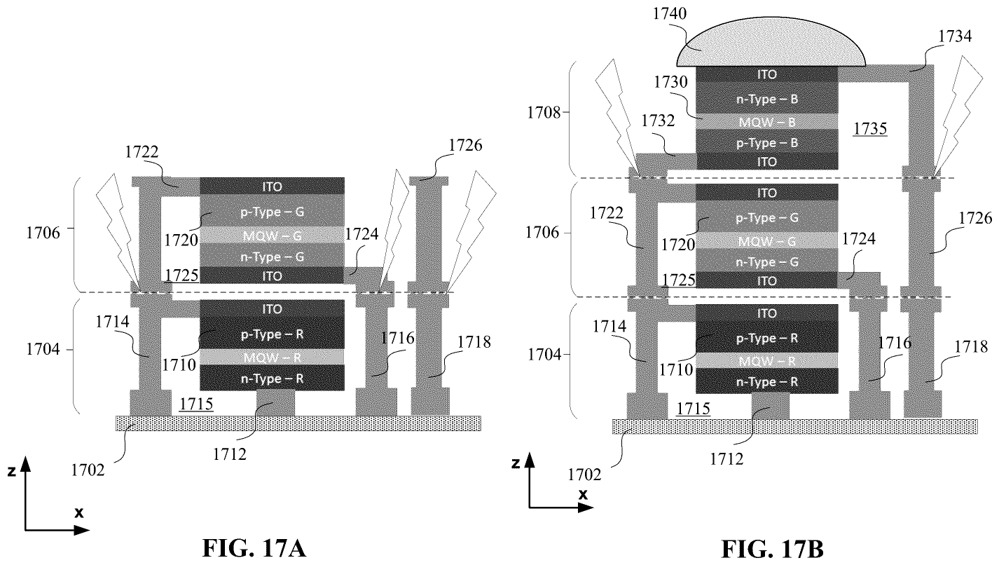

FIGS. 17A-17B illustrates an example of bonding LED wafers by room temperature hybrid bonding and localized laser annealing according to certain embodiments. The LED wafers may include two or more LED wafers each including micro-LEDs configured to emit light of a certain color. For example, an LED wafer 1704 may include micro-LEDs configured to emit red light (e.g., including III-P materials), an LED wafer 1706 may include micro-LEDs configured to emit green light (e.g., including III—N-based active regions with a certain indium doping density), while an LED wafer 1708 may include micro-LEDs configured to emit blue light (e.g., including III—N-based active regions with a different indium doping density).

In the illustrated example shown in FIG. 17A, LED wafer 1704 may include red light emitting micro-LEDs 1710, n-contacts 1712 for micro-LEDs 1710, p-connectors 1714 for micro-LEDs 1710, n-connectors 1716 for connecting to micro-LEDs 1720 on LED wafer 1706, n-connectors 1718 for connecting to micro-LEDs 1730 on LED wafer 1708, and a dielectric material 1715 (e.g., SiN, SiO₂, Al₂O₃, etc.) for electrically isolating micro-LEDs 1710 on LED wafer 1704. LED wafer 1704 may be bonded to a backplane 1702 by hybrid bonding as described above. LED wafer 1706 may include green light emitting micro-LEDs 1720, n-connectors 1724 for micro-LEDs 1720, p-connectors 1722 for micro-LEDs 1720, n-connectors 1726 for connecting to micro-LEDs 1730 on LED wafer 1708, and a dielectric material 1725 (e.g., SiN, SiO₂, Al₂O₃, etc.) for electrically isolating micro-LEDs 1720 on LED wafer 1706. LED wafer 1706 may be bonded to LED wafer 1704 by a hybrid bonding, where dielectric material 1725 and dielectric material 1715 at the bonding interface may first be bonded at room temperature, and then the bonding pads for p-connectors 1714 and 1722, n-connectors 1716 and 1724, and n-connectors 1718 and 1726 may be annealed to bond the metal at the bonding interface. In the illustrated example, the annealing may be localized annealing using laser beams, where the laser beams may be tilted to desired angles and can be focused, such that only localized areas of the connectors may be heated to an elevated temperature to anneal and bond the connectors. In some embodiments, the laser beam may be a pulsed laser beam including short pulses at a certain pulse rate, and may be scanned at a certain scanning frequency, to localize the heat.

FIG. 17B shows that LED wafer 1708 may be bonded to LED wafer 1706 by room temperature hybrid bonding and localized laser annealing after bonding LED wafer 1706 to LED wafer 1704. In the illustrated example, LED wafer 1708 may include blue light emitting micro-LEDs 1730, n-connectors 1734 for micro-LEDs 1730, p-connectors 1732 for micro-LEDs 1730, and a dielectric material 1735 (e.g., SiN, SiO₂, Al₂O₃, etc.) for electrically isolating micro-LEDs 1730 on LED wafer 1708. LED wafer 1708 may also include micro-lenses 1740 formed thereon. LED wafer 1708 may be bonded to LED wafer 1706 by a hybrid bonding, where dielectric material 1735 and dielectric material 1725 at the bonding interface may first be bonded at room temperature, and then the bonding pads for p-connectors 1732 and 1722 and n-connectors 1726 and 1734 may be annealed to bond the metal at the bonding interface. In the illustrated example, the annealing may be localized annealing using laser beams, where the laser beams may be tilted to desired angles and can be focused, such that only localized areas of the connectors may be heated to an elevated temperature to anneal and bond the connectors. In some embodiments, the laser beam may be a pulsed laser beam including short pulses at a certain pulse rate, and may be scanned at a certain scanning frequency, to localize the heat.

Embodiments may include different combinations of features in view of the description Certain embodiments are described in the following examples.

In Example 1, a display device includes a die stack that includes a backplane die, a first LED die bonded to the backplane die, and a second LED die bonded to the first LED die. The backplane die includes LED drive circuits. The first LED die includes micro-LEDs configured to emit light around a first wavelength. The second LED die includes micro-LEDs configured to emit light around a second wavelength that is shorter than the first wavelength.

Example 2 includes the display device of Example 1, where the first LED die includes p-connectors and n-connectors for electrically connecting the micro-LEDs on the first LED die to the drive circuits on the backplane die, and p-connectors and n-connectors for electrically connecting the micro-LEDs on the second LED die to the drive circuits on the backplane die.

Example 3 includes the display device of Example 2, where the p-connectors for electrically connecting the micro-LEDs on the first LED die to the drive circuits on the backplane die and the p-connectors for electrically connecting the micro-LEDs on the second LED die to the drive circuits on the backplane die are shared in the first LED die.

Example 4 includes the display device of Example 2, where the n-connectors for electrically connecting the micro-LEDs on the first LED die to the drive circuits on the backplane die and the n-connectors for electrically connecting the micro-LEDs on the second LED die to the drive circuits on the backplane die are shared in the first LED die.

Example 5 includes the display device of any of Examples 1-4, where the micro-LEDs on the first LED die are configured to emit red light, and the micro-LEDs on the second LED die are configured to emit green or blue light.

Example 6 includes the display device of any of Examples 1-5, where each micro-LED of the micro-LEDs on the second LED die is aligned with a respective micro-LED of the micro-LEDs on the first LED die to form a pixel of the display device.

Example 7 includes the display device of any of Examples 1-6, where the die stack further comprises a third LED die bonded to the second LED die and including micro-LEDs configured to emit light around a third wavelength that is shorter than the second wavelength.

Example 8 includes the display device of Example 7, where the second LED die includes: p-connectors and n-connectors for electrically connecting the micro-LEDs on the second LED die to the drive circuits on the backplane die through the first LED die; and p-connectors and n-connectors for electrically connecting the micro-LEDs on the third LED die to the drive circuits on the backplane die through the first LED die.

Example 9 includes the display device of Example 8, where the p-connectors for electrically connecting the micro-LEDs on the second LED die to the drive circuits on the backplane die and the p-connectors for electrically connecting the micro-LEDs on the third LED die to the drive circuits on the backplane die are shared in the second LED die.

Example 10 includes the display device of Example 7, where each micro-LED of the micro-LEDs on the third LED die is aligned with a respective micro-LED of the micro-LEDs on the second LED die and a respective micro-LED of the micro-LEDs on the first LED die form a pixel of the display device that includes three subpixels.

Example 11 includes the display device of any of Examples 1-10, where the first LED die is bonded to the backplane die by hybrid bonding.

Example 12 includes the display device of any of Examples 1-11, where the second LED die is bonded to the first LED die by hybrid bonding.

Example 13 includes the display device of any of Examples 1-12, where active regions of the micro-LEDs on the first LED dies include a first semiconductor material different from a second semiconductor material of the active regions of the micro-LEDs on the second LED dies.

Example 14 includes the display device of any of Examples 1-13, where the LED drive circuits include complementary metal-oxide-semiconductor (CMOS) circuits.

Example 15 includes the display device of any of Examples 1-14, where the display device further comprises an array of micro-lenses above the second LED die.

Example 16 includes the display device of Example 15, where each micro-lens of the array of micro-lenses is on a respective micro-LED of the micro-LEDs on the second LED die and a respective micro-LED of the micro-LEDs on the first LED die.

Example 17 includes the display device of any of Examples 1-16, where a lateral size of each micro-LED of the micro-LEDs on the first LED die and the micro-LEDs on the second LED die is less than 5 μm.

Example 18 includes a method of fabricating a display micro-light emitting diode (micro-LED) device, the method comprising: bonding a first light emitting diode (LED) wafer to a backplane wafer by hybrid bonding, the first LED wafer including micro-LEDs configured to emit light around a first wavelength; bonding a first dielectric material layer at a surface of the first LED wafer to a second dielectric material layer at a surface of a second LED wafer at room temperature, the second LED wafer including micro-LEDs configured to emit light around a second wavelength that is shorter than the first wavelength; and bonding metal contacts at the surface of the first LED wafer to metal contacts at the surface of the second LED wafer using a laser beam.

Example 19 includes the method of Example 18, where the laser beam includes a focused laser beam illuminating the metal contacts at a localized area.

Example 20 includes the method of Example 18 or 19, where the laser beam illuminates the metal contacts at a localized area from a surface-normal direction or at a tilted angle.

### V. Surface Loss Reduction by Creating a Band Engineered Charge Trap-Based Sidewall Passivation

As described above, the internal quantum efficiency of an LED depends on the relative rates of competitive radiative (light producing) recombination and non-radiative (lossy) recombination that occur in the active region of the LED. Non-radiative recombination processes in the active region include Shockley-Read-Hall (SRH) recombination at defect sites, and electron-electron-hole (eeh) and/or electron-hole-hole (ehh) Auger recombination. The Auger recombination is a non-radiative process involving three carriers, which affects LEDs of all sizes. For LEDs fabricated by etching epitaxial layers to form LED mesa structures for individual LEDs, the IQEs and EQEs of the LEDs may be low due to, for example, high defect densities at the sidewalls of the LED mesa structures caused by the abrupt ending of the lattice structure, chemical contamination, and/or structural damages.

For example, in plasma etching, high-energy ions (e.g., Ar⁺, Cl₂⁺, Cl⁺ or HF⁺) may be used to bombard the exposed surfaces of semiconductor epitaxial layers. Because of the bombardment by high-energy particles, the surfaces created by the etching may be highly damaged, where the damages may include alterations to the crystal structure or other modifications to the surfaces. The damages may extend into the interior of the mesa structure, such as about 50 nm to about 500 nm or more below the surfaces formed by the etching. Therefore, the active region in proximity to the sidewalls of the mesa structure may have a high density of defects, such as lattice dislocations, dangling bonds, pores, grain boundaries, vacancies, surface oxides, surfaces modifications by plasma atoms, interstitial defects, substitutional defects, inclusion of precipitates, and the like. The defects may introduce energy states having deep or shallow energy levels in the bandgap. Carriers may be trapped by these energy states until they recombine non-radiatively. Therefore, the active region in proximity to the sidewalls of the mesa structure may have a higher rate of nonradiative recombination, which may reduce the efficiency of the LED.

In micro-LEDs, the mesa structures may have very small sizes, such as with a width less than about 10 μm, less than about 5 μm, less than about 3 μm, or less than about 2 μm. As such, the lateral size (e.g., diameter or width) of each micro-LED may be comparable to the minority carrier diffusion length. Therefore, a larger proportion of the total active region may be within the minority carrier diffusion length from the sidewall surfaces where the defect density and thus the defect-induced non-radiative recombination rate may be high. As a result, a larger proportion of the injected carriers may diffuse to the regions near the sidewall surfaces, where the carriers may be subjected to a higher SRH recombination rate. This may cause the efficiency of the micro-LED to decrease (in particular, at low current injection), cause the peak efficiency of the micro-LED to decrease, and/or cause the peak efficiency operating current to increase. Increasing the injected current may cause the efficiencies of the micro-LEDs to drop due to the higher eeh or ehh Auger recombination rate at a higher current density, and may also cause spectral shift of the emitted light. As the physical sizes of micro-LEDs are further reduced, efficiency losses due to surface recombination near the etched sidewall surfaces that include surface imperfections may become much more significant.

III-phosphide materials, such as AlGaInP, can have a high surface recombination velocity and minority carrier diffusion length. For example, red AlGaInP LEDs may generally operate at a reduced carrier concentration (e.g., about 10¹⁷ to 10¹⁸ cm⁻³), and thus may have a relatively long carrier life time τ. The carrier diffusivity D in the active region in the undoped quantum wells of red AlGaInP LEDs may also be rather large. As a result, the carrier diffusion length L=\sqrt{D×τ} can be, for example, about 10-25 μm or longer in some devices. In addition, the surface recombination velocity of AlGaInP material may be an order of magnitude higher than the surface recombination velocities of III-nitride materials. Thus, compared with LED made of III-nitride materials (e.g., blue and green LEDs made of GaN), the internal and external quantum efficiencies of AlGaInP-based red LEDs can drop even more significantly as the device size decreases.

Various techniques have been used to reduce the non-radiative surface recombination thereby improving the efficiencies of the micro-LED. For example, surface treatments and dielectric passivation have been used to reduce the defect density at the mesa sidewalls and thus suppress the non-radiative recombination near the mesa sidewalls. However, due to the abrupt ending of the lattice structure, there may still be defects at the mesa sidewalls that can lead to high non-radiative recombination.

According to certain embodiments, to avoid the non-radiative recombination at sidewalls of individual micro-LED mesa structures formed by etching epitaxial layers that include the light-emitting active layers, thereby improving the efficiencies of the micro-LEDs, charge storage structures may be used at the mesa sidewalls to create an electric field at the mesa sidewalls to keep one type of carriers (e.g., electrons) away from the mesa sidewall surface. The charge storage structure may include band-engineered dielectric layers (e.g., two or more dielectric materials having different work functions or energy bands such as SiO₂ and SiN), and can be programmed like non-volatile storage memory (e.g., using the Fowler-Nordheim mechanism) to inject charges (e.g., electrons) into a charge trapping/storage layer (e.g., a potential well formed by a SiN layer sandwiched by SiO₂ layers) that can store the charges (e.g., positive or negative charges). The charges stored in the highly charged dielectric at the mesa sidewalls can repel free carriers (e.g., electrons) in the active region that have charges with the same polarity as the stored charges, thereby keeping the free carriers away from the mesa sidewalls. With no or fewer free carriers of one polarity (e.g., electrons or holes) at the mesa sidewalls, non-radiative recombination of electrons and holes may be significantly suppressed or reduced. In some embodiments, the charge storage structure can be programmed by applying a voltage signal on the sidewall reflector (e.g., including Al, Ag, Cu, Ti, a metal alloy, etc.) that may function as the gate electrode, to inject and store charges. The charge storage structure can be programmed, for example, after manufacturing or during initialization or reset. During normal operation of the micro-LEDs, no electrical signal may need to be applied to the sidewall reflector because the charges may be trapped in the potential well. The charge storage structure and the programming/charge injection structure may be implemented using some existing structures of micro-LEDs, such as the sidewall passivation layer and sidewall reflector, and can be relatively easy to integrate into existing process flow.

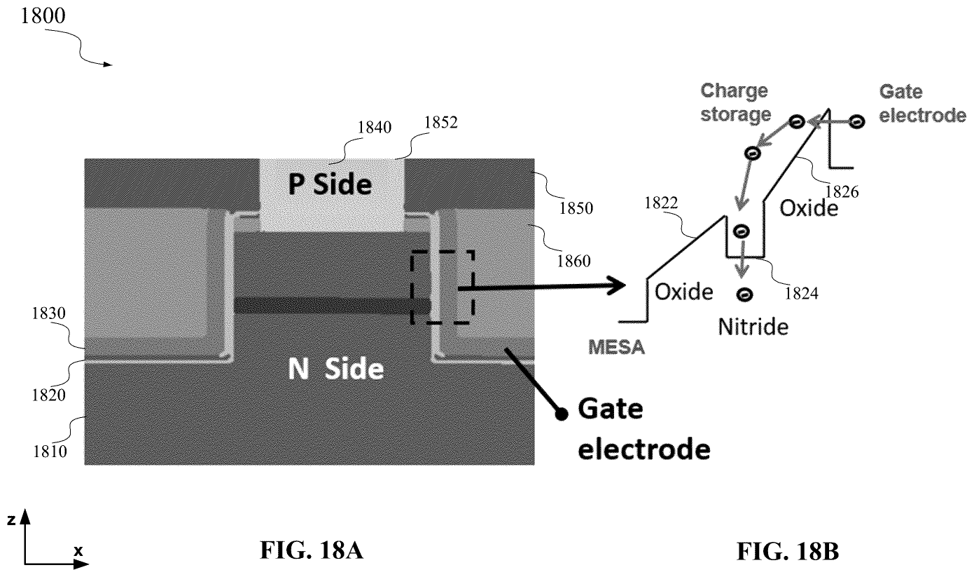

FIG. 18A illustrates an example of a micro-LED 1800 including a charge storage structure at the mesa sidewall according to certain embodiments. Micro-LED 1800 may include a semiconductor mesa structure 1810 that may include an n-doped semiconductor layer, an active region including one or more quantum wells, and a p-doped semiconductor layer. In the example illustrated in FIG. 18A, micro-LED 1800 may also include a passivation layer 1820, a sidewall reflector 1830 that may be electrically conductive, and a p-contact 1840 formed in a dielectric material layer 1850. Sidewalls of sidewall reflector 1830 may be surrounded by an isolation material 1860, such as a dielectric material. P-contact 1840 may include a metal or a metal alloy and may be used to apply a voltage signal to the p-type semiconductor layer to control micro-LED 1800. In some embodiments, a diffusion barrier layer 1852 may be between p-contact 1840 and dielectric material layer 1850.

Passivation layer 1820 may include a plurality of layers that may have different energy bandgaps. The plurality of layers may include at least two dielectric layers that sandwich one or more other layers and electrically isolate the one or more other layers from the semiconductor mesa structure and the sidewall reflector. The one or more other layers may have an energy band narrower than the energy band of the two dielectric layers and may be used as a potential well for storing charges. In one example, passivation layer 1820 may include a nitride layer sandwiched by two oxide layers. In some embodiments, the one or more other layers between the two dielectric layers may include a metal layer, a semiconductor layer, a dielectric layer, or a combination thereof.

FIG. 18B illustrates an example of injecting electrons into the charge storage structure of the micro-LED of FIG. 18A according to certain embodiments. In the example shown in FIG. 18B, the charge storage structure includes a first oxide layer 1822 (e.g., including SiO₂) adjacent to the semiconductor mesa structure, a second oxide layer 1826 (e.g., including SiO₂) adjacent to sidewall reflector 1830, and a nitride layer 1824 (e.g., including SiN) between first oxide layer 1822 and second oxide layer 1826. The conduction band of nitride layer 1824 may be lower than the conduction band of first oxide layer 1822 and second oxide layer 1826. In the illustrated example, sidewall reflector 1830 may be biased (e.g., negatively biased) with respect to the semiconductor mesa structure 1810 (e.g., p-contact 1840) and the bias is large enough, electrons from sidewall reflector 1830 may tunnel through second oxide layer 1826 by Fowler-Nordheim tunneling and may be trapped in the potential well in nitride layer 1824. As such, a potential barrier may be created around the mesa sidewalls due to the charge stored in the charge trapping/storage layer. This potential barrier may prevent electrons from reaching mesa sidewall surfaces during LED operations. The charges stored in the charge trapping/storage layer may repel free carriers having the same polarity as the stored charges to prevent the free carrier from reaching the mesa sidewalls.

As described above, the charge storage structure can be programmed, for example, after manufacturing or during initialization or reset. During normal operation of the micro-LEDs, no electrical signal may need to be applied to the sidewall reflector because the charges are trapped in the potential well. In some embodiments, if needed, the stored charges may be removed by reversely biasing the sidewall reflector with respect to the semiconductor mesa structure 1810 (e.g., p-contact 1840), such that charges of the opposite polarity (e.g., holes) may be injected into the potential well to recombine with the stored charges (electrons) through SRH recombination.

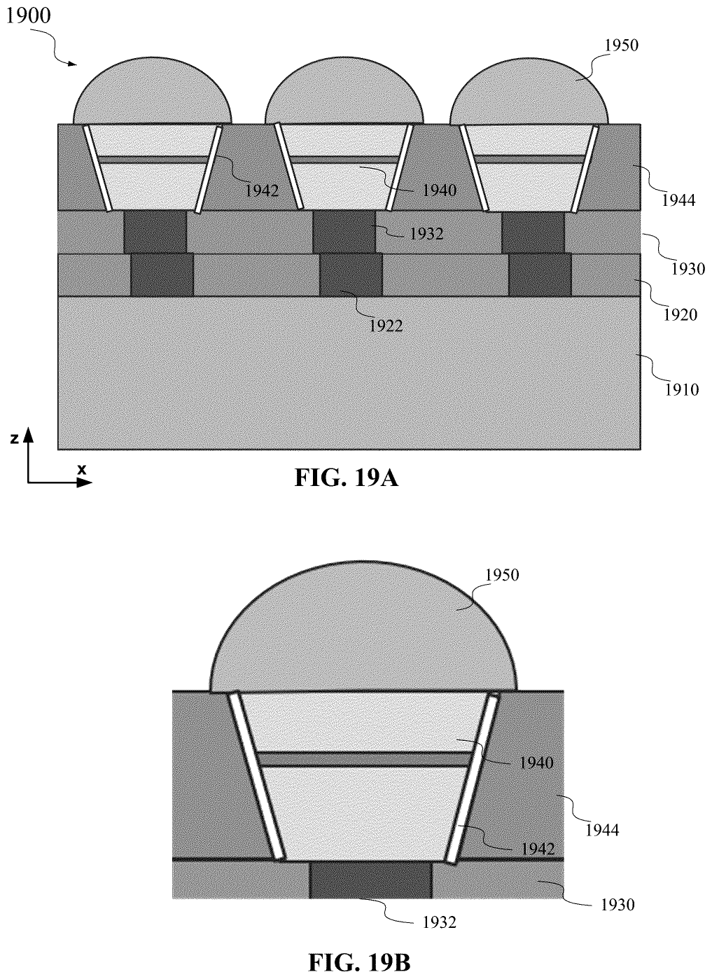

FIG. 19A illustrates an example of a micro-LED device 1900 including an array of micro-LEDs having charge storage structures at the mesa sidewalls according to certain embodiments. FIG. 19B illustrates an example of a micro-LED in the micro-LED device of FIG. 19A. In the illustrated example, micro-LED device 1900 may include a backplane 1910 (e.g., a CMOS backplane) having a bonding layer 1920 bonded to an array of micro-LEDs on a micro-LED wafer. Bonding layer 1920 may include a dielectric layer with metal connectors 1922 formed therein. The micro-LED wafer may include an array of semiconductor mesa structures 1940, an array of micro-lenses 1950, and a bonding layer 1930 that include electrical contacts 1932 (e.g., p-contacts) formed therein. Bonding layer 1930 may be bonded to bonding layer 1920 of backplane 1910 using hybrid bonding techniques as described above.

Each semiconductor mesa structure 1940 may include a charge storage structure 1942 at the mesa sidewalls and an isolation material 1944 between semiconductor mesa structures 1940. Charge storage structure 1942 may be similar to the charge storage structure of micro-LED 1800 and may include two dielectric layers and one or more charge storage layers between the two dielectric layers. Charge storage structure 1942 may also serve as the passivation layer. In some embodiments, charge storage structure 1942 may include a reflective metal layer that forms a sidewall reflector. In some embodiments, isolation material 1944 may include a reflective metal material and may be used as the sidewall reflector. As described above, the sidewall reflector may be used as an electrode to apply a bias voltage and inject charges into the charge storage layer.

Embodiments may include different combinations of features in view of the description. Certain embodiments are described in the following examples.

In Example 1, a micro-light-emitting diode (micro-LED) may include a semiconductor mesa structure, a charge storage structure on sidewalls of the semiconductor mesa structure, and a conductive material layer on the second dielectric layer. The charge storage structure may include a first dielectric layer on the sidewalls of the semiconductor mesa structure, a second dielectric layer, and one or more charge storage layer between the first dielectric layer and the second dielectric layer. The conductive material layer is configurable to apply an electric field to the charge storage structure such that electrons or holes are injected into the one or more charge storage layers.

Example 2 includes the micro-LED of Example 1, where the one or more charge storage layers include electrons or holes stored therein.

Example 3 includes the micro-LED of any of Examples 1 and 2, wherein an energy bandgap of a charge storage layer of the one or more charge storage layers is narrower than energy bandgaps of the first dielectric layer and the second dielectric layer.

Example 4 includes the micro-LED of any of Examples 1-3, where the first dielectric layer and the second dielectric layer include oxide layers (e.g., SiO₂ layers), and the one or more charge storage layers include a nitride layer (e.g., a SiN layer).

Example 5 includes the micro-LED of any of Examples 1-4, where the one or more charge storage layers include a metal layer, a dielectric layer, a semiconductor layer, or a combination thereof.

Example 6 includes the micro-LED of any of Examples 1-5, where the first dielectric layer is a passivation layer for the micro-LED.

Example 7 includes the micro-LED of any of Examples 1-6, where the conductive material layer includes a reflective metal layer that serves as a sidewall reflector of the micro-LED.

Example 8 includes a micro-LED device comprising an array of micro-LEDs, where each micro-LED of the array of micro-LEDs includes the micro-LED of any of Examples 1-7.

### VI. Heat-Spreading Micro Lens for Micro-LED Display

Micro-LED displays may be sensitive to temperature. For example, the performance of micro-LED devices may deteriorate with the increase of the operating temperature. Due to the constraints in the energy budget and the form factor of near-eye displays, it may be difficult to use active thermal solution in micro-LED-based near-eye display to manage the junction temperature at some components such as the micro-LED displays.

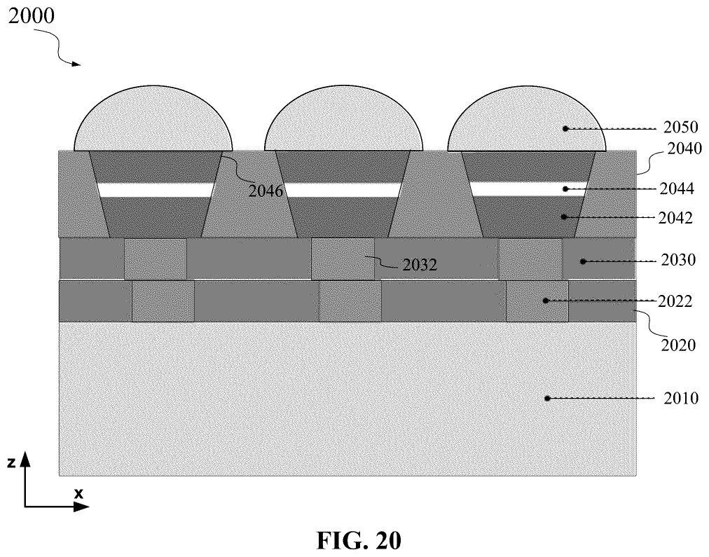

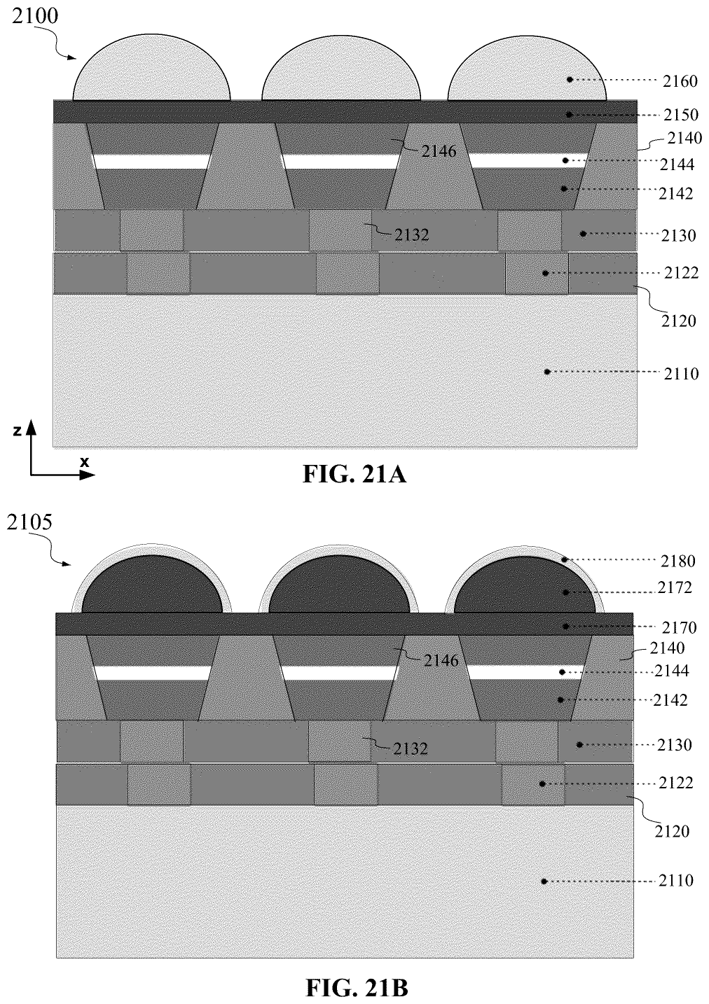

FIG. 20 illustrates an example of a micro-LED device 2000 including an array of micro-lenses 2050 on an array of micro-LEDs. In the illustrated example, micro-LED device 2000 may include a backplane 2010 (e.g., a CMOS backplane) having a bonding layer 2020 bonded to an array of micro-LEDs on a micro-LED wafer. Bonding layer 2020 may include a dielectric layer (e.g., including SiO₂) with metal connectors 2022 (e.g., made of copper) formed therein. The micro-LED wafer may include an array of semiconductor mesa structures electrically and/or optically isolated by filling materials 2040 that may include dielectric materials and/or metal materials. Each semiconductor mesa structure may include a first doped (e.g., n-doped or p-doped) semiconductor layer 2042 (e.g., including a III-P or III-N material such as GaN), an active region 2044, and a second doped (e.g., p-doped or n-doped) semiconductor layer 2046. Even though not shown in FIG. 20, each semiconductor mesa structure may include a sidewall passivation layer, a sidewall reflector, and the like, as described above and below in this disclosure. The micro-LED wafer may also include a bonding layer 2030 that includes electrical contacts 2032 (e.g., made of copper) formed in a dielectric material layer (e.g., a SiN or SiO₂ layer). Bonding layer 2030 may be bonded to bonding layer 2020 of backplane 2010 using hybrid bonding techniques as described above. An array of micro-lenses 2050 may be formed on the micro-LED wafer after the bonding and removal of the substrate of the micro-LED wafer, as described above with respect to, for example, FIGS. 12A-12E. As also described above, the array of micro-lenses 2050 may be native lenses formed in a semiconductor material layer of the micro-LED wafer, or may be non-native lenses formed in a material layer (e.g., a dielectric material such as SiN, SiO₂, or another dielectric material) deposited on the micro-LED wafer after the removal of the substrate.

In micro-LED device 2000, a significant amount of heat may be generated in active regions 2044 due to, for example, non-radiative recombination of carriers in active regions 2044 that may result in a very low internal quantum efficiency. It may be difficult for the heat generated in active regions 2044 to dissipate in micro-LED device 2000 because of low thermal conductivity of the materials surrounding active regions 2044. As such, the temperature of active regions 2044 may increase, and thus the performance (e.g., efficiency) of the micro-LEDs may decrease and the emission wavelength may change.

According to certain embodiments, passive thermal designs may be used to achieve the desired localized temperature. In one example, a heat-spreading layer may be positioned between micro-LEDs and micro-lenses. The heat-spreading layer may include large thermal-conductivity materials such as diamond, aluminum nitride (AlN), and graphene, and thus may function as heat spreader to enhance in-plane heat dissipation, thereby achieving a more uniform temperature at the micro-LED display. The heat-spreading layer may have a suitable refractive index such that it is optically compatible with the micro-lenses and the micro-LEDs. The heat-spreading layer may also have a coefficient of thermal expansion (CTE) close to the materials of the micro-LEDs (e.g., GaN) so as to avoid defects (e.g., peeling) caused by CTE mismatch.

FIG. 21A illustrates an example of a micro-LED device 2100 including a heat-spreading layer 2150 between an array of micro-lenses 2160 and an array of micro-LEDs according to certain embodiments. In the illustrated example, micro-LED device 2100 may include a backplane 2110 (e.g., a CMOS backplane) having a bonding layer 2120 bonded to an array of micro-LEDs on a micro-LED wafer. Bonding layer 2120 may include a dielectric layer (e.g., including SiO₂) with metal connectors 2122 (e.g., made of copper) formed therein. The micro-LED wafer may include an array of semiconductor mesa structures electrically and/or optically isolated by filling materials 2140 that may include dielectric materials and/or metal materials. Each semiconductor mesa structure may include a first doped (e.g., n-doped or p-doped) semiconductor layer 2142 (e.g., including a III-P or III-N material such as GaN), an active region 2144, and a second doped (e.g., p-doped or n-doped) semiconductor layer 2146. Even though not shown in FIG. 21, each semiconductor mesa structure may include a sidewall passivation layer, a sidewall reflector, and the like, as described above and below in this disclosure. The micro-LED wafer may also include a bonding layer 2130 that includes electrical contacts 2132 (e.g., made of copper) formed in a dielectric material layer (e.g., a SiN or SiO₂ layer). Bonding layer 2130 may be bonded to bonding layer 2120 of backplane 2110 using hybrid bonding techniques as described above.

In micro-LED device 2100, before forming an array of micro-lenses 2160 on the micro-LEDs, a heat-spreading layer 2150 may be deposited on the micro-LED wafer after the bonding and removal of the substrate of the micro-LED wafer. The array of micro-lenses 2160 may be formed in a material layer (e.g., a dielectric material such as SiN or another dielectric material) deposited on heat-spreading layer 2150. With heat-spreading layer 2150 on top of the micro-LEDs, it may be easier to connect heat-spreading layer 2150 to a heat sink (e.g., a frame or a substrate such as a glass or a SiC-based waveguide).

Heat-spreading layer 2150 may include, for example, diamond, AlN, or graphene, which may have high thermal conductivities. For example, the thermal conductivity of GaN for making blue and green light-emitting micro-LEDs may be about 130 W/(m*K) and the thermal conductivity of InGaP for making red light-emitting micro-LEDs may be about 1.4 W/(m*K), while diamond may have a thermal conductivity greater than about 1800 W/(m*K), graphene may have a thermal conductivity about 3000-5000 W/(m*K), and AlN may have a thermal conductivity greater than 150 W/(m*K). Therefore, heat-spreading layer 2150 may better dissipate heat from the active region than III-V semiconductor materials such as GaN or InGaP. The CTE of AlN may be about 4.6 ppm/° C., which may match the CTEs of III-P and III-N semiconductor materials used to make micro-LEDs, such as GaN (with a CTE about 5.59 (//) or 3.17 (⊥)) or InGaP (with a CTE about 5.1). Therefore, defects (e.g., peeling) caused by CTE mismatch may be avoid when materials such as AlN are used as the heat-spreading layer. Heat-spreading materials such as diamond, AlN, or graphene may also have refractive indices close to the refractive indices of the semiconductor materials and higher than the refractive indices of materials such as SiN. Thus, using the heat-spreading layer between the micro-LEDs and micro-lenses 2160 may not cause additional loss due to reflection.

FIG. 21B illustrates an example of a micro-LED device 2105 including an array of micro-lenses 2172 made in a heat-spreading material layer 2170 on an array of micro-LEDs according to certain embodiments. In the illustrated example, micro-LED device 2105 may include backplane 2110 (e.g., a CMOS backplane) having bonding layer 2120 bonded to an array of micro-LEDs on a micro-LED wafer. Bonding layer 2120 may include a dielectric layer (e.g., including SiO₂) with metal connectors 2122 (e.g., made of copper) formed therein. The micro-LED wafer may include an array of semiconductor mesa structures electrically and/or optically isolated by filling materials 2140 that may include dielectric materials and/or metal materials. Each semiconductor mesa structure may include first doped (e.g., n-doped or p-doped) semiconductor layer 2142 (e.g., including a III-P or III-N material such as GaN), active region 2144, and second doped (e.g., p-doped or n-doped) semiconductor layer 2146. Even though not shown in FIG. 21, each semiconductor mesa structure may include a sidewall passivation layer, a sidewall reflector, and the like, as described above and below in this disclosure. The micro-LED wafer may also include a bonding layer 2130 that includes electrical contacts 2132 (e.g., made of copper) formed in a dielectric material layer (e.g., a SiN or SiO₂ layer). Bonding layer 2130 may be bonded to bonding layer 2120 of backplane 2110 using hybrid bonding techniques as described above.

In micro-LED device 2105, the array of micro-lenses 2172 may be formed in a heat-spreading material layer 2170 deposited on the micro-LEDs after the bonding of the micro-LED wafer to backplane 2110 and the removal of the substrate of the micro-LED wafer. In some embodiments, surfaces of micro-lenses 2172 may be coated with an antireflection layer 2180. Heat-spreading material layer 2170 may be very close to the heat source (e.g., active regions 2144), and thus may more effectively dissipate heat generated in the micro-LEDs (e.g., in active regions 2144). With heat-spreading material layer 2170 on top of the micro-LEDs, it may be easier to connect heat-spreading material layer 2170 to a heat sink (e.g., a frame or a substrate such as a glass or a SiC-based waveguide).

As described above, heat-spreading material layer 2170 may include, for example, diamond, AlN, or graphene, which may have high thermal conductivities as described above. Therefore, heat-spreading material layer 2170 may better dissipate heat from the active region than III-V semiconductor materials such as GaN or InGaP. The CTE of AlN may match the CTEs of III-P and III-N semiconductor materials used to make micro-LEDs, such as GaN or InGaP. Therefore, defects (e.g., peeling) caused by CTE mismatch may be avoid when materials such as AlN are used as the heat-spreading layer. Heat-spreading materials such as diamond, AlN, or graphene may also have refractive indices close to the refractive indices of the semiconductor materials and higher than the refractive indices of materials such as SiN. Therefore, micro-lenses 2172 can be thinner than micro-lenses 2160 for the same focal length, which may be desirable for red light-emitting micro-LEDs.

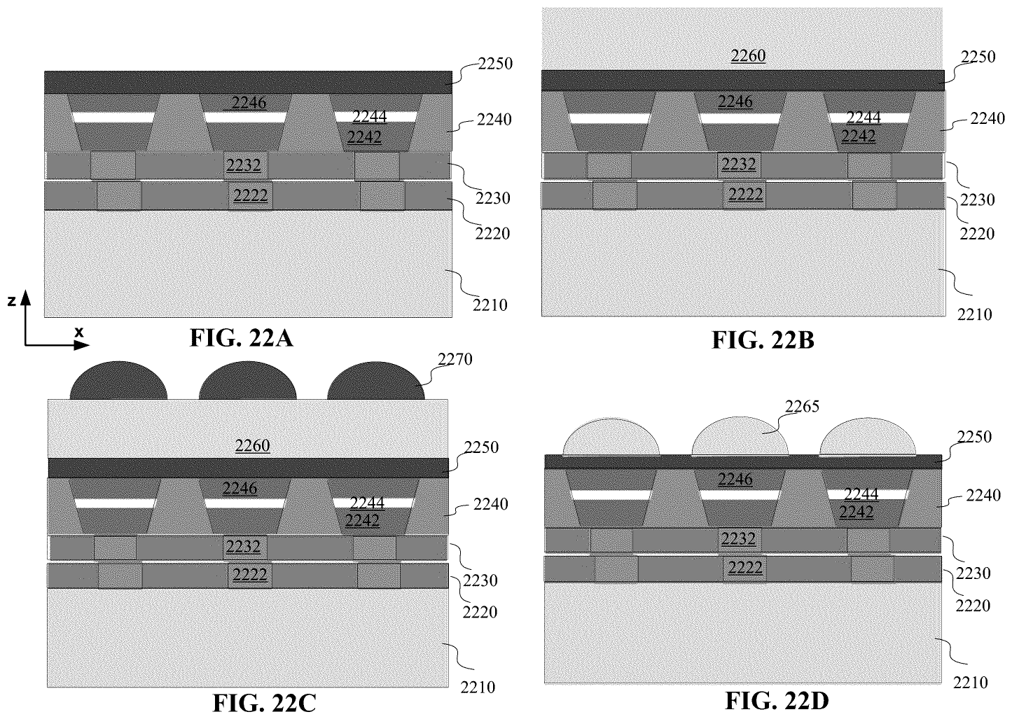

FIGS. 22A-22D illustrate an example of a process of fabricating an example of a micro-LED device including a heat-spreading layer between an array of micro-lenses and an array of micro-LEDs according to certain embodiments. FIG. 22A shows a wafer stack including a backplane 2210 and a micro-LED wafer bonded together. The wafer stack may be formed using, for example, techniques described above with respect to FIGS. 8A-12E. For example, the individual mesa structures may be formed before or after the bonding and removal of the substrate of the micro-LED wafer. As illustrated, backplane 2210 (e.g., a CMOS backplane) may have a bonding layer 2220 bonded to an array of micro-LEDs on the micro-LED wafer. Bonding layer 2220 may include a dielectric layer (e.g., including SiO₂) with metal connectors 2222 (e.g., made of copper) formed therein. The micro-LED wafer may include an array of semiconductor mesa structures electrically and/or optically isolated by filling materials 2240 that may include dielectric materials and/or metal materials. Each semiconductor mesa structure may include a first doped (e.g., n-doped or p-doped) semiconductor layer 2242 (e.g., including a III-P or III-N material such as GaN), an active region 2244, and a second doped (e.g., p-doped or n-doped) semiconductor layer 2246. Even though not shown in FIG. 22A, each semiconductor mesa structure may include a sidewall passivation layer, a sidewall reflector, and the like, as described above and below in this disclosure (e.g., with respect to FIGS. 7A, 7B, 11F, 12C, etc.). The micro-LED wafer may also include a bonding layer 2230 that includes electrical contacts 2232 (e.g., made of copper) formed in a dielectric material layer (e.g., a SiN or SiO₂ layer). Bonding layer 2230 may be bonded to bonding layer 2220 of backplane 2210 using hybrid bonding techniques as described above.

A heat-spreading layer 2250 may be deposited on the array of micro-LEDs. As described above, heat-spreading layer 2250 may include a material that may have a high thermal conductivity and a CTE matching the CTEs of the semiconductor materials of the micro-LEDs. The heat-spreading material may also have a high refractive index, such as above 2.0. In some embodiments, the heat-spreading material may include diamond, AN, graphene, and the like. Heat-spreading layer 2250 may have a certain thickness so that the heat generated in, for example, active regions 2244, can be dissipated at a faster rate, without significantly increasing the thickness of the wafer stack. In some embodiments, an electrically conductive material may be used as the heat-spreading layer and a common electrode for the array of micro-LEDs. In some embodiments, a transparent conductive oxide (e.g., ITO) layer may be deposited on the array of micro-LEDs before depositing heat-spreading layer 2250.

FIG. 22B shows that a lens material layer 2260 may be deposited on heat-spreading layer 2250. Lens material layer 2260 may include a dielectric material, a semiconductor material, or an organic material. In one example, Lens material layer 2260 may include SiN. FIG. 22C shows that an etch mask 2270 may be formed on lens material layer 2260. Etch mask 2270 may be formed using, for example, a gray-scale photoresist or other techniques. Lens material layer 2260 may be etched using etch mask 2270 to form micro-lenses 2265 in lens material layer 2260 as shown in FIG. 22D.

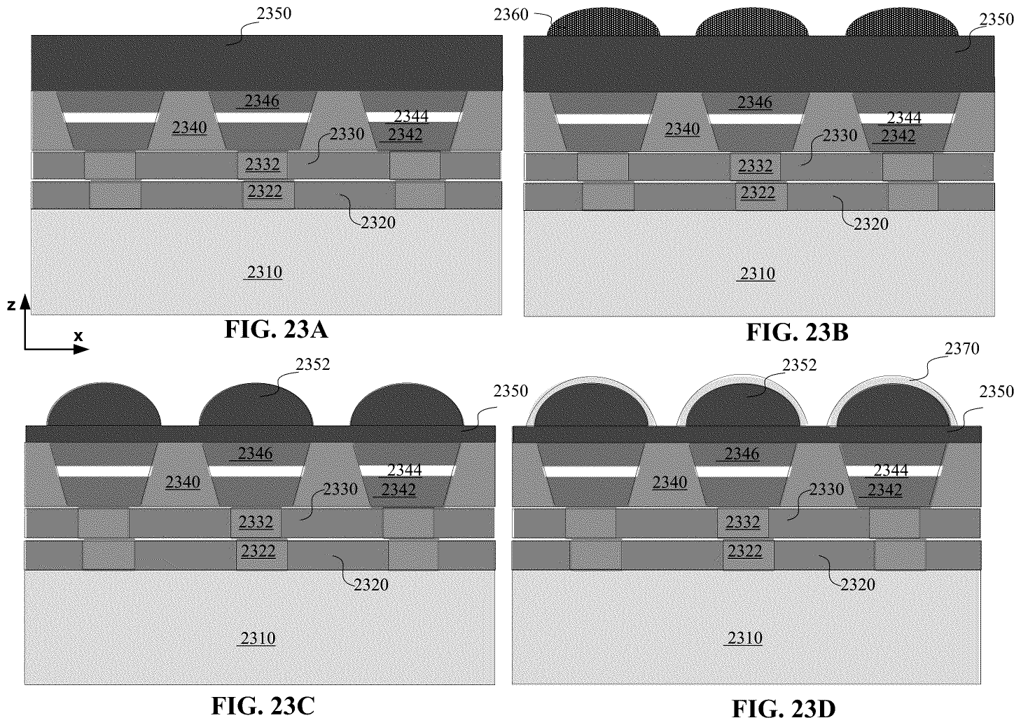

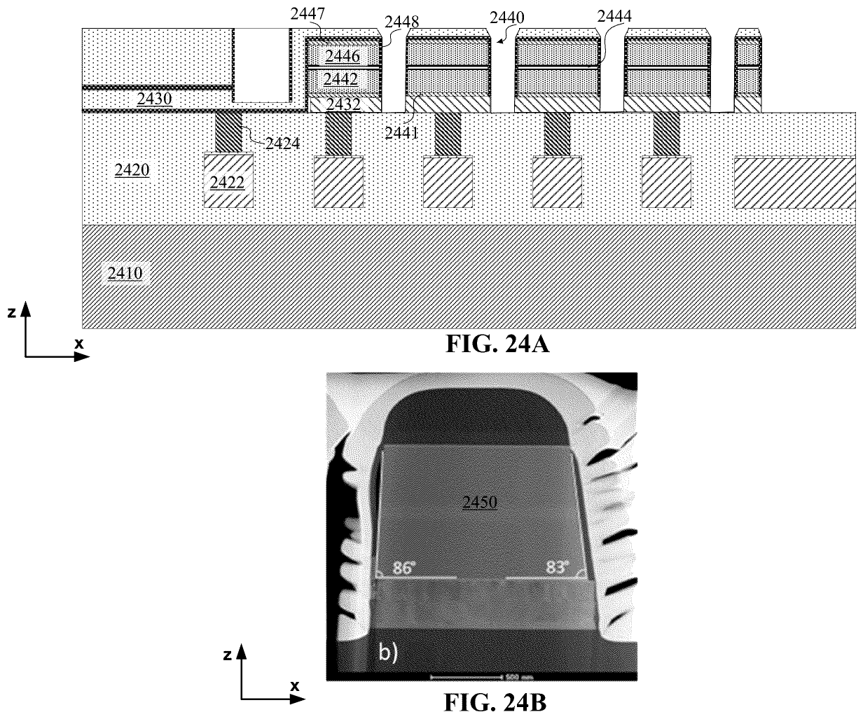

FIGS. 23A-23D illustrate an example of a process of fabricating an example of a micro-LED device including an array of micro-lenses made in a heat-spreading material layer on an array of micro-LEDs according to certain embodiments. FIG. 23A shows a wafer stack including a backplane 2310 and a micro-LED wafer bonded together. The wafer stack may be formed using, for example, techniques described above with respect to FIGS. 8A-12E. For example, the individual mesa structures may be formed before or after the bonding and removal of the substrate of the micro-LED wafer. As illustrated, backplane 2310 (e.g., a CMOS backplane) may have a bonding layer 2320 bonded to an array of micro-LEDs on the micro-LED wafer. Bonding layer 2320 may include a dielectric layer (e.g., including SiO₂) with metal connectors 2322 (e.g., made of copper) formed therein. The micro-LED wafer may include an array of semiconductor mesa structures electrically and/or optically isolated by filling materials 2340 that may include dielectric materials and/or metal materials. Each semiconductor mesa structure may include a first doped (e.g., n-doped or p-doped) semiconductor layer 2342 (e.g., including a III-P or III-N material such as GaN), an active region 2344, and a second doped (e.g., p-doped or n-doped) semiconductor layer 2346. Even though not shown in FIG. 23A, each semiconductor mesa structure may include a sidewall passivation layer, a sidewall reflector, and the like, as described above and below in this disclosure (e.g., with respect to FIGS. 7A, 7B, 11F, 12C, etc.). The micro-LED wafer may also include a bonding layer 2330 that includes electrical contacts 2332 (e.g., made of copper) formed in a dielectric material layer (e.g., a SiN or SiO₂ layer). Bonding layer 2330 may be bonded to bonding layer 2320 of backplane 2310 using hybrid bonding techniques as described above.

A heat-spreading layer 2350 may be deposited on the array of micro-LEDs. As described above, heat-spreading layer 2350 may include a material that may have a high thermal conductivity and a CTE matching the CTEs of the semiconductor materials of the micro-LEDs. The heat-spreading material may also have a high refractive index, such as above 2.0. In some embodiments, the heat-spreading material may include diamond, AN, graphene, and the like. Heat-spreading layer 2350 may have a certain thickness so that the heat generated in, for example, active regions 2344, can be dissipated at a faster rate, without significantly increasing the thickness of the wafer stack. In some embodiments, an electrically conductive material may be used as the heat-spreading layer and a common electrode for the array of micro-LEDs. In some embodiments, a transparent conductive oxide (e.g., ITO) layer may be deposited on the array of micro-LEDs before depositing heat-spreading layer 2350.

FIG. 23B shows that an etch mask 2360 may be formed on heat-spreading layer 2350. Etch mask 2360 may be formed using, for example, a gray-scale photoresist or other techniques. Heat-spreading layer 2350 may be etched using etch mask 2360 to form micro-lenses 2352 in heat-spreading layer 2350 as shown in FIG. 23C. In this way, micro-lenses 2352 may be part of heat-spreading layer 2350, and thus heat-spreading layer 2350 can be thicker to more efficiently conduct the heat generated by the micro-LEDs, without increasing the total thickness of micro-LED-based display. Optionally, antireflection coating 2370 may be deposited on surfaces of micro-lenses 2352 formed in heat-spreading layer 2350 as shown in FIG. 23D to reduce surface reflection and improve light extraction efficiency.

Embodiments may include different combinations of features in view of the description. Certain embodiments are described in the following examples.

In Example 1, a micro-light-emitting diode (micro-LED) device may include a backplane, an array of micro-LEDs bonded to the backplane, a heat-spreading layer formed on the array of micro-LEDs, and an array of micro-lenses on the heat-spreading layer, where the heat-spreading layer is characterized by a thermal conductivity greater than 100 W/(m*K).

Example 2 includes the micro-LED of Example 1, where the heat-spreading layer is characterized by a coefficient of thermal expansion (CTE) matching a CTE of the array of micro-LEDs.

Example 3 includes the micro-LED of Example 1 or 2, where the heat-spreading layer is characterized by the thermal conductivity greater than 1000 W/(m*K).

Example 4 includes the micro-LED of any of Examples 1-3, where the heat-spreading layer is characterized by a refractive index greater than 2.0.

Example 5 includes the micro-LED of any of Examples 1-4, where the array of micro-lenses and the heat-spreading layer include a same material.

Example 6 includes the micro-LED of any of Examples 1-5, where the heat-spreading layer includes diamond, AN, or graphene.

### VII. Lateral Mirror Slope Inversion by Lithography and Etching

As described above, at the light-emitting surface of an LED, such as the interface between the LED and air, incident light with incident angles greater than a critical angle may be reflected back to the LED due to total internal reflection (TIR). Because of the geometry of the LED (e.g., the shape of the mesa structure and the orientation of the sidewall reflector), some light reflected back to the LED may be trapped and eventually be absorbed by the LED. For example, some trapped light may be absorbed by the semiconductor materials to generate electron-hole pairs, which may recombine radiatively or non-radiatively. Some trapped light may be absorbed by metals (e.g., metal contacts or reflectors) at the bottom and/or sidewalls of the LED due to, for example, surface plasmon resonance that may be excited by p-polarized light at the interface between a metal layer and a dielectric layer (e.g., a passivation layer). Because of the high refractive indices of many III-V semiconductor materials (e.g., about 2.4 for GaN, and greater than about 3.0 for GaP, InP, GaInP, and AlGaInP), the critical angle for total internal reflection at the interface between the III-V semiconductor material and an adjacent lower refractive index material (e.g., air or a dielectric) may be small. As such, a large portion of the light emitted in the active region of a III-V material-based LED may be trapped in the LED due to TIR and may eventually be absorbed by the LED. Therefore, the LEE of the micro-LED may be low. In large LEDs, the light extraction efficiency may be improved by using, for example, thin film technology or patterned sapphire substrates with dense, periodic patterns on the substrate surfaces, or rough light emitting surfaces, to randomize the propagation directions of the photons and increase the possibility of the photons being released from the confinement and exiting the mesa structure. However, these techniques may not be used in micro-LEDs with linear dimensions less than, for example, about 5 μm or about 3 μm, due to the small sizes and high aspect ratios (height vs width) of these micro-LEDs. Micro-lenses may be used to extract and collimate light emitted from LEDs to increase the total LEEs (e.g., light with emission angles within ±90°) and the collected LEEs (e.g., light with emission angles within ±18.5°) of LEDs in a near-eye display. However, it is challenging to precisely and repeatably fabricate micro-lenses that have the desired, smooth thickness profiles for small micro-LEDs (e.g., with a width less than about 2 μm), using existing techniques, such as photolithography and dry/wet etching techniques.

During the manufacturing of individual micro-LEDs (pixels of the light sources of a display panel), an important process is the formation of minors on the sidewalls of individual micro-LEDs. The sidewall minor may be used to, for example, avoid optical cross-talk between individual micro-LEDs and increase light extraction efficiency of the micro-LEDs. In some high density micro-LED array fabrication processes where the singulation of the individual micro-LEDs is performed by etching the epitaxial layers after bonding a micro-LED wafer with the epitaxial layers to a backplane wafer, as described above with respect to, for example, FIGS. 11A-11F, the sidewall minors may be formed by filling the trenches between the individual mesa structures with suitable material(s), such as a reflective metal (e.g., Al, Cu, Ag, etc.). In order to form individual mesa structures for individual micro-LEDs, an anisotropic plasma etching process may generally be used to etch trenches in the epitaxial semiconductor layers. It can be difficult to achieve mesa structures with straight (vertical) sidewall, and it can be even more difficult to form mesa structures with sidewalls that are outwardly tilted at a desired angle in the light emitting direction. As such, minors formed on sidewalls of the mesa structures may have reflective surfaces that are tilted inwardly with respect to the mesa structures in the light emitting direction. Therefore, the sidewall mirrors may reflect a large portion of the incident light in directions that are substantially opposite to the light emitting direction of the micro-LEDs. In addition, the inwardly tilted sidewalls of the mesa structures may reduce the emissive apertures of the micro-LEDs. As such, the inwardly tilted sidewalls of the mesa structures may result in reduced light extraction efficiency.

FIG. 24A illustrates an example of a wafer stack including individual mesa structures on a micro-LED wafer that is bonded to a backplane wafer. In the illustrated example, the backplane wafer (e.g., a CMOS backplane) may include a substrate 2410 and drive circuits formed thereon. The drive circuits may include, for example, CMOS circuits (not shown) and a plurality of interconnect layers formed in one or more dielectric material layers 2420. FIG. 24A shows a top metal layer 2422 (e.g., a copper layer or an aluminum layer) and a plurality of vias 2424 (e.g., tungsten vias) in the one or more dielectric material layers 2420. The micro-LED wafer may include an a array of mesa structures 2440 formed by bonding the micro-LED wafer to the backplane wafer, removing the substrate of the micro-LED wafer, and etching the epitaxial layers of the micro-LED wafer from the top. The micro-LED wafer may include an electrode layer 2432 (e.g., a titanium layer) deposited on the epitaxial layers. Electrode layer 2432 may be patterned after the bonding (e.g., after the etching of the epitaxial layers) or may be patterned before the bonding. Even though mesa structures 2440 in FIG. 24A are shown to have vertical sidewalls, the sidewalls of mesa structures 2440 may be tilted inwardly in the z direction due to the etching from the top (in the −z direction).

Each mesa structure 2440 may include a first carrier injection layer 2441 (or a first contact layer), a first barrier layer 2442, an active region 2444 that may include one or more quantum wells, a second barrier layer 2446, and a second carrier injection layer 2447 (or a first contact layer). First carrier injection layer 2441 and second carrier injection layer 2447 may include, for example, GaN or GaAs, and may be oppositely doped and may be used to inject carriers into active region 2444. First barrier layer 2442 and second barrier layer 2446 may have a higher bandgap than the quantum well layers and may be undoped or unintentionally doped. For example, in some embodiments, the barrier layers may include GaN and the quantum well layers may include InGaN. In some embodiments, the barrier layers may include AlGaInP and the quantum well layers may include GaInP. As described above, the sidewalls of the semiconductor mesa structures may be tilted inwardly in the z direction due to etching in the −z direction. A passivation layer 2448 deposited on the sidewalls of the semiconductor mesa structures may also have sidewalls inwardly tilted along the z direction. In some embodiments, passivation layer 2448 may include a dielectric material such as SiN. In some embodiments, one or more oxide layers 2430 may be formed on the passivation layer 2448.

FIG. 24B is a transmission electron microscopy (TEM) image of an example of a mesa structure formed by etching the semiconductor epitaxial layers of a micro-LED wafer as described above with respect to, for example, FIG. 24A. FIG. 24B shows a semiconductor mesa structure 2450 formed by etching the semiconductor epitaxial layers on a substrate in the −z direction. In the illustrated example, sidewalls of semiconductor mesa structure 2450 may not be straight, but may be tilted at an angle, for example, about 83-86° with respect to the x direction, or about, for example, 4-7° with respect to the z direction.

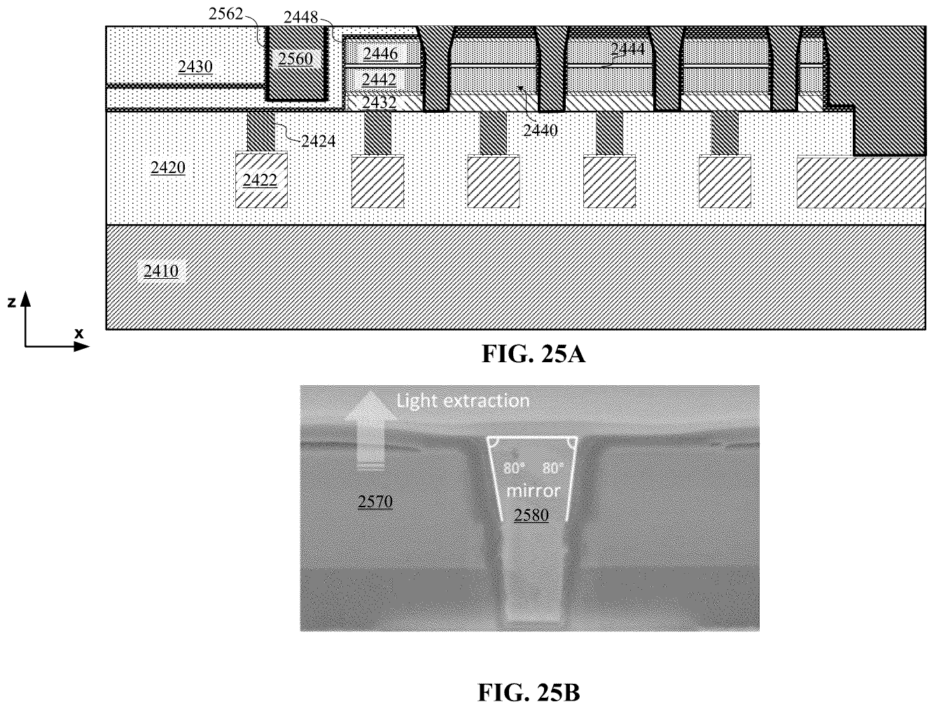

FIG. 25A illustrates an example of a wafer stack including individual mesa structures on a micro-LED wafer that is bonded to a backplane wafer, where gaps between the individual mesa structures are filled with reflective material. The wafer stack shown in FIG. 25A may be made from the wafer stack shown in FIG. 24A after depositing a reflective metal layer 2560 to fill the trenches between mesa structures 2440. Reflective metal layer 2560 may include, for example, Cu, Al, Ag, Ti, a metal alloy, or a combination thereof. For example, in some embodiments, a diffusion barrier layer 2562, such as a Ti layer, may be deposited on the sidewalls (e.g., passivation layer 2448) of the mesa structure, before depositing other material(s) of the reflective metal layer 2560. The reflective surface of the sidewall minor may be at the interface between passivation layer 2448 and reflective metal layer 2560, and thus may tilt inwardly with respect to the mesa structure along the light emitting direction (e.g., z direction).

FIG. 25B is a TEM image of a region of a micro-LED wafer showing that the sidewall mirror for each mesa structure is inwardly tilted with respect to the mesa structure. FIG. 25B shows a reflective metal layer 2580 deposited into trenches between mesa structures 2570 that may include inwardly tilted sidewalls. Due to the shape of mesa structures 2570, the interface between the mesa structure and reflective metal layer 2580 may be tilted towards mesa structures 2570 (inwardly tilted with respect to mesa structures 2570) in the z direction. In the example illustrated in FIG. 25B, the reflective surfaces of reflective metal layer 2580 may be tilted towards mesa structures 2570 at an angle about 80° with respect to the horizontal direction (e.g., x direction) or about 10° with respect to the vertical direction (e.g., the z direction). Thus, the light emitting aperture at the top of mesa structure 2570 may be smaller than the bottom of mesa structure 2570. As a result, a large portion of the light incident on the sidewall minor may be reflected towards the bottom of mesa structure 2570, and may be trapped and absorbed in mesa structure 2570.

According to certain embodiments disclosed herein, the reflective metal layer deposited into the trenches between micro-LED mesa structures may be selectively etched to remove the reflective metal material near the sidewalls of the trenches (and mesa structure), such that the sidewalls of the reflective metal material in the trenches may tilt away from the mesa structures and gaps may be created between the mesa structures and the reflective material. A transparent material (e.g., a dielectric material such as SiN, SiO₂, or Al₂O₃) may be deposited to fill the gaps. As a result, the reflective surface may be at the interface between the transparent material and the reflective metal material, which may tilt away from the mesa structures (outwardly with respect to the mesa structures) along the light emitting direction. Different etching techniques, such as plasma etching, wet etching, or a combination thereof, may be used to achieve different shapes of the reflective surfaces of the mirror. The etching parameters may also be precisely controlled to achieve the desired shape and height of the minor in order to orient it with respect to the mesa structure and the light emitting surface of the micro-LED, such that the aperture of the light emitting surface of the micro-LED may be larger than the bottom portion of the mesa structure of the micro-LED. In this way, the sidewall mirror may reflect a large portion of the incident light towards the light emitting surface, rather than towards the bottom of the mesa structure, thereby improving the light extraction efficiency of the micro-LED.

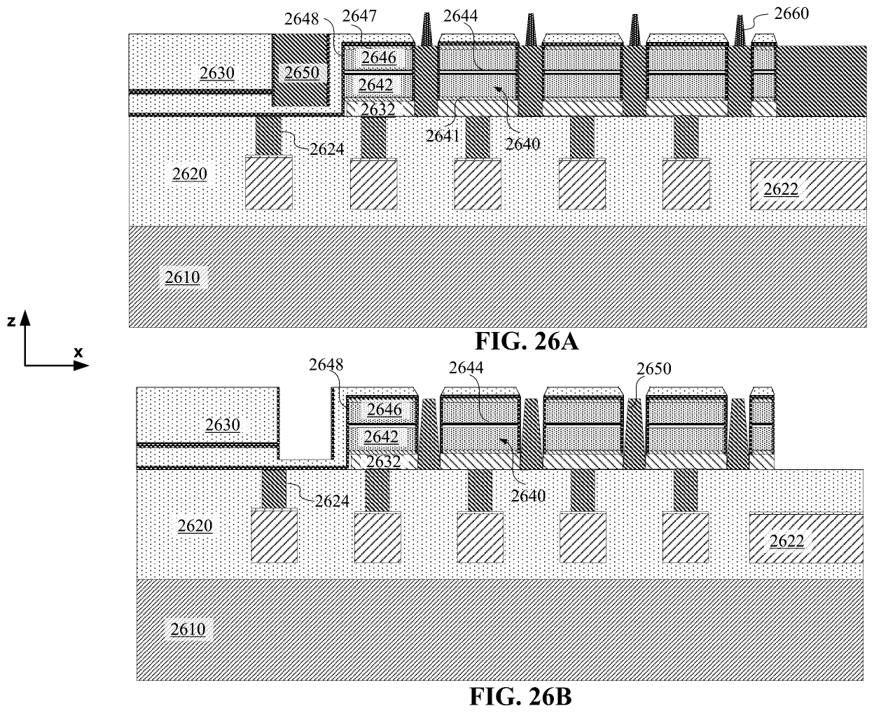

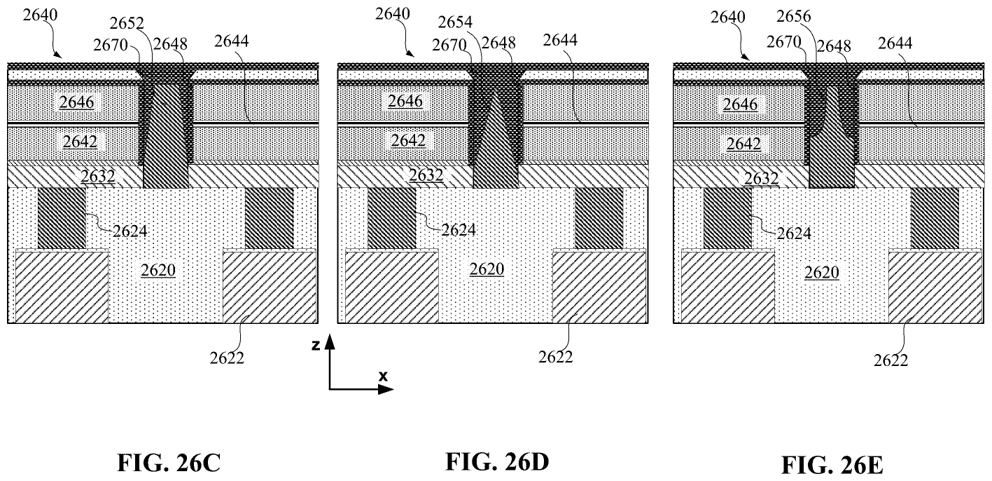

FIGS. 26A and 26B illustrate an example of a process of forming sidewall minors with outwardly tilted reflective surfaces along the light emitting direction of micro-LEDs according to certain embodiments. In the illustrated example, a wafer stack including individual mesa structures on a micro-LED wafer may be bonded to a backplane wafer (e.g., a CMOS backplane). The backplane wafer may include a substrate 2610 and drive circuits formed thereon. The drive circuits may include, for example, CMOS circuits (not shown) and a plurality of interconnect layers formed in one or more dielectric material layers 2620.

FIG. 26A shows a top metal layer 2622 (e.g., a copper layer or an aluminum layer) and a plurality of vias 2624 (e.g., tungsten vias) in the one or more dielectric material layers 2620. The micro-LED wafer may include an array of mesa structures 2640 formed by bonding the micro-LED wafer to the backplane wafer, removing the substrate of the micro-LED wafer, and etching the epitaxial layers of the micro-LED wafer from the top. The micro-LED wafer may include an electrode layer 2632 (e.g., a titanium layer) deposited on the epitaxial layers. Electrode layer 2632 may be patterned after the bonding (e.g., after the etching of the epitaxial layers) or may be patterned before the bonding. Even though mesa structures 2640 in FIG. 26A are shown to have vertical sidewalls, the sidewalls of mesa structures 2640 may be tilted inwardly in the z direction due to the etching from the top (in the −z direction).

Each mesa structure 2640 may include a first carrier injection layer 2641 (or a first contact layer), a first barrier layer 2642, an active region 2644 that may include one or more quantum wells, a second barrier layer 2646, and a second carrier injection layer 2647 (or a second contact layer). First carrier injection layer 2641 and second carrier injection layer 2647 may include, for example, GaN or GaAs, and may be oppositely doped and may be used to inject carriers into active region 2644. First barrier layer 2642 and second barrier layer 2646 may have a higher bandgap than the quantum well layers and may be undoped or unintentionally doped. For example, in some embodiments, the barrier layers may include GaN and the quantum well layers may include InGaN. In some embodiments, the barrier layers may include AlGaInP and the quantum well layers may include GaInP. As described above, the sidewalls of the semiconductor mesa structures may be tilted inwardly in the z direction due to etching in the −z direction. A passivation layer 2648 deposited on the sidewalls of the semiconductor mesa structures may also have sidewalls inwardly tilted along the z direction. In some embodiments, passivation layer 2648 may include a dielectric material such as SiN. In some embodiments, one or more oxide layers 2630 may be formed on passivation layer 2648.

After forming passivation layer 2648 on sidewalls of the mesa structures, a reflective material 2650 (e.g., including one or more metal or metal alloy layers) may be deposited into the gaps between mesa structures 2640. Reflective material 2650 may include, for example, Cu, Al, Ag, Ti, or a combination thereof. Due to the shape of mesa structures 2640 formed by etching, the interface between reflective material 2650 and mesa structures 2640 (e.g., passivation layer 2648) may have an undesired orientation as discussed above. To modify the orientation of the reflective surfaces of the sidewall minors, an etch mask 2660 may be formed on the reflective material 2650 between mesa structures 2640 and may be used to selectively etch reflective material 2650. Etch mask 2660 may include an array of structures that cover center regions of reflective material 2650 between mesa structures 2640. A dry or wet etching may be performed using etch mask 2660 to remove portions of reflective material 2650 at the interfaces between mesa structures 2640 and reflective material 2650. The etching process may more preferentially etch metal or metal alloy materials than dielectric materials (e.g., SiN or SiO₂). The center regions of the reflective material 2650 between mesa structures 2640 protected by etch mask 2660 may not be etched, whereas reflective material 2650 adjacent to mesa structures 2640 (e.g., passivation layer 2648 of mesa structures 2640) and not protected by etch mask 2660 may be at least partially removed by the etching to form gaps between reflective material 2650 and mesa structures 2640.

FIG. 26B shows that, after the etching using etch mask 2660, reflective material 2650 in regions not protected by etch mask 2660 may be at least partially removed, such that gaps may be formed between reflective material 2650 and mesa structures 2640. As shown in FIG. 26B, after the etching, reflective material 2650 between mesa structures 2640 may have a larger lateral area at the bottom and may have smaller lateral area at the top. Different etching processes (e.g., dry or wet etching processes) and/or different etching process parameters may result in reflective mirrors of different shapes. In one example, the remaining reflective material 2650 between two adjacent mesa structures 2640 may have a cross-sectional shape of a trapezoid in an x-z plane. A transparent material (e.g., a dielectric material such as an oxide or a nitride) may be deposited to fill gaps between the remaining reflective material 2650 and mesa structures 2640 (e.g., passivation layer 2648 of mesa structures 2640).

FIG. 26C illustrates an example of a region of the wafer stack after depositing a transparent material 2670 (e.g., a dielectric material such as an oxide or a nitride) into gaps between the remaining reflective material 2650 and mesa structures 2640 according to certain embodiments. In the example shown in FIG. 26C, the remaining reflective material 2650 may form a reflective structure 2652 (e.g., a minor) having a cross-sectional shape of a trapezoid in an x-z plane. Transparent material 2670 filling the gaps between reflective structure 2652 and mesa structures 2640 may include, for example, SiN or SiO₂. In some embodiments, transparent material 2670 may include a same material as the material of passivation layer 2648, such as SiN. A new mesa structure of each micro-LED formed by mesa structure 2640 (including passivation layer 2648) and transparent material 2670 on the sidewalls of mesa structure 2640 may have a larger lateral area at the top (in z direction) and a smaller lateral area at the bottom of the new mesa structure. The interface between transparent material 2670 and reflective structure 2652 may be the reflective surface of reflective structure 2652. As shown in FIG. 26C, the reflective surface of reflective structure 2652 may be tilted away from mesa structure 2640 (outwardly with respect to mesa structure 2640) in the vertical (z) direction, and thus may reflect a large portion of incident light towards the light emitting surface of the micro-LED. As such, the light extraction efficiency of the resultant micro-LED may be higher than the micro-LEDs shown in, for example, FIGS. 25A and 25B.

FIG. 26D illustrates an example of a region of the wafer stack after depositing transparent material 2670 (e.g., a dielectric material such as an oxide or a nitride) into gaps between the remaining reflective material 2650 and mesa structures 2640. In the example shown in FIG. 26D, the remaining reflective material 2650 may form a reflective structure 2654 having a cross-sectional shape of a triangle in an x-z plane, due to a different etching process and/or different etching process parameters used to etch reflective material 2650. As described above, transparent material 2670 filling the gaps between reflective structures 2654 and mesa structures 2640 may include, for example, SiN or SiO₂. In some embodiments, transparent material 2670 may include a same material as the material of passivation layer 2648, such as SiN. A new mesa structure of each micro-LED formed by mesa structure 2640 (including passivation layer 2648) and transparent material 2670 on the sidewalls of mesa structure 2640 may have a larger lateral area at the top (in z direction) and a smaller lateral area at the bottom of the new mesa structure. The interface between transparent material 2670 and reflective structure 2654 may be the reflective surface of reflective structure 2654. As shown in FIG. 26D, the reflective surface of reflective structure 2654 may be tilted away from mesa structure 2640 (outwardly with respect to mesa structure 2640) in the vertical (z) direction, and thus may reflect a large portion of incident light towards the light emitting surface of the micro-LED. As such, the light extraction efficiency of the resultant micro-LED may be higher than the micro-LEDs shown in, for example, FIGS. 25A and 25B.

FIG. 26E illustrates another example of a region of the wafer stack after depositing transparent material 2670 (e.g., a dielectric material such as an oxide or a nitride) into gaps between the remaining reflective material 2650 and mesa structures 2640. In the example shown in FIG. 26E, the remaining reflective material 2650 after etching may form a reflective structure 2656 having curved surfaces, due to a different etching process and/or different etching process parameters used to etch reflective material 2650. The curved surfaces of reflective structure 2656 may have, for example, a hyperbolic shape. As described above, transparent material 2670 filling the gaps between reflective structures 2656 and mesa structures 2640 may include, for example, SiN or SiO₂. In some embodiments, transparent material 2670 may include a same material as the material of passivation layer 2648, such as SiN. A new mesa structure of each micro-LED formed by mesa structure 2640 (including passivation layer 2648) and transparent material 2670 on the sidewalls of mesa structure 2640 may have a larger lateral area at the top (in z direction) and a smaller lateral area at the bottom of the new mesa structure. The interface between transparent material 2670 and reflective structure 2656 may be the reflective surface of reflective structure 2656. As shown in FIG. 26E, the reflective surface of reflective structure 2656 may be nonlinearly tilted away from mesa structure 2640 (outwardly with respect to mesa structure 2640) in the vertical (z) direction, and thus may reflect (and may also reflectively collimate) a large portion of incident light towards the light emitting surface of the micro-LED. As such, the light extraction efficiency of the resultant micro-LED may be higher than the micro-LEDs shown in, for example, FIGS. 25A and 25B.

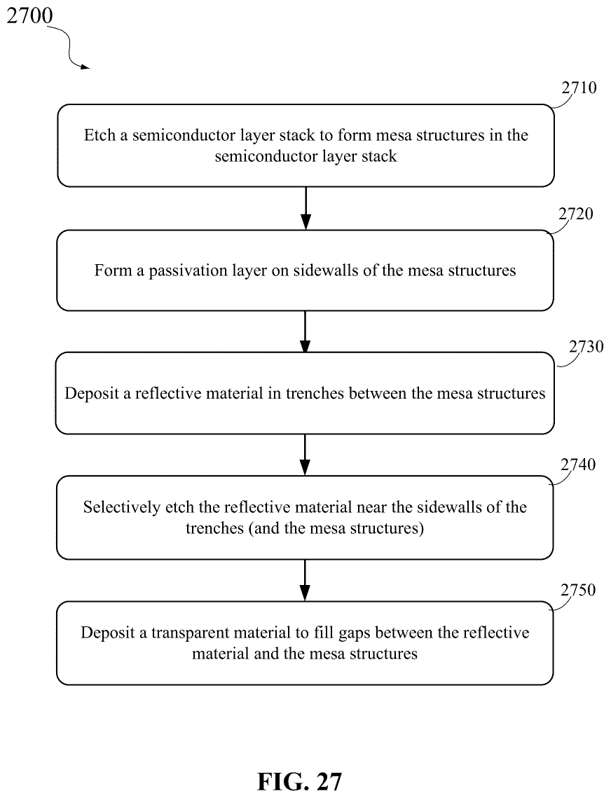

FIG. 27 includes a flowchart 2700 illustrating an example of a process for fabricating micro-LED sidewall reflectors according to certain embodiments disclosed herein. Operations described in flowchart 2700 are for illustration purposes only and are not intended to be limiting. For example, the operations of flowchart 2700 may be performed in any suitable order, not necessarily in the order depicted in FIG. 27. Further, in various implementations, modifications may be made to flowchart 2700 to add additional operations, omit some operations, merge some operations, simultaneously perform some operations, or split an operation.

Operations at block 2710 may include etching a semiconductor layer stack to form semiconductor mesa structures in the semiconductor layer stack. The semiconductor layer stack may be bonded to a backplane wafer that includes drive circuits. The semiconductor layer stack may be formed by growing a plurality of epitaxial layers grown on a substrate (e.g., a sapphire, Si, or GaAs substrate), or a buffer layer on the substrate; bonding the semiconductor layer stack on the substrate to the backplane wafer, and removing the substrate after the bonding to expose the plurality of epitaxial layers. The epitaxial layers may include, for example, a p-type doped layer (e.g., a hole injection layer), an n-type doped layer (e.g., an electron injection layer), and an active region including one or more quantum wells. Each quantum well may include a quantum well layer sandwiched by two barrier layers for trapping free carriers. The etching may include a anisotropic etching process (e.g., plasma etching or reactive ion beam etching) that may preferentially etch the semiconductor epitaxial layers in the vertical direction (surface-normal direction of the semiconductor epitaxial layers). After the etching, individual semiconductor mesa structures may be formed in the semiconductor layer stack. Due to the etching from the top (opposite to the light emitting direction), the top of each semiconductor mesa structure may have a size smaller than a bottom of each semiconductor mesa structure. As such, each semiconductor mesa structure may have sidewalls that are tilted inwardly in the light emitting direction.

Operations in block 2720 may include forming a passivation layer on the sidewalls of the semiconductor mesa structures. The passivation layer may include, for example, an oxide (e.g., Al₂O₃ or SiO₂) or a nitride (e.g., SiN). The passivation layer may be deposited on the sidewalls of the semiconductor mesa structures conformally (e.g., using atomic layer deposition techniques) or non-conformally (e.g., using chemical or physical vapor deposition techniques).

Operations in block 2730 may include depositing a reflective material in trenches between the semiconductor mesa structures. The reflective material may include a metal (e.g., Al, Cu, Ag, Ti, etc.), a metal alloy, or a combination thereof. In one example, depositing the reflective material may include depositing a barrier layer (e.g., including Ti) on the passivation layer and then depositing a metal (e.g., Cu or Al) in the gaps between the semiconductor mesa structures.

Operations in block 2740 may include selectively etching the reflective material near the sidewalls of the trenches (and the mesa structures), for example, using an etch mask and dry or wet etching processes. The etch mask may be patterned to cover a center region of the reflective material between adjacent semiconductor mesa structures, while exposing the reflective material near the sidewalls of the semiconductor mesa structures. The etching process and etching parameters may be selected to achieve a desired shape of the reflective surface. The etching process may include dry etching, wet etching, or a combination thereof. For example, isotropic wet etching may be used to form reflective surfaces with a curved shape (e.g., a hyperbolic shape), such that the reflective surface may reflectively collimate the light emitted in the semiconductor mesa structure.

Operations in block 2750 may include depositing a transparent material to fill gaps between the reflective material and the mesa structures. The transparent material may include a dielectric material such as an oxide (e.g., Al₂O₃ or SiO₂) or a nitride (e.g., SiN), and may or may not be the same material of the passivation layer. The interface between the transparent material and the remaining reflective material may be the reflective surface of the sidewall reflector for each micro-LED.

Even though not shown in FIG. 27, in some embodiments, the process may also include, for example, forming an array of micro-lenses on the semiconductor mesa structures to further improve the light extraction efficiency and collimate the emitted light beam to improve the collected light extraction efficiency.

Embodiments may include different combinations of features in view of the description. Certain embodiments are described in the following examples.

In Example 1, a method of fabricating a micro-LED device may include etching a semiconductor layer stack to form mesa structures in the semiconductor layer stack, forming a passivation layer on sidewalls of the mesa structures, depositing a reflective material in trenches between the mesa structures, selectively etching the reflective material near the sidewalls of the mesa structures, and depositing a transparent material to fill gaps between the reflective material and the mesa structures.

Example 2 includes the method of Example 1, wherein the reflective material includes a metal, a metal alloy, or a combination thereof.

Example 3 includes the method of Example 1 or 2, wherein selectively etching the reflective material near the sidewalls of the mesa structures includes forming an etch mask on the reflective material in the trenches between the mesa structures, and etching the reflective material by dry or wet etching.

Example 4 includes the method of any of Examples 1-3, wherein the transparent material and the passivation layer include a same material.

Example 5 includes the method of any of Examples 1-4, wherein the transparent material includes an oxide or a nitride.

Example 6 includes the method of any of Examples 1-5, wherein selectively etching the reflective material near the sidewalls of the mesa structures forms a reflective structure having a surface that is tilted away from an adjacent mesa structure in a light emitting direction.

Example 7 includes the method of any of Examples 1-6, wherein selectively etching the reflective material near the sidewalls of the mesa structures forms a reflective structure having a curved surface that is capable of at least partially collimate light emitted in the mesa structure.

Example 8 includes the method of any of Examples 1-7, wherein the semiconductor layer stack includes a p-type semiconductor layer, an n-type semiconductor layer, and an active region between the p-type semiconductor layer and the n-type semiconductor layer.

Example 9 includes the method of any of Examples 1-8, wherein the method further comprises bonding a micro-LED wafer that includes the semiconductor layer stack on a substrate to a backplane wafer, and removing the substrate to expose the semiconductor layer stack.

In Example 10, a micro-LED device may include a plurality of micro-LEDs, each micro-LED including a semiconductor mesa structure with sidewalls inwardly tilted in a light emitting direction of the micro-LED, a reflector surrounding the semiconductor mesa structure and characterized by a reflective surface tilted away from the semiconductor mesa structure in the light emitting direction of the micro-LED, and one or more dielectric materials filling regions between the semiconductor mesa structure and the reflector.

Example 11 includes the micro-LED device of Example 10, wherein the one or more dielectric materials include an oxide or a nitride.

Example 12 includes the micro-LED device of Example 10 or 11, wherein the one or more dielectric materials include a passivation material deposited on the sidewalls of the semiconductor mesa structure.

Example 13 includes the micro-LED device of any of Examples 10-12, wherein the reflector includes a metal, a metal alloy, or a combination thereof.

Example 14 includes the micro-LED device of any of Examples 10-13, wherein the semiconductor mesa structure includes a p-type semiconductor layer, an n-type semiconductor layer, and an active region between the p-type semiconductor layer and the n-type semiconductor layer.

Example 15 includes the micro-LED device of any of Examples 10-14, wherein the reflective surface is curved to at least partially collimate light emitted by the semiconductor mesa structure.

Example 16 includes the micro-LED device of any of Examples 10-15, wherein the micro-LED is configured to emit red, green, or blue light.

Example 17 includes the micro-LED device of any of Examples 10-16, wherein a pitch of the plurality of micro-LEDs is less than 10 μm or less than 5 μm.

Example 18 includes the micro-LED device of any of Examples 10-17, wherein the micro-LED device further includes a backplane die bonded to the plurality of micro-LEDs, the backplane die including drive circuits for controlling the plurality of micro-LEDs.

### VIII. Synchronized ELVDD Tracking for μOLED Display

In high luminance, high resolution μOLED display, due to the high current and the resistance of the electrical interconnects (e.g., traces) for electroluminescent driving voltage (ELVDD), ELVDD may drop from the power source to the pixels in the active area. This may cause the currents flowing through the μOLEDs to be different from the desired values and different on different rows even if the display data is the same for pixels on different rows, which may lead to poor display quality such as lower brightness and/or lower brightness uniformity. In some implementations, the ELVDD may be tracked at regions near the active area using a display drive integrated circuit (DDIC), such that the reference voltage (Vref) and/or the signal voltage (Vsig) can be changed accordingly to match the ELVDD drop, thereby compensating the voltage drop in ELVDD which may otherwise cause luminance drop. The DDIC may track the ELVDD in real-time and compensate the ELVDD drop in real-time by changing the Vref and/or Vsig based on the tracked ELVDD.

However, the ELVDD tracking path can be noisy due to interference from multiple signals, and thus the sensed ELVDD may be different from the actual ELVDD. In addition, there may be delay between the time that the ELVDD is sensed and the time that the Vref/Vsig signal is adjusted in the DDIC. As such, the sensed ELVDD level may be different from the actual ELVDD level when the Vref or Vsig signal is applied, and different ELVDDs may be used for Vref and Vsig compensation. Thus, the compensation value used for Vref and Vsig compensation in each one horizontal line (1H) time period may not be proper, which may cause display artifacts such as vertical bright lines (mura defects).

According to certain embodiments disclosed herein, the ELVDD may be sensed once in each horizontal line (1H) time period, and the result may be applied to Vref/Vsig compensation for the horizontal line time period. A sample and hold circuit may be used for sensing and storing the ELVDD value for use in each horizontal line time period. The sensing may be synchronized with the horizontal line timing using a synchronized clock signal, where the edges of the clock signal for ELVDD sensing with respect to the horizontal line timing can be selected such that the DDIC may sense a stabilized ELVDD value. As such, the correct ELVDD may be used to adjust the Vref and Vsig levels in each 1H time period, and thus the OLED pixels may emit light with the appropriate brightness and brightness uniformity.

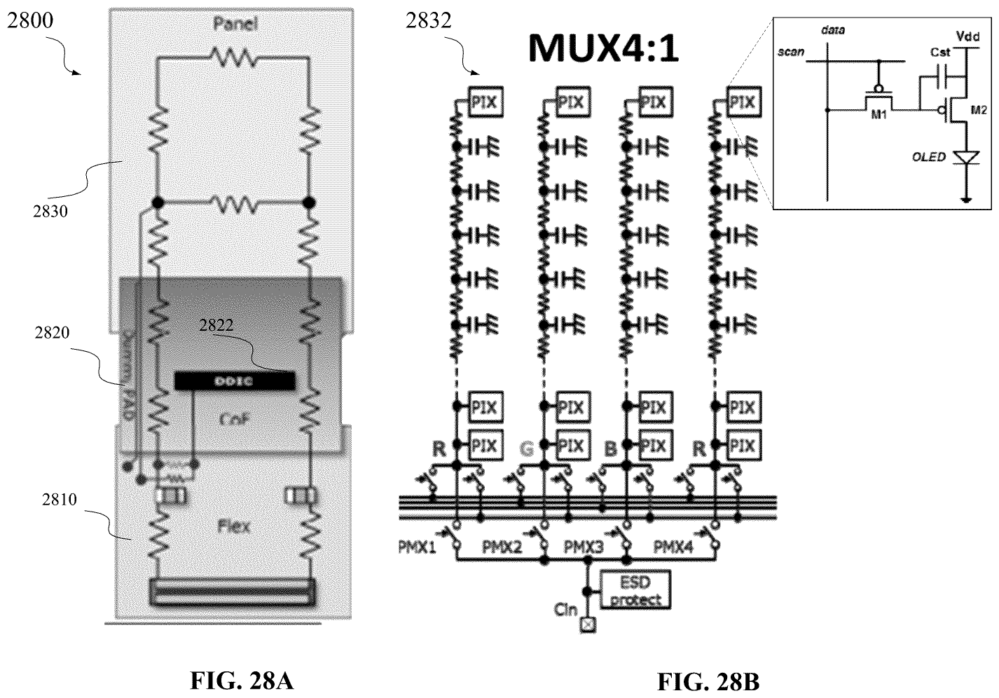

FIG. 28A illustrates IR drop in an example of an OLED display 2800. In the illustrated example, OLED display 2800 may include a flexible printed circuit board (Flex) 2810, a chip on flex (COF) 2820, and a display panel 2830, where COF 2820 may be coupled to both Flex 2810 and display panel 2830. Flex 2810 may include traces in a flexible substrate (rather than the typical printed circuit board) and may be used to deliver, for example, power or some control signal to COF 2820 and display panel 2830. Flex 2810 may also include some electrical components such as decoupling capacitors. COF 2820 may also include traces in a flexible film and may include microchips or dies, such as one or more display driver integrated circuits (DDICs) 2822, directly mounted on the flexible film. Display panel 2830 may include a two-dimensional array of pixel drive circuits (e.g., 2T1C pixel driving circuits) that may control operations of a two-dimensional array of light emitters (e.g., OLEDs or μOLEDs).

As shown in FIG. 28A, power, control, and/or data signals may need to be delivered through traces on Flex 2810 and COF 2820 to the pixel drive circuits. The traces may have resistance that may cause IR drops on the path. In high luminance, high resolution display panels, both the current (I) on the traces and the resistance of traces may be high, and thus the voltage drop on the path may be high. The current used by the display panel may vary over time due to, for example, difference in the display content and brightness, and the high update rate of the display. As such, the voltage drop on the path may vary and thus the voltage for driving the pixel drive circuits may vary. Thus, it can be difficult to achieve the desire brightness and/or the desired brightness uniformity across the display panel.

FIG. 28B illustrates an example of a portion 2832 of an OLED display panel that includes demultiplexers (DMUXes) to reduce the number of pads. As shown in FIG. 28B, each column (or row) of the OLED display panel may include a plurality of pixels or sub-pixels that are connected to a same column line, which may have distributed resistance and capacitance along the path. Thus, the voltage level of the drive signal on the column line may drop gradually and may be the lowest at the pixel furthest from the driver circuits (e.g., the DDIC). In high resolution displays, such as micro-displays for near-eye display or head-mounted display where the area of the display panel is small but the number of pixels of the display panel is high, the pitch of the pixels may be very small, such as about tens of microns or a few microns. Each pixel (a color pixel) may include multiple monochromatic sub-pixels, such as red, green, and blue sub-pixels. Thus, for a display panel with 2,000 pixels on each row, 6000 column lines may be needed. It can be difficult for the DDIC and COF to accommodate dedicated pins and/or pads for each column line (or row) of the two-dimensional array of pixels of the display panel. In some implementations, demultiplexers may need to be used to drive multiple adjacent columns of pixels (or sub-pixels) using a same DDIC pin and pad. As such, in each horizontal line time period, a DDIC pin may be switched to send data to multiple columns. In the example shown in FIG. 28B, a 1:4 demultiplexer (DMUX) may be used to drive 4 columns of sub-pixels using one DDIC pin, four display data values may be sent from the DDIC pin at different time in each horizontal line time period, and the DMUX may selectively connect the four column lines to the DDIC pin at different time in each horizontal line time period to receive the corresponding display data values. The four columns of sub-pixels driven by a same DDIC pin may be used to drive light emitters that emit the same or different colors.

In the illustrated example, each pixel drive circuit may be a 2T1C pixel drive circuit that includes two transistors and one capacitor. In other implementations, different pixel drive circuits may be used. In the 2T1C pixel drive circuit shown in FIG. 28B, in the data write period, pixels on a line may be selected by a scan signal, which may turn on transistor M1 to receive reference (e.g., reset) and display data from the data line (e.g., column line). The reference and display data may be used to store an appropriate display drive signal in a storage capacitor Cst. In the emission period, an emission control signal may be applied to a emission control switch (not shown, which may be between Vdd and the drain of current drive transistor M2 and may be shared by two or more pixels) to enable the current drive transistor M2, where the current of current drive transistor M2 may be controlled by the display drive signal stored in a storage capacitor Cst.

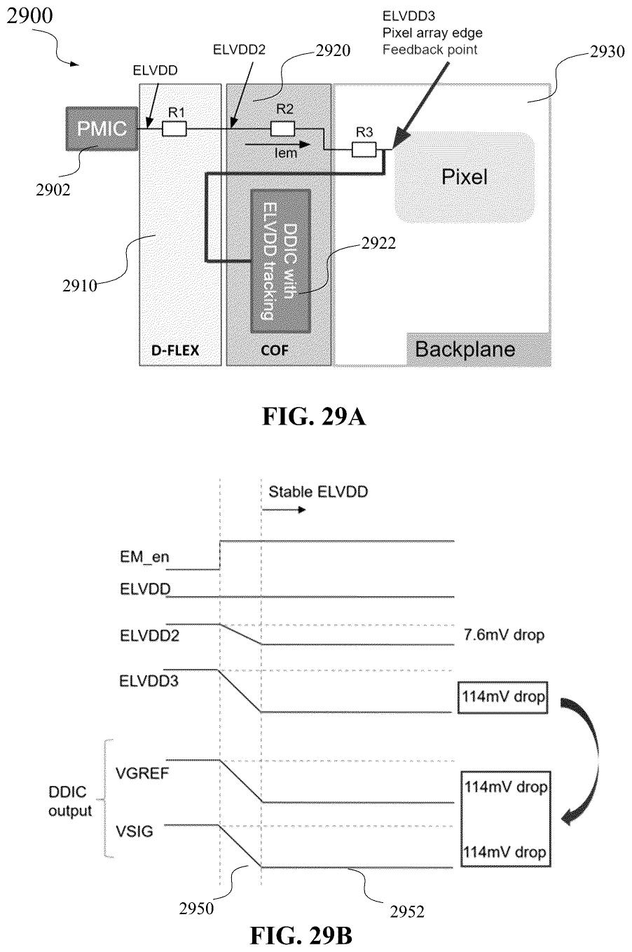

FIG. 29A illustrates an example of an OLED display 2900 that includes circuits for tracking supply voltage drop. OLED display 2900 may be a simplified model of OLED display 2800. As illustrated, OLED display 2900 may include a Flex 2910, a COF 2920, and a display panel 2930, where COF 2920 may be coupled to both Flex 2910 and display panel 2930 using, for example, contact pads or traces. Flex 2910 may include traces in a flexible substrate and may be used to deliver, for example, power (e.g., supply voltage) from a power management integrated circuit (PMIC) 2902 to COF 2920 and display panel 2930. The resistance of the traces on Flex 2910 for power delivery may be modeled using a resistor R1. COF 2920 may also include traces in a flexible film and may include microchips or dies, such as one or more DDICs 2922, directly mounted on the flexible film. The resistance of the traces for power delivery on COF 2920 may be modeled using a resistor R2. Display panel 2930 may include a two-dimensional array of pixel drive circuits (e.g., 2T1C pixel driving circuits) that may control operations of a two-dimensional array of light emitters (e.g., OLEDs). The connection between COF 2920 and display panel 2930 and the traces on display panel 2930 for power distribution to pixels may also be resistive. The resistance of the interconnects between COF 2920 and the pixel array edge of display panel 2930 may be modeled using a resistor R3.

In the illustrated example, the power supply output from PMIC 2902 may be at a level ELVDD at the input edge of Flex 2910, the power supply level at the input edge of COF 2920 may be reduced to ELVDD2, and the power supply level at the pixel array edge of display panel 2930 may be reduced to ELVDD3. DDIC 2922 may include ELVDD tracking capability and may sense ELVDD3 at the pixel array edge of display panel 2930. The sensed ELVDD may be used to adjust the reference signals and data signals accordingly so that the desired currents may be provided to the light emitters by the pixel drive circuits (e.g., 2T1C pixel driving circuits) that are controlled by ELVDD, reference signals, and data signals.

FIG. 29B shows examples of supply voltage drop at different locations of an OLED display. FIG. 29B shows a switching period 2950 and a stabilized period 2952 of an emission time window. When the emission is enabled, the display may be in switching period 2950, where the drive current drawn by the pixels may increase until it is stabilized, and thus the supply level may drop due to IR drop until the drive current is stabilized. In the illustrated example, when the emission enable signal EM_en is set to high, even if the supply level from the PMIC is stable, ELVDD2 at the input edge of COF 2920 may drop by, for example, 7.6 mV, while ELVDD3 at the pixel array edge of display panel 2930 may drop by, for example, about 114 mV. Therefore, to provide the desired current to the light emitter, the control signal output by the DDIC, such as the reference signal VGREF and data signal VSIG, may need to be reduced by similar amount (e.g., about 114 mv).

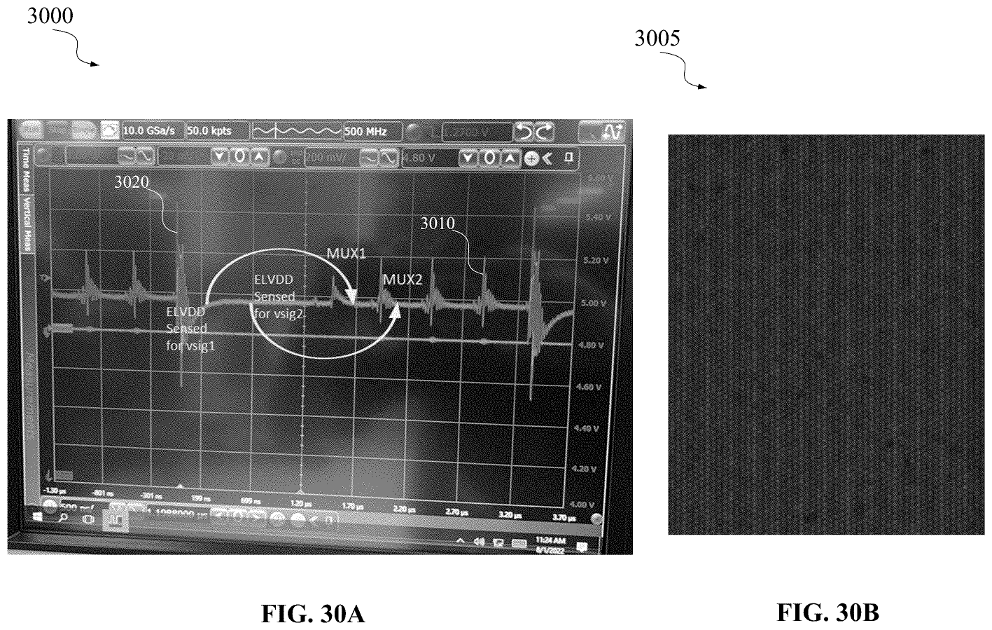

FIG. 30A includes a diagram 3000 illustrating an example of ELVDD tracking and compensation in an example of a display panel that uses DMUXes. In the illustrated example, the DDIC may track the ELVDD in real-time and compensate the ELVDD drop in real-time by changing the Vref and/or Vsig signals based on the tracked ELVDD. A curve 3010 shows an example of the tracked ELVDD and a curve 3020 shows the horizontal line timing. As illustrated, the sensed ELVDD signal can be noisy due to the interference from multiple signals, and thus may be different from the actual ELVDD. In addition, there may be delay between the time that the ELVDD is sensed and the time that the Vref/Vsig signal is adjusted in the DDIC. As such, the sensed ELVDD level may be different from the actual ELVDD level when the Vref or Vsig signal is applied, and different ELVDD levels may be used for Vref and Vsig compensation. In the example shown in FIG. 30A, the sensed ELVDD for compensating Vsig1 (data signal for the first column of the four columns sharing a DDIC pin) may be lower than the sensed ELVDD for compensating Vsig2 (data signal for the second column of the four columns sharing a DDIC pin). Thus, the compensation values used for the Vref and Vsig compensation in each horizontal line (1H) time period may be different and may include various errors. As a result, the Vref and Vsig signals may be incorrectly compensated, which may cause display artifacts such as vertical bright lines (mura defects).

FIG. 30B includes an image 3005 illustrating an example of the mura effect caused by improper ELVDD values used for reference voltage and/or signal voltage compensation. As shown, the brightness of image 3005 may not be uniform, and image 3005 may include many vertical bright lines.

According to certain embodiments disclosed herein, to reduce the artifacts described above, the ELVDD may be sensed once in each horizontal line (1H) time period, and the sensed result may be used for Vref/Vsig compensation for the horizontal line time period. A sample and hold circuit may be used for sensing and storing the ELVDD value for use in the horizontal line time period. The sensing may be synchronized with the horizontal line timing using a synchronized clock signal. The edges of the clock signal for ELVDD sensing with respect to the horizontal line timing can be selected such that the DDIC may sense a stabilized ELVDD value, rather than in the switching period. As such, an appropriate ELVDD value may be used to adjust the Vref and Vsig levels in each 1H time period, and thus the OLED pixels may emit light with the appropriate brightness and brightness uniformity.

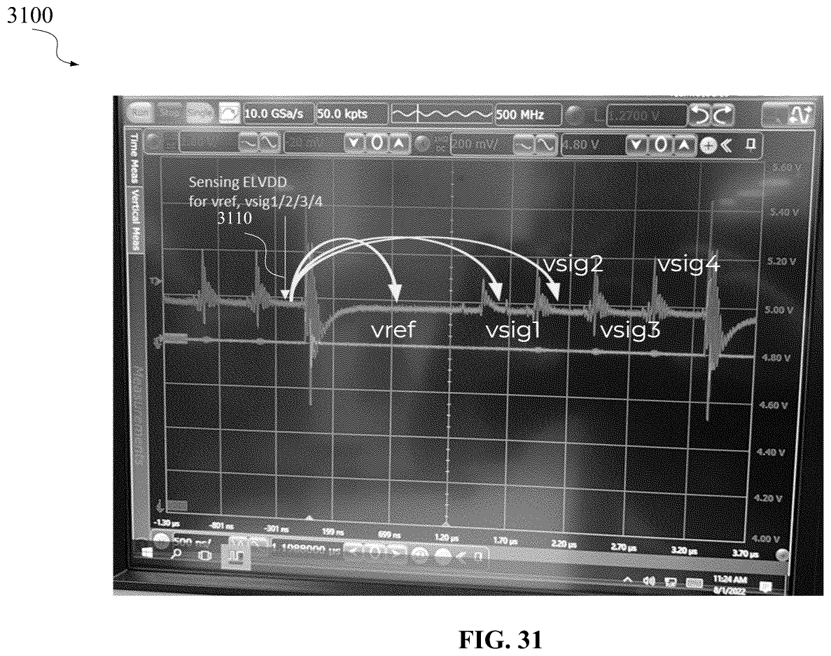

FIG. 31 includes a diagram 3100 illustrating an example of ELVDD tracking and compensation in an OLED display according to certain embodiments. In the illustrate example, in each horizontal line time period, ELVDD is sensed once at a time instant 3110 (e.g., at the end of a horizontal line time period) when the ELVDD is relatively stable (e.g., not in the switching period). The sensed value may be held and used to compensate the reference voltage level and the data drive signal voltage levels in the horizontal line time period or the next horizontal line time period. In embodiments where 1:4 DMUXes are used as described above with respect to, for example, FIG. 28B, the data drive signals from a DDIC pin in each horizontal line time period may include Vsig 1 (data signal for the first column of the four columns sharing the DDIC pin), Vsig2 (data signal for the second column of the four columns sharing the DDIC pin), Vsig3 (data signal for the third column of the four columns sharing the DDIC pin), and Vsig4 (data signal for the fourth column of the four columns sharing the DDIC pin).

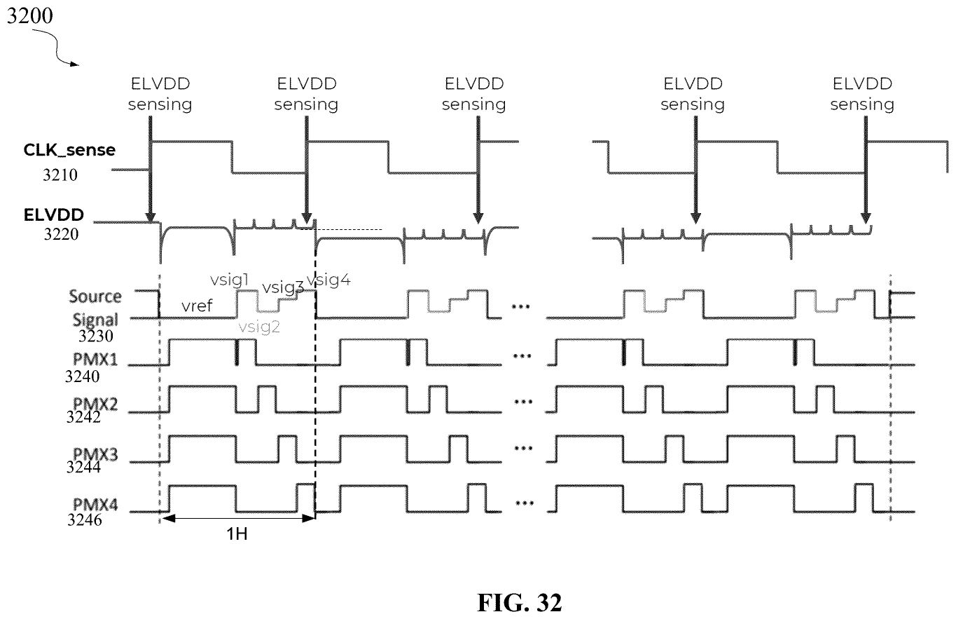

FIG. 32 includes an example of a timing diagram 3200 illustrating an example of sensing ELVDD once in each horizontal line time period using a sensing clock signal 3210 that is synchronized with the horizontal line timing according to certain embodiments Timing diagram 3200 shows signals for controlling the display drive circuits of an OLED display panel shown in FIG. 28B, and the measured ELVDD level in a waveform 3220. The signals for controlling the display drive circuits may include a source signal shown by a waveform 3230, and DMUX switch control signals PMX1 (shown by a waveform 3240), PMX2 (shown by a waveform 3242), PMX3 (shown by a waveform 3244), and PMX4 (shown by a waveform 3246).

At the beginning of each horizontal line time period (1H), the DDIC may first send a Vref signal through a source signal driver shared by multiple (e.g., 4 in the illustrated example) column lines, and send DMUX switch control signals to turn on the DMUX switches for the four column lines, such that the Vref signal may be send to all pixels connected to the four column lines to set (charge or discharge) the drive signal storage capacitors of the pixels to a common voltage level. After setting (or resetting) the drive signal storage capacitors, the DDIC may send data drive signal Vsig1 for the pixel (or sub-pixel) on the first column line and the selected row through the source signal driver, and may only turn on the DMUX switch for the first column line by setting DMUX switch control signal PMX1 to a high level and setting DMUX switch control signals PMX2, PMX3, and PMX4 to low levels, such that data drive signal Vsig1 may be stored in the drive signal storage capacitor of the pixel on the first column line and the selected row. The DDIC may then send the data drive signal Vsig2 for the pixel (or sub-pixel) on the second column line and the selected row through the source signal driver, and may only turn on the DMUX switch for the second column line by setting DMUX switch control signal PMX2 to a high level and setting DMUX switch control signals PMX1, PMX3, and PMX4 to low levels, such that data drive signal Vsig2 may be stored in the drive signal storage capacitor of the pixel on the second column line and the selected row. Data drive signal Vsig3 for the pixel on the third column line and the selected row and data drive signal Vsig4 for the pixel on the fourth column line and the selected row may be stored in the corresponding drive signal storage capacitors in a similar manner.

As illustrated by waveform 3220, the measured ELVDD level may vary from one horizontal line time period to another horizontal line time period. The measured ELVDD level may also vary within each horizontal line time period, and may include spikes or droops during switching periods. Thus, if the ELVDD level is continuously sensed and used to correct the Vref and Vsig levels, incorrect ELVDD levels may be used, for example, if the sensing time is during a switching period.

In the illustrated example, timing diagram 3200 also includes a CLK_sense signal for controlling the time of sensing the ELVDD by the DDIC, where the sensing may only occur at the rising edges of the CLK_sense signal, and the rising edges of the CLK_sense signal may be at the end of each horizontal line time period. The CLK_sense signal may be generated by the DDIC and may be synchronized with the source signal or the horizontal line timing clock. In other embodiments, ELVDD may be sensed at the falling edges of the CLK_sense signal, and/or the edges of the CLK_sense signal may be at different time instants within each horizontal line time period (1H). For example, ELVDD may be sensed in a stabilized period after Vsig1, Vsig2, or Vsig 3 is sent (e.g., after DMUX switch control signal PMX1, PMX2, or PMX3 is set to a high level).

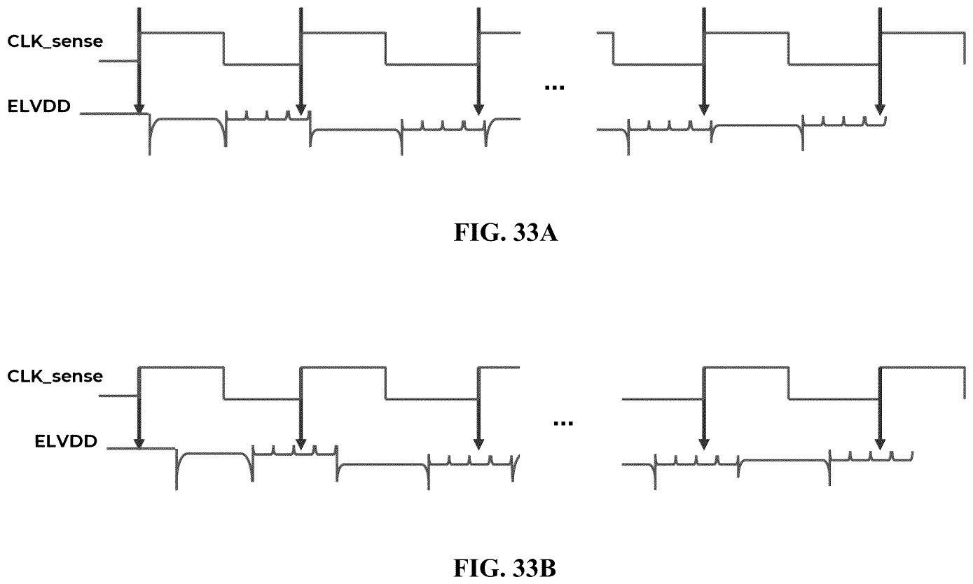

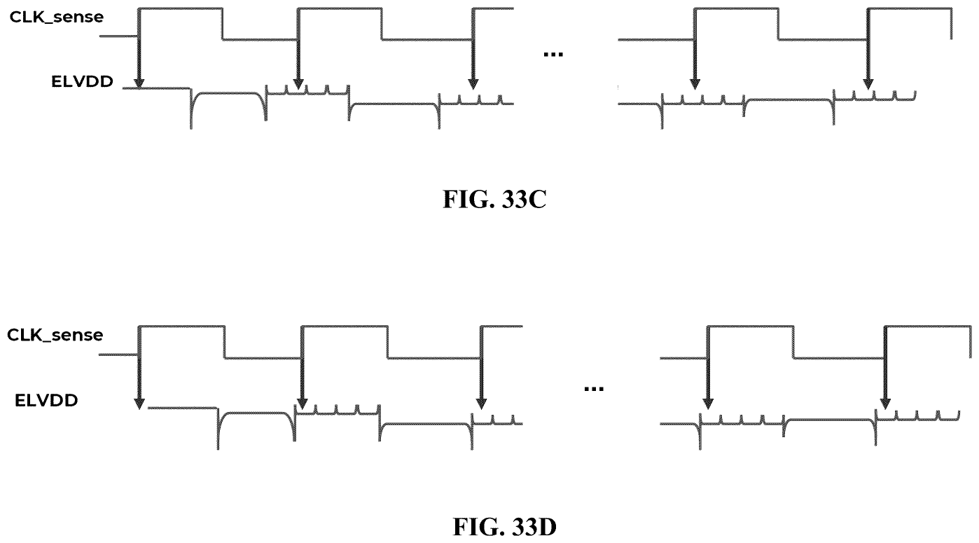

FIGS. 33A-33D illustrate examples of sensing ELVDD at different time instants in each horizontal line time period according to certain embodiments. The sensing time may be controlled by a clock signal CLK_sense, which may be generated by a DDIC and may be synchronized with the source signals and/or the DMUX switch control signals. In the example illustrated in FIG. 33A, the ELVDD sensing may be triggered by rising edges of the clock signal CLK_sense, where the rising edges of the clock signal CLK_sense may be at a time instant after the data drive signal for the fourth column line is sent in each horizontal line time period. Therefore, the ELVDD may be sensed after the data drive signal for the fourth column line is sent in each horizontal line time period.

In the example illustrated in FIG. 33B, the ELVDD sensing may be triggered by rising edges of the clock signal CLK_sense, where the rising edges of the clock signal CLK_sense may be at a time instant after the data drive signal for the third column line is sent but before the data drive signal for the fourth column line is sent in each horizontal line time period. Therefore, the ELVDD may be sensed after the data drive signal for the third column line is sent but before the data drive signal for the fourth column line is sent in each horizontal line time period.

In the example illustrated in FIG. 33C, the ELVDD sensing may be triggered by rising edges of the clock signal CLK_sense, where the rising edges of the clock signal CLK_sense may be at a time instant after the data drive signal for the second column line is sent but before the data drive signal for the third column line is sent in each horizontal line time period. Therefore, the ELVDD may be sensed after the data drive signal for the second column line is sent but before the data drive signal for the third column line is sent in each horizontal line time period.

In the example illustrated in FIG. 33D, the ELVDD sensing may be triggered by rising edges of the clock signal CLK_sense, where the rising edges of the clock signal CLK_sense may be at a time instant after the data drive signal for the first column line is sent but before the data drive signal for the second column line is sent in each horizontal line time period. Therefore, the ELVDD may be sensed after the data drive signal for the first column line is sent but before the data drive signal for the second column line is sent in each horizontal line time period.

The examples shown in FIGS. 33A-33D are for illustration purposes only, and are not intended to limit the disclosure to the specific examples. In various embodiments, the ELVDD sensing may be triggered by rising edges, falling edges, high voltage levels, low voltage levels, and the like, and the sensing clock signal may be delayed by different amounts of time with respect to the source signal, the horizontal line timing, and/or the control signals for the DMUX switch. In some embodiments, the sensing time may be dynamically adjusted to determine a time instant for ELVDD sensing that may yield better display results.

Embodiments may include different combinations of features in view of the description. Certain embodiments are described in the following examples.

In Example 1, a display device includes a display panel including a two-dimensional (2-D) array of pixels, and a control circuit at a peripheral region of the display panel, wherein the control circuit is configured to measure a supply voltage level for the 2-D array of pixels at the peripheral region of the display panel, and adjust levels of drive control signals based on the measured supply voltage level.

Example 2 includes the display device of Example 1, wherein the control circuit is configured to measure the supply voltage level once in each horizontal line time period.

Example 3 includes the display device of any of Examples 1 and 2, wherein the control circuit is controlled by a control signal characterized by a period equal to a horizontal line time period.

Example 4 includes the display device of Example 3, wherein the control signal includes a clock signal.

Example 5 includes the display device of Example 4, wherein edges of the clock signal are adjustable with respect to the drive control signals.

Example 6 includes the display device of any of Examples 1-5, wherein the control circuit is part of a display driver integrated circuit (DDIC).

Example 7 includes the display device of any of Examples 1-6, wherein the display panel includes a supply voltage sensing path, and the control circuit is configured to measure the supply voltage level through the supply voltage sensing path.

Example 8 includes the display device of any of Examples 1-7, wherein the control circuit is configured to adjust, based on the measured supply voltage level, the levels of the drive control signals including a reference voltage signal, one or more data driving signals, or a combination thereof.

Example 9 includes the display device of any of Examples 1-8, wherein the control circuit is configured to adjust, based on the measured supply voltage level, the levels of the drive control signals in real time.

Example 10 includes the display device of Example 9, wherein the control circuit is configured to adjust the levels of the drive control signals in a horizontal line time period based on the supply voltage level measured in a preceding horizontal line time period.

Example 11 includes the display device of any of Examples 1-10, wherein the control circuit is on a chip on flex (COF) that is coupled to the display panel through contact pads.

Example 12 includes the display device of Example 11, wherein the display device further includes a flexible printed circuit coupled to the COF and a power management integrated circuit.

Example 13 includes the display device of any of Examples 1-12, wherein the display panel includes a plurality of demultiplexers, and wherein each demultiplexer of the plurality of demultiplexer is configured to send data from a control signal channel of the control circuit to multiple column lines of the display panel during different time periods within each horizontal line time period.

Example 14 includes the display device of any of Examples 1-13, wherein the display panel includes an OLED display panel for near-eye display.

Example 15 includes the display device of any of Examples 1-14, wherein the control circuit is configured to hold a measured supply voltage before a next supply voltage level is measured.

### IX. Digital Misalignment Calibration Method in Tiled Displays

Augmented reality (AR) and virtual reality (VR) applications may use near-eye displays (e.g., head-mounted displays) to present images to users. A near-eye display system may include an image source (e.g., a display panel) for generating image frames, and display optics for projecting the image frames to the user's eyes. Human eyes can have a wide monocular FOV (e.g., about 170°-175° or wider) and wide total binocular FOV (e.g., about 200°-220° or wider). To provide more immersive experience to a user of an artificial reality system, such as an AR, VR, or MR system, the near-eye display system of the artificial reality system may need to provide a large FOV that may be close to the FOV of naked human eyes without using the artificial reality system. In addition, to improve the immersive experience of using the near-eye display system, a higher resolution display system may be desired. It can be challenging to provide a near-eye display that can provide both a large FOV and a high resolution.

The FOV of a display system is the angular range over which an image may be projected in the near or far field. The FOV of a display system is generally measured in degrees, and the resolution over the FOV is generally measured in pixels per degree (PPD). The FOV of a display system may be linearly proportional to the size of the image source (e.g., the display panel), and may be inversely proportional to the focal length of the display optics (e.g., a collimation lens or lens assembly). A balance between the size of the image source and the optical power of the display optics may be needed in order to achieve a good modulation transfer function (MTF) and reduced size/weight/cost. For example, for a smaller display panel, the field of view may be increased by bringing the image source closer, but the image source would need to have higher PPD, and the aberrations of the display optics at the periphery may limit the effective field of view. In addition, to achieve a high PPD, micro displays with ultra-high pixels per inch (PPI) may be needed. There may be many technological challenges and cost issues associated with making high-PPI display panels (e.g., silicon-based μOLED panels or micro-LED panels) with large sizes to cover wider FOVs. For example, when a single drive circuit die is used, the drive circuit die may need to have large chip dimensions to accommodate the OLED panel, gate and data driver, and display driver integrated circuit (DDIC) on the single die, and advanced processing technology with higher cost may need to be used. Production yield of the larger chips may be low. Therefore, micro displays may generally be small due to the limited sizes of the drive circuit dies and/or high cost for large sized drive circuit dies. As such, the FOVs of current AR/VR/MR systems may be limited, which may adversely affect the user experience.

Tiled displays that use two or more discrete display systems may be used to improve the FOV, where a central display system for the central FOV and one or more peripheral display systems for the peripheral FOV may be placed, for example, side by side. However, tiled displays with discrete display systems may have many issues. One notable issue is the boundary between the central display system and the peripheral display systems. For example, mechanical structures such as lens housing and eye-tracking assembly housing may create physical boundary between the discrete display systems of the tiled displays. In addition, the boundary between discrete display systems with mismatching resolutions can result in abrupt transitions across a displayed image.

In some designs, an integrated, tiled display system may include at least a peripheral display panel with a lower resolution, and a higher resolution central display panel. The peripheral display panel may include, for example, a lower resolution panel (e.g., with PPI 1K) that does not need to use a silicon backplane to drive. For example, the peripheral display panel may be controlled using thin-film transistor (TFT) drive circuits or flexible printed circuit. The lower resolution peripheral display panel may include, for example, a low-resolution OLED display panel such as an active matrix organic light-emitting diode (AMOLED) display panel, or a liquid crystal display (LCD) panel. In some embodiments, at least the peripheral region of the lower resolution display panel can be flexible or may be curved. The central display panel may have a higher resolution (e.g., with PPI≥4K or 5K), and may include, for example, micro-LEDs or μOLEDs with silicon-based backplane drive circuits. Thus, the tiled display system can have a higher resolution at least in the center (or foveated) region, and may also have a wider FOV provided by the combination of the central display panel and the peripheral display panel. For example, the monocular FOV of the tiled display system can be greater than 135°, 150°, 170° or wider, and the binocular FOV of a near-eye display including the tiled display system may be greater than abut 150°, 180°, 200°, 220°, or wider.

The central display panel with the higher resolution may have a non-active edge region adjacent to the peripheral display panel. The small non-active edge region of the central display panel may be on top of and overlap with a non-active edge region of the peripheral display panel. Drive circuit of the peripheral display panel can be underneath the central display panel. Therefore, the non-active region between the two display panels of the tiled display system can be very small (e.g., less than 2 mm, 1 mm, 0.5 mm, or smaller), such that the tiled display system may include a substantially continuous display panel with a higher resolution central region and a lower resolution peripheral region. In some embodiments, at least the peripheral region of the base substrate and the lower resolution display panel formed thereon can be curved to further increase the FOV (e.g., greater than 180°, such as about 200°-240°. Foveated rending may be utilized to create a smooth transition between the higher resolution central region and the lower resolution peripheral region. For example, in the boundary regions of the central display panel with the higher resolution, pixels in the central display panel may be grouped to form macro-pixels to gradually decrease the effective resolution from the higher resolution to the low resolution of the peripheral display panel.

The tiled displays formed by integrating heterogeneous display panels into one near-eye display system to expand the FOV may still have some gaps between the heterogeneous display panels and may have characteristic mismatch issues. For example, when the central display panel is placed on top of the lower display panel, the central display panel with the higher resolution may have a non-active edge region adjacent to the peripheral display panel. In addition, it can also be difficult to precisely align the heterogeneous display panels such that the heterogeneous display panels can have the same alignment from batch to batch.

According to certain embodiments, a tiled display may include a lower resolution display panel (e.g., a plastic OLED display panel) and a higher resolution display panel (e.g., a μOLED display panel) under a center region of the lower resolution display panel. The center region of the lower resolution display may not include any active pixels and thus may be parent. The higher resolution display panel may have an active area greater than the transparent center region of the lower resolution display panel, such that the higher resolution display panel can be coarsely aligned and bonded to the lower resolution display panel with peripheral regions of the higher resolution display panel overlapping active pixels of the lower resolution display panel. The alignment between the higher resolution display panel and the lower resolution display panel may then be measured by, for example, selectively turning on certain pixels near the overlapped regions and capturing images using a high resolution camera to determine the relative positions of the pixels on the higher resolution display panel that are under the transparent center region of the lower resolution display panel. Based on the determined relative positions of the pixels on the higher resolution display panel that are under the transparent center region of the lower resolution display panel, the display driver integrated circuit can control these pixels on the higher resolution display panel and the pixels on the lower resolution display panel accordingly to generate images. For example, the DDIC may have driver circuits for all active regions of the higher resolution display panel and the lower resolution display panel, and may be capable of driving the pixels of the higher resolution display panel under the transparent center region of the lower resolution display panel to accommodate or correct the horizontal shift, vertical shift, and/or angular rotation of the higher resolution display panel with respect to the transparent center region of the lower resolution display panel, such that the users would not notice the misalignment.

According to certain embodiments, a method of digital misalignment compensation for a tiled display may include: selectively turning on pixels of a higher resolution display panel and/or a lower resolution display panel, wherein the higher resolution display panel is under a center region of the lower resolution display panel and an active area of the higher resolution display panel is greater than a transparent center region of the lower resolution display panel, such that the higher resolution display panel can be coarsely aligned and bonded to the lower resolution display panel with peripheral regions of the higher resolution display panel overlapping active pixels of the lower resolution display panel. The method may also include capturing one or more images of the display that includes the higher resolution display panel and the lower resolution display panel while the pixels of the higher resolution display panel and/or the lower resolution display panel are selectively turned on; determining a misalignment (e.g., lateral offset and/or rotation) between the higher resolution display panel and the lower resolution display panel based on the captured one or more images; and storing information of the misalignment in a storage device of the display, such that a display driver integrated circuit may drive pixels of the higher resolution display panel and/or the lower resolution display panel using the stored information of the misalignment to correct the misalignment.

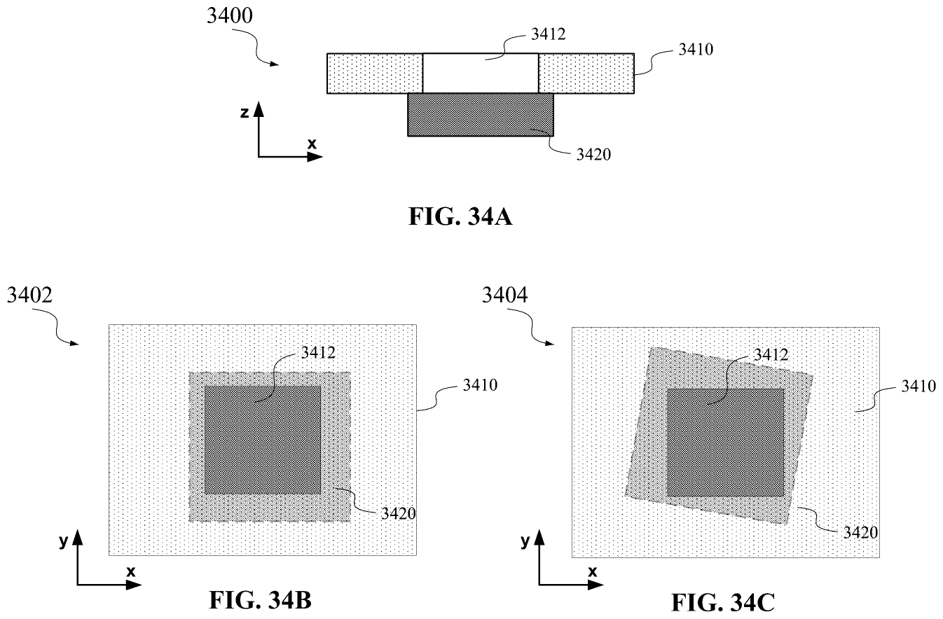

FIG. 34A is a cross-sectional view of an example of a tiled display panel 3400 according to certain embodiments. In the illustrated example, tiled display panel 3400 may include a lower resolution display panel 3410 and a higher resolution display panel 3420 under a center region of lower resolution display panel 3410. Lower resolution display panel 3410 may include, for example, a lower resolution plastic OLED display panel, an AMOLED display panel, or a liquid crystal display panel. A center region 3412 of lower resolution display panel 3410 may have no active pixels and may be transparent. Higher resolution display panel 3420 may include, for example, a micro-display panel such as a μOLED display panel or a micro-LED display panel. The active area of higher resolution display panel 3420 may be larger than the transparent center region 3412 of lower resolution display panel 3410. As described above, due to the small pixel size of higher resolution display panel 3420, it may be difficult to precisely and consistently align and bond higher resolution display panel 3420 with respect to lower resolution display panel 3410. Therefore, the lateral position of higher resolution display panel 3420 with respect to lower resolution display panel 3410 may be different in different tiled display panels.

FIG. 34B is a top view of an example of a tiled display panel 3402 according to certain embodiments. Tiled display panel 3402 may be an example of tiled display panel 3400. In tiled display panel 3402, there may be a lateral shift (in x and/or y direction) between the center of higher resolution display panel 3420 and the center of lower resolution display panel 3410, or between a corner of higher resolution display panel 3420 and a corner of the transparent center region of lower resolution display panel 3410.

FIG. 34C is a top view of an example of a tiled display panel 3404 according to certain embodiments. Tiled display panel 3404 may be an example of tiled display panel 3400. In tiled display panel 3404, there may be a lateral shift (in x and/or y direction) between the center of higher resolution display panel 3420 and the center of lower resolution display panel 3410, or between a corner of higher resolution display panel 3420 and a corner of the transparent center region of lower resolution display panel 3410. There may also be a relative lateral rotation between higher resolution display panel 3420 and lower resolution display panel 3410, such that corresponding edges of higher resolution display panel 3420 and lower resolution display panel 3410 may be at a certain angle with respect to each other.

In order to properly display images using the tiled display panels disclosed herein, the drive circuits of a tiled display panel may need to know the misalignment in a specific tiled display panel precisely, so that the drive circuits may drive appropriate pixels of the higher resolution display panel with appropriate display drive signals to accommodate the misalignment. According to certain embodiments, the misalignment between the higher resolution display panel and the lower resolution display panel may be measured by, for example, selectively turning on certain pixels near the overlapped regions and capturing images using a high resolution camera to determine the relative positions of the pixels on the higher resolution display panel that are under the transparent center region of the lower resolution display panel. Based on the determined relative positions of the pixels on the higher resolution display panel that are under the transparent center region of the lower resolution display panel, the display driver integrated circuit can control these pixels on the higher resolution display panel and the pixels on the lower resolution display panel accordingly to generate images. For example, a DDIC may have driver circuits for all active regions of the higher resolution display panel and the lower resolution display panel. The DDIC and/or another device (e.g., a graphic processing unit) may be capable of selectively driving the pixels of the higher resolution display panel under the transparent center region of the lower resolution display panel, and/or may be capable of transforming (e.g., shifting and/or rotating) digital display data based on the misalignment and generating appropriate display drive signals for the pixels based on the transformed digital display data, to accommodate or correct the horizontal shift, vertical shift, and/or angular rotation of the higher resolution display panel with respect to the transparent center region of the lower resolution display panel, such that users would not notice the misalignment.

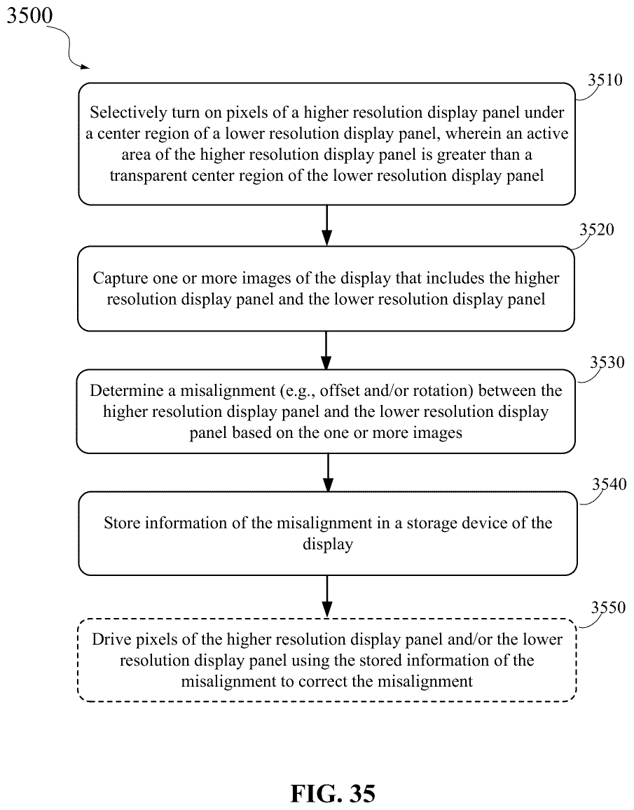

FIG. 35 includes a flowchart 3500 illustrating an example of a method of digital misalignment compensation for a tiled display panel according to certain embodiments. Operations described in flowchart 3500 are for illustration purposes only and are not intended to be limiting. For example, the operations of flowchart 3500 may be performed in any suitable order, not necessarily in the order depicted in FIG. 35. Further, in various implementations, modifications may be made to flowchart 3500 to add additional operations, omit some operations, merge some operations, simultaneously perform some operations, or split an operation.

Operations at block 3510 may include selectively turning on one or more pixels of a higher resolution display panel under a center region of a lower resolution display panel. A center region of the lower resolution display panel may have no active pixels and may be transparent. An active area of the higher resolution display panel may be greater than the transparent center region of the lower resolution display panel, such that, even if the higher resolution display panel is coarsely aligned and bonded to the lower resolution display panel, peripheral regions of the higher resolution display panel may overlap active pixels of the lower resolution display panel and there may be active pixels in any region within the perimeter of the lower resolution display panel. In some embodiments, pixels on one or more rows or columns of the higher resolution display panel may be turned on, and pixels on one or more rows or columns of the lower resolution display panel may be turned on.

Operations at block 3520 may include capturing one or more images of the tiled display panel that includes the higher resolution display panel and the lower resolution display panel, while the pixels of the higher resolution display panel and/or the lower resolution display panel are selectively turned on. A high resolution camera or a camera with a high magnification power may be used to capture the images. In some embodiments, the one or more images may include images in which pixels in different regions of the display panels are turned on.

At block 3530, the misalignment (e.g., offset and/or rotation) between the higher resolution display panel and the lower resolution display panel may be determined based on the one or more images. For example, based on the known locations of the pixels of the higher resolution display panel that are turned on, the known locations of the pixels of the lower resolution display panel that are turned on, and the relative positions of these pixels on the captured images, the misalignment (e.g., lateral shift and/or rotation angle) of the higher resolution display panel with respect to the lower resolution display panel may be determined.

At block 3540, the information of the misalignment determined for a specific tiled display panel may be saved to a storage device associated with the tiled display panel, such as a read-only memory device or another non-volatile memory device (e.g., a flash memory device) at a peripheral region of the tiled display panel. These operations may be performed at the factory. The saved information of the misalignment may be used by the display drive circuits for the tiled display panel to accommodate the misalignment during normal operations of the tiled display panel.

For example, during operations of the tiled display panel at block 3550, a display driver integrated circuit and/or another device (e.g., a graphic processing unit) may generate appropriate display drive signals for the pixels on the higher resolution display panel and the pixels on the lower resolution display panel, based on the misalignment information, such that users would not notice the misalignment. In one example, the DDIC may have driver circuits for all active regions of the higher resolution display panel and the lower resolution display panel, and may be capable of selectively driving the pixels of the higher resolution display panel under the transparent center region of the lower resolution display panel based on the misalignment information. In another example, a graphic processing unit may transform (e.g., shifting and/or rotating) the original digital display data based on the misalignment information to accommodate or correct the horizontal shift, vertical shift, and/or angular rotation of the higher resolution display panel with respect to the transparent center region of the lower resolution display panel, and may send the transformed digital display data to the DDIC, and the DDIC may generate display drive signals for the pixels based on the transformed digital display data.

Embodiments may include different combinations of features in view of the description. Certain embodiments are described in the following examples.

In Example 1, a display device includes a tiled display panel. The tiled display panel includes a first display panel and a second display panel under a center region of the first display panel. The first display panel has a lower resolution but a larger area than the second display panel. The center region of the first display panel is transparent. The second display panel has an active area greater than the transparent center region of the first display panel, such that, even if the second display panel is only coarsely aligned with the first display panel, peripheral regions of the second display panel overlap active pixels of the first display panel and there are active pixels in any region within the perimeter of the first display panel.

Example 2 includes the display device of Example 1, wherein the first display panel includes an LCD display panel, an OLED display panel, or an LED display panel.

Example 3 includes the display device of Example 1 or 2, wherein the second display panel includes a μOLED display panel, a micro-LED display panel, or another micro-display panel.

Example 4 includes the display device of any of Examples 1-3, wherein the display device further comprises a non-volatile memory device storing information of a misalignment between the first display panel and the second display panel.

Example 5 includes the display device of Example 4, wherein the display device further comprises a drive circuit configured to drive the second display panel based on the information of a misalignment between the first display panel and the second display panel.

Example 5 includes the display device of any of Examples 1-4, wherein the second display panel is horizontally shifted or rotated with respect to the first display panel.

In Example 6, a method of digital misalignment compensation for the tiled display panel of any of Examples 1-5 comprises:
selectively turning on pixels of a first display panel under a transparent center region of a second display panel, wherein an active area of the first display panel is greater than the transparent center region of the second display panel;
capturing one or more images of the tiled display panel that includes the first display panel and the second display panel while the pixels of the first display panel are selectively turned on;
determining a misalignment (e.g., offset and/or rotation) between the first display panel and the second display panel based on the one or more images; and
storing information of the misalignment in a storage device of the tiled display panel.

Example 7 includes the method of Example 6, wherein the method further comprises driving pixels of the first display panel and/or the second display panel using the stored information of the misalignment to correct the misalignment.

### X. Dynamic Burn-In Compensation Using Interpolation of Compensation Parameters

Modern display devices are often based on light emitting diode (LED) technology. Display devices in artificial reality systems tend to be smaller compared to electronic displays in other applications, such as television sets or desktop monitors. Despite being smaller, display devices in artificial reality systems are usually high-resolution, with large pixel counts and high pixel density (e.g., in pixels per centimeter) because such displays are typically viewed up close. To meet performance requirements in a small and/or portable form factor, HMDs and other display devices used in an artificial reality environment are sometimes built from micro-LEDs, which can have an LED lateral dimension of 100 micrometers or less, e.g., a diameter on the order of 10 microns or on the order of 1 micron. LED displays, especially organic LED (OLED) displays, are prone to burn-in. Burn-in is a problem in which repetitive use of the display over time (e.g., displaying the same image over thousands of hours) causes pixels to degrade to varying degrees depending on how the individual pixels were used. The degradation is characterized by loss of brightness (luminance) and sometimes manifests as a ghost image.

Burn-in is a problem for many electronic displays. Burn-in can occur when a pixel has been driven with a high luminance value (e.g., to emit the color white) for an extended period of time, e.g., thousands of hours. A pixel driven in such a manner can referred to as a high-stressed pixel. In comparison to low-stressed pixels, high-stressed pixels tend to be dimmer, exhibiting lower brightness given the same input. Because images rendered on a display are not uniformly bright or dark, the individual pixels of an LED display will degrade by different amounts over the lifetime of the display. Degradation in pixel performance can be compensated through adjusting the input signal to a pixel, e.g., by increasing the drive voltage or current beyond that which would have been used in the absence of compensation. The extent of the adjustment to the input signal depends on the extent of the pixel degradation.

In some instances, sensing circuitry may be provided to measure degradation. For example, each pixel in a display may be provided with its own sensor circuit, which can be incorporated into the circuitry forming the pixel (e.g., as part of a pixel cell). Sensor-based compensation is not always feasible. For example, smaller-size displays such as HMDs or other displays used in an artificial reality system may not have enough space to fit sensing circuitry, especially if each pixel is to be individually measured. As an alternative to sensing, pixel degradation may be estimated using a prediction algorithm. In general, sensor measurements provide a more accurate indication of degradation. However, degradation can be estimated with a reasonable level of accuracy based on collection of information regarding how each pixel has been used. For instance, in some embodiments, a display driver or controller can be configured to periodically estimate how much each pixel has degraded based on collecting information regarding frequency of use, operating temperature, luminance data (e.g., grayscale value of images displayed), and/or other factors that contribute to burn-in. The display driver may compute a value for a compensation parameter according to the degradation estimate and then store the compensation parameter in a memory for subsequent use in a compensation operation.

Ideally, each pixel in a display is individually compensated so that the amount by which the input signal to the pixel is adjusted is determined according to the amount by which the pixel has degraded. However, compensation on a per-pixel basis is not always feasible. The amount of memory needed to store compensation parameters is expected to increase in correspondence with increases in display resolution, in some cases beyond the storage capacity of available memory. For example, a display driver in an artificial reality system may be implemented as an integrated circuit that includes embedded memory used for image processing and other display-related operations. The embedded memory of the display driver may be significantly smaller in capacity (e.g., less than 10 megabytes) compared to memory available for run-time execution of an artificial reality application. For a 2000×2000 pixel display, storing a compensation parameter for each individual pixel may require several times more memory (e.g., around 100 megabytes), and that is assuming that the entirety of the embedded memory is available for storing compensation information. In practice, only a fraction of the embedded memory may be dedicated for compensation purposes. Displays for VR and other artificial reality environments can be even higher in resolution, e.g., 4000×4000. Additionally, more memory use leads to higher power consumption, which is another factor to be considered when implementing burn-in compensation.

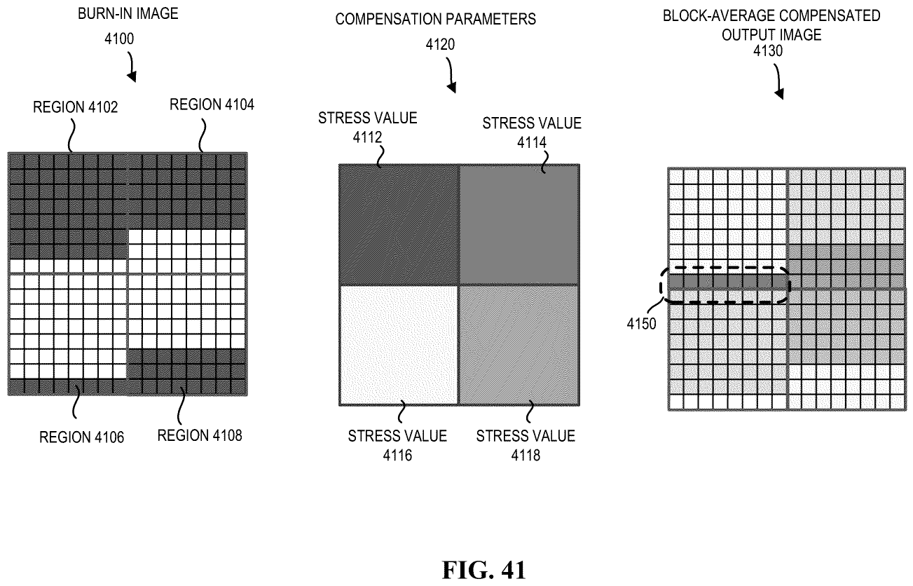

Block-based compensation is a less memory-intensive approach to burn-in compensation. In block-based compensation, the display area is divided into uniformly sized blocks or regions, and a separate compensation parameter is applied to each block based on the compensation parameters of the pixels within the block. For instance, block-based compensation can involve computing a block-specific compensation parameter as the average or median of the compensation parameter values of every pixel in the block. An example of block-averaging is shown in FIG. 41, discussed below. Although block-based compensation requires less memory than per-pixel compensation, there are certain drawbacks, including reduced image quality. Accordingly, achieving high image quality in combination with low memory consumption can be challenging.

To address the challenges discussed above, aspects of the present disclosure relate to burn-in compensation through applying interpolation to block-based compensation parameters. The interpolation can be performed with respect to different blocks within a display region to compute additional compensation parameters at a sub-block level, e.g., compensation parameters for individual pixels. This enables higher image quality compared to a purely block-based approach. Further, the interpolation can be performed at run-time (e.g., upon powering up a display controller) in order to avoid storing the additional compensation parameters in memory. In this manner, a balance between image quality and memory consumption can be achieved through a mix of block-level compensation and local (e.g., pixel-level) compensation.

Aspects of the present disclosure relate to burn-in compensation for pixels in an LED display. A pixel of an LED display can be formed using one or more light emitters, i.e., LEDs. To emit light of different colors, each pixel may include a set of emitters that collectively produce the light emitted by the pixel. For instance, a pixel can include at least one red emitter, at least one green emitter, and at least one blue emitter so that the pixel can be controlled to emit light according to an input red-green-blue (RGB) value. Accordingly, the pixel-related functionality described herein may be applied to a single emitter or to multiple emitters that form a pixel. RGB is one example of a color model that may be employed by a display system. CMYK (cyan-magenta-yellow-key black) is another example. A value expressed in terms of a color model can be separated into a luminance component and a chrominance component. The luminance component represents brightness and may, for example, correspond to a grayscale level between 0 and 255, where 0 is black (fully dark) and 255 is white (fully bright).

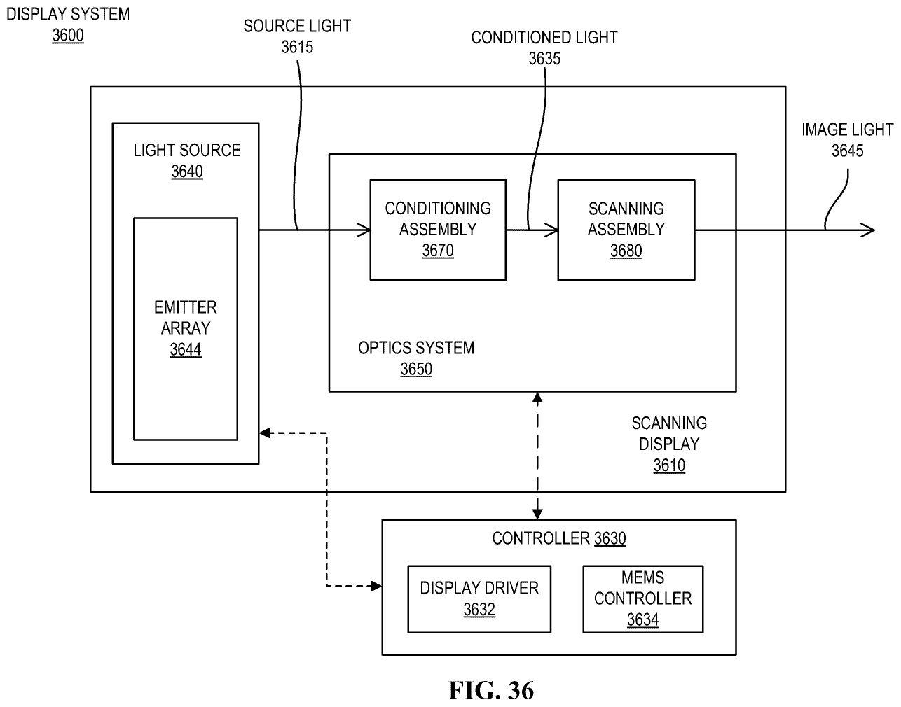

FIG. 36 is a block diagram of a display system 3600 usable for implementing one or more embodiments. The display system 3600 may correspond to an implementation of the near-eye displays in FIGS. 1-5 and includes a scanning display 3610, a controller 3630, a light source 3640, and an optics system 3650. The display system 3600 is an example of a display environment in which light produced by the emitters in the display is not viewed directly but is instead processed using optical components to form an output image for display to a user.

Scanning display 3610 generates image light 3645 in accordance with scanning instructions from the controller 3630. The scanning display 3610 includes a light source 3640 and an optics system 3650. The light source 3640 is a source of light that generates a spatially coherent or a partially spatially coherent source light 3615, e.g., an image or partial image. The optics system 3650 includes a conditioning assembly 3670 and a scanning assembly 3680. The conditioning assembly 3670 transforms the source light 3615 into conditioned light 3635, and the scanning assembly 3680 scans the conditioned light 3635. The image light 3645 may be coupled to an entrance of an output waveguide (not shown) to direct the image light 3645 toward an eye of the user.

Light source 3640 emits light in accordance with image data in the form of one or more illumination parameters received from the controller 3630. An illumination parameter is used by the light source 3640 to generate light. An illumination parameter may include, e.g., source wavelength, pulse rate, pulse amplitude, beam type (continuous or pulsed), other parameter(s) that affect the emitted light, or some combination thereof. The illumination parameter can be applied to an emitter of the light source 3640 using analog and/or digital signals that drive the light source, e.g., to a luminance signal that sets the brightness of an emitter based on the voltage or current level of the luminance signal. The illumination parameter and/or other image data can be supplied from the controller 3630 to circuitry that generates, based on the image data, the signals which drive the light source. This driving circuitry can be included in the light source 3640 (e.g., co-located with emitters of the light source) or located external to the light source 3640.

Light source 3640 includes a set of emitters, where each emitter may be, e.g., a light-emitting diode (LED), a laser diode, a vertical cavity surface emitting laser (VCSEL), an organic LED (OLED), a micro-LED, a tunable laser, or some other light source that emits coherent or partially coherent light. The emitters of the light source 3640 emit light in a visible band (e.g., from about 390 nm to 700 nm). In some embodiments, the scanning display 3610 comprises multiple light sources, each with its own array of emitters emitting light in a distinct wavelength such that when scanned, light emitted from each of the light sources are overlapped to produce various wavelengths in a spectrum. Each emitter of the light source 3640 includes an emission surface from which a portion of source light is emitted. The emission surface may be identical for all emitters or may vary between emitters. The emission surface may have different shapes (circular, hexagonal, etc.).

The emitters of the light source 3640 can be arranged as an array 3644, which can be one-dimensional (1D) or two-dimensional (2D). In a 2D array, the emitters are formed along a first dimension and a second dimension orthogonal to the first dimension (e.g., along rows and columns). Each column of emitters corresponds to a respective column in an image ultimately displayed to the user. The emitters may be of various colors. For example, the light source 3640 may include a set of red emitters, a set of green emitters, and a set of blue emitters, where emitters of different color together form an individual pixel. An individual pixel may include at least one red emitter, at least one green emitter, and at least one blue emitter. Rows of emitters of the same color may be arranged in a single group. For example, the array may comprise N rows of red emitters followed by N rows of green emitters and then N rows of blue emitters.

Light source 3640 may include additional components such as data shifting circuits and driving circuits, which are electrically coupled to the emitter array 3644. The data shifting circuits may supply image data from the controller 3630 to the driving circuits, which then generate signals that activate the emitters. For example, image data can be sequentially shifted through a row or column of emitters to form a display image, with the resulting emitted light being scanned to form an output image. The driving circuits include circuitry for controlling the array of emitters based on the image data. For example, the driving circuits may apply illumination parameters received from the controller 3630 (e.g., luminance values received from a display driver of the controller) to control each emitter in the array of emitters using analog and/or digital control signals. The emitters can be controlled using electric currents (current-mode control) or voltages (voltage-mode control). In some embodiments, the emitters are controlled using pulse-width modulation (PWM), amplitude adjustments, or a combination of both.

Conditioning assembly 3670 conditions the source light 3615 produced by the light source 3640. Conditioning the source light 3615 may include, e.g., expanding, collimating, focusing, distorting emitter spacing, adjusting orientation an apparent location of an emitter, correcting for one or more optical errors (e.g., field curvature, chromatic aberration), some other adjustment of the light, or some combination thereof. Accordingly, the conditioning assembly 3670 may include one or more optical elements such as lenses, mirrors, apertures, gratings, or any other suitable optical element that affects image light.

Scanning assembly 3680 includes one or more optical elements that redirect light via one or more reflective portions of the scanning assembly 3680. The direction where the light is redirected toward depends on specific orientations of the one or more reflective portions. The one or more reflective portions of the scanning assembly may form a planar or curved surface (e.g., spherical, parabolic, concave, convex, cylindrical, etc.) that operates as a mirror. The scanning assembly 3680 scans along at least one dimension of a 2D emitter array, through rotation about a predetermined axis. In some embodiments, the scanning assembly 3680 is configured to scan in at least the smaller of the two dimensions. For example, if the emitters are arranged in a 2D array where the rows are substantially longer (i.e., contain more emitters) than the columns, then the scanning assembly 3680 may scan down the columns (e.g., row by row or multiple rows at a time). In other embodiments, the scanning assembly 3680 may perform a raster scan (horizontally or vertically depending on scanning direction). The scanning assembly 3680 can include multiple scanning mirrors, each of which is configured to scan in 0, 1, or 2 dimensions. The scanning can be controlled using one or more microelectromechanical systems (MEMS) devices, such as electrostatic or electromagnetic actuators, included in the optics system 3650.

Controller 3630 controls the light source 3640 and the optics system 3650. The controller 3630 takes content for display and divides the content into discrete sections. The controller 3630 instructs the light source 3640 to sequentially present the discrete sections using individual emitters corresponding to a respective row or column in an image ultimately displayed to the user. The controller 3630 instructs one or both of the conditioning assembly 3670 and the scanning assembly 3680 to condition and/or scan the discrete sections. The controller 3630 controls the optics system 3650 to direct the discrete sections of the image light 3645 to different areas, e.g., to different coupling points of a waveguide. Accordingly, each discrete portion may be presented in a different location and at different times such that the full output image is rendered as a sequence of partial images. While each discrete section is presented at different times, the presentation and scanning of the discrete sections can occur fast enough such that a user's eye integrates the different sections into a single image or series of images. The controller 3630 also provides illumination parameters (e.g., luminance values) for the light source 3640.

The controller 3630 may include software and/or hardware components that control the scanning assembly 3680 in synchronization with controlling the light source 3640. For example, the controller 3630 may include one or more computer processors, a dedicated graphics processor, application-specific integrated circuits, software programs containing instructions for execution by the one or more computer processors, etc. In some embodiments, the controller 3630 includes a display driver 3632 and a separate MEMS controller 3634. The display driver 3632 can be implemented as an integrated circuit that generates control signals for the light source 3640 based on instructions from a processor executing a software application that generates the images to be displayed. For example, the software application can be an application that generates an AR or VR presentation for viewing on an HMD. The MEMS controller 3634 may include circuitry that generates control signals for one or more MEMS devices that drive the rotation of the scanning assembly 3680. The display driver 3632 and the MEMS controller 3634 may be communicatively coupled to one another to facilitate the synchronization of output from the display driver 3632 with output from the MEMS controller 3634. In some embodiments, the controller 3630 includes timing circuitry such as a clock generator that produces one or more clock signals which determine the timing of the outputs of the display driver 3632 and the MEMS controller 3634. The clock signals may, for example, determine various operational phases for the output of instructions to the light source 3640 and/or the output of instructions to the MEMS devices.

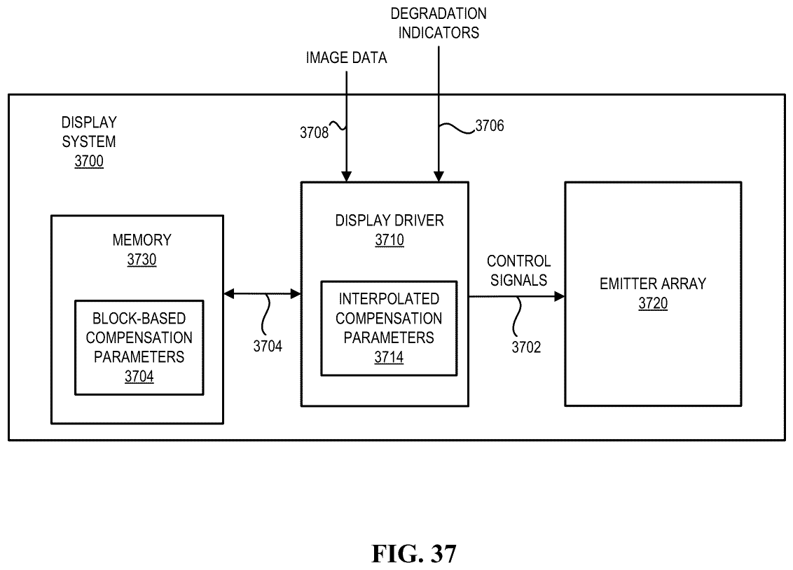

FIG. 37 is a block diagram of a display system 3700 according to some embodiments. FIG. 37 is a simplified diagram depicting components that are relevant to burn-in compensation. Display system 3700 is shown as including a display driver 3710, an emitter array 3720, and a memory 3730. However, the display system 3700 may include additional or fewer components. For example, display system 3700 may correspond to the display system 3600, in which case display system 3700 could include a scanning assembly, among other things.

Display driver 3710 is analogous to the display driver 3632 in FIG. 36 and is configured to control the operation of the emitter array 3720 using control signals 3702. The display driver 3710 generates the control signals 3702 based on image data 3708 that can be supplied from a processor (e.g., a CPU or GPU) in connection with execution of a software application. Display driver 3710 may also generate the control signals 3702 based on compensation parameters 3704 retrieved from the memory 3730. The display driver 3710 may periodically update the compensation parameters 3704 as the pixels of the emitter array 3720 degrade over time.

Memory 3730 includes one or more memory devices accessible to the display driver 3710. The memory device(s) that form the memory 3730 can include volatile memory, non-volatile memory, or a combination of volatile and non-volatile memory. For example, in some implementations, the display driver 3710 is an integrated circuit with embedded flash memory as the memory 3730. In some implementations, the memory 3730 and the display driver 3710 are co-located in an integrated circuit, e.g., an SoC integrated circuit. In addition to storing the compensation parameters 3704, the memory 3730 can include working memory for storage of data generated by the display driver 3710 in connection with image-related processing.

Compensation parameters are parameters with values that are correlated to the degradation of display pixels, e.g., individual emitters or groups of emitters. In the example of FIG. 37, the compensation parameters 3704 are block-based compensation parameters determined at the block-level, e.g., for individual blocks within a display panel formed by the emitter array 3720. Thus, each compensation parameter 3704 may be associated with a corresponding group of pixels within a particular block. In some implementations, the values of the compensation parameters 3704 correspond to stress metrics that directly express the stress levels of the pixels. Alternatively, the compensation parameter values may represent the extent to which the control signals 3702 are to be adjusted in consideration of the stress levels, e.g., coefficients of a mathematical function used to compute the value of a control signal.

As discussed above, storing a separate compensation parameter for each pixel can be memory intensive. Storing block-based compensation parameters 3704 is more memory efficient. Each block corresponds to a different region of the display and may be assigned a corresponding compensation parameter that is determined by the display driver 3710 based on degradation indicators 3706. In particular, a compensation parameter for an individual block/region may be computed as a function (e.g., an average or median value) of degradation indicators 3706 for the pixels within the block. The display driver 3710 may store the compensation parameters 3704 in the memory 3730 without storing compensation parameters at a sub-block level (e.g., for individual pixels). In some embodiments, the information that the display driver 3710 uses to compute the compensation parameters 3704 (e.g., at least some of the degradation indicators 3706) may also be stored in the memory 3730.

Degradation indicators 3706 can include data characterizing one or more factors that contribute to burn-in. More generally, degradation indicators 3706 can include any type of information that can be used to determine the conditions under which the emitter array 3720 has been or is being operated. In some instances, the degradation information is supplied through communication between the display driver 3710 and an external source, for example, readings from a temperature sensor. Alternatively or additionally, the degradation indicators 3706 can include information generated by the display driver 3710. For example, the display driver 3710 may be configured to accumulate historical data regarding how long each pixel has been used (e.g., number of hours of on-time), usage frequency (e.g., average on-time), and the brightness of the image data 3708 (e.g., average luminance or grayscale value for each pixel over the course of multiple image frames). The historical data can include statistical data such as a histogram for each pixel or each display region.

The display driver 3710 may be configured to estimate the degradation of each pixel and/or each display region as a function of the degradation indicators 3706. In some embodiments, display driver 3710 may be configured to apply a model of the pixel degradation. The display driver 3710 can update the model over time to reflect changes in the way the pixels are driven, for example, to account for adjustments to the voltage or current level of a control signal as a result of a calibration operation. The display driver 3710 may periodically calculate and store the compensation parameters 3704, for example, every 10 minutes. In this manner, the compensation parameters 3704 can be kept updated to reflect the estimated degradation of the pixels over the lifetime of the display system 3700.

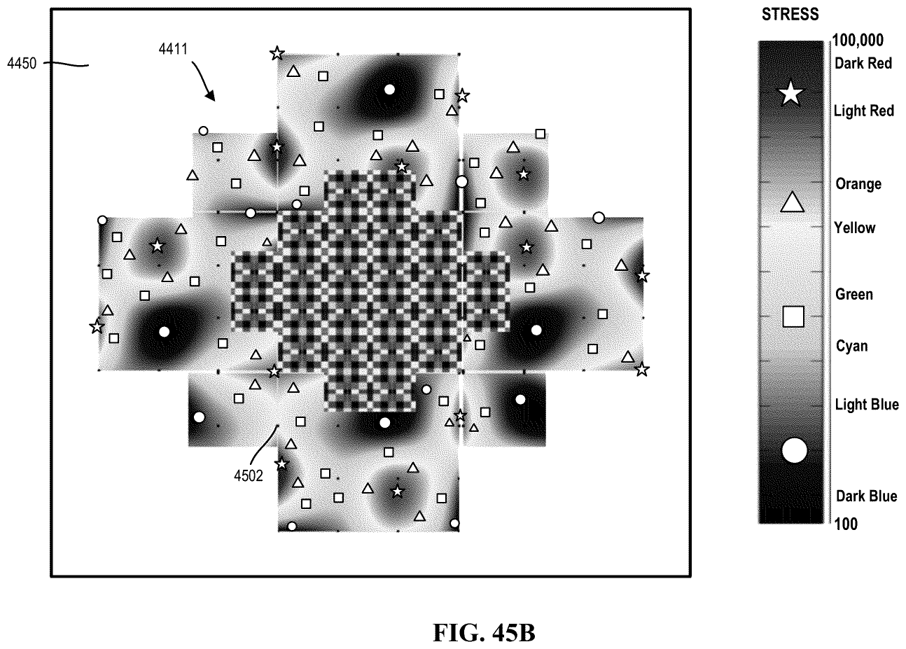

To generate the control signals 3702, the display driver 3710 may determine a set of uncalibrated control signals based on the image data 3708 for the next image to be displayed. Further, the display driver 3710 may determine adjustments to the uncalibrated control signals based on the compensation parameters 3704. As discussed below, e.g., in connection with FIGS. 45A and 45B, burn-in compensation can be performed without relying exclusively on block-averaging or other block-based compensation methods. Instead, the display driver 3710 may process the compensation parameters 3704 to calculate additional compensation parameters through interpolating at least some of the compensation parameters 3704. The interpolation produces a set of interpolated compensation parameters 3714 that are applicable to smaller-sized features within the blocks. For example, the display driver 3710 may determine an interpolation function based on the compensation parameters of two or more neighboring blocks and use the interpolation function to calculate compensation parameters for individual pixels along a path from one neighboring block to another neighboring block.

Unlike the block-based compensation parameters 3704, which are determined and stored in advance, the interpolated compensation parameters 3714 can be determined dynamically during runtime operation of the display system, e.g., sometime after the display driver 3710 is powered on and then periodically thereafter in conjunction with updating the block-based compensation parameters 3704. The display driver 3710 can temporarily store the interpolated compensation parameters 3714 in working memory (e.g., a volatile memory device) internal to the display driver 3710. Alternatively, the working memory could correspond to a portion of the memory 3730. The working memory does not have to store all of the interpolated compensation parameters 3714 at once. For instance, the display driver 3710 may compute the interpolated compensation parameters 3714 in batches to adjust the control signals 3702 over several computation cycles. With the inclusion of the interpolated compensation parameters 3714, the resolution of the block-based compensation parameters 3704 is effectively increased without having to dedicate part of the memory 3730 to long-term storage of the interpolated compensation parameters 3714. Thus, the interpolated compensation parameters 3714 provide for more localized burn-in compensation compared to block-based compensation alone (e.g., compensation using only the compensation parameters 3704).

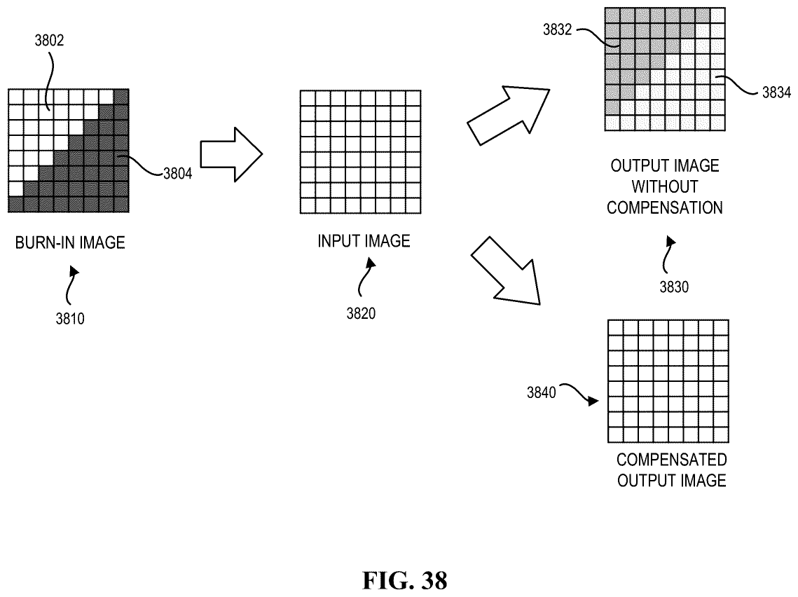

FIG. 38 shows an example of output images produced with and without compensation. In FIG. 38, a burn-in image 3810 is rendered on a display for a period of time sufficient to cause the pixels of the display to degrade. For example, the burn-in image 3810 may be presented continuously or periodically for a total of several thousand hours. As shown, the burn-in image 3810 is non-uniform and divided into a bright region 3802 (e.g., white-colored) and a dark region 3804 (e.g., black-colored). Subsequently, an input image 3820 is presented on the display. The input image 3820 is uniformly bright and may consist of pixels that have the same color (e.g., white). In the absence of compensation, the resulting image produced on the display based on the input image 3820 may be an output image 3830. The burn-in image 3810 is shown as an 8 pixel by 8 pixel image for simplicity. In practice, images tend to much larger.

The output image 3830 in the absence of compensation is expected to be non-uniformly bright in correspondence with the non-uniformity of the burn-in image 3810. As shown in FIG. 38, the brightness of the pixels in the output image 3830 has an inverse relationship with the brightness of the pixels in the burn-in image 3810. Pixels of the burn-in image that are brighter (the region 3802) are subjected to a higher level of stress than pixels that are darker (the region 3804). Accordingly, the output image 3830 may include a region 3832 and a region 3834 corresponding to the region 3802 and the region 3804, respectively. The region 3832 of the output image 3830 is darker compared to the region 3834 due to the pixels of the region 3832 having been subjected to higher stress. Further, although the region 3834 is brighter, the pixels in the region 3834 may also be degraded, but to a lesser degree than the pixels in the region 3832. Therefore, even the region 3834 may be darker compared to the input image 3820.

FIG. 38 also shows an output image 3840 corresponding to an image that would be produced based on the input image 3820 if the display were fully compensated. The output image 3840 is essentially indistinguishable from the input image 3820. To produce the output image 3840, the display may be compensated by individually adjusting the brightness of each pixel on the display. As discussed above, compensation on a per-pixel basis is not always feasible due to memory constraints. However, the block-based compensation and interpolation techniques disclosed herein can be used to achieve high quality output images with less memory.

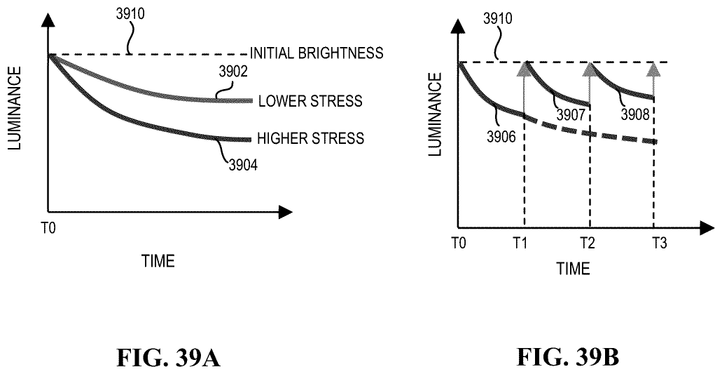

FIG. 39A shows example luminance curves illustrating differences in the relative brightness of pixels that are subjected to higher stress (luminance curve 3904) compared to pixels that are subjected to lower stress (luminance curve 3902). At time T0, the pixels of the display have not yet been degraded and their brightness levels may correspond to an initial brightness level 3910 when the display is first put into use or just after the display has been manufactured. After an extended period of use, e.g., 10,000 hours, the pixels that have been subjected to lower cumulative stress will have degraded to a lesser degree than the pixels that have been subjected to higher cumulative stress. Thus, pixels that are subjected to higher stress will become increasing dimmer over time compared to lower-stressed pixels. In any case, given enough time, all the pixels are expected to experience some decrease in brightness relative to the initial brightness level 3910.

FIG. 39B shows example luminance curves for a group of pixels over the course of several compensation operations. In this example, the display is operated in a similar manner as discussed above with respect to the higher stressed pixels in the example of FIG. 39A. Accordingly, the pixels may degrade according to a luminance curve 3906 that is similar to the curve 3904. For illustration purposes, the discussion of FIG. 39B is limited to these higher stressed pixels. As indicated by the dotted portion of the luminance curve 3906, the degradation of the pixels will follow a similar trajectory as the luminance curve 3904 in the absence of any compensation. However, in this example, a first compensation operation is performed at time T1 to bring the pixels back to the initial brightness level 3910. After the compensation operation is performed, the pixels will resume degrading to decrease in brightness starting once again from the initial brightness level 3910. Similarly, a second compensation operation and a third compensation operation are performed at time T2 and time T3, respectively, each time to bring the pixels back to the initial brightness level 3910.

In some embodiments, compensation may be performed periodically whenever the display is in use, e.g., to update the stored compensation parameters every ten minutes. FIG. 39B shows the pixels degrading in the same manner following each compensation operation. A luminance curve 3907 between T1 and T2 and a luminance curve 3908 between T2 and T3 may have a similar profile as the luminance curve 3906. However, depending on how the pixels are driven, the pixels may follow a different degradation trajectory after each compensation (parameter update) operation. Accordingly, in some embodiments, the display system may update a degradation model after each compensation operation to account for differences between the manner in which pixels are driven before and after the compensation operation.

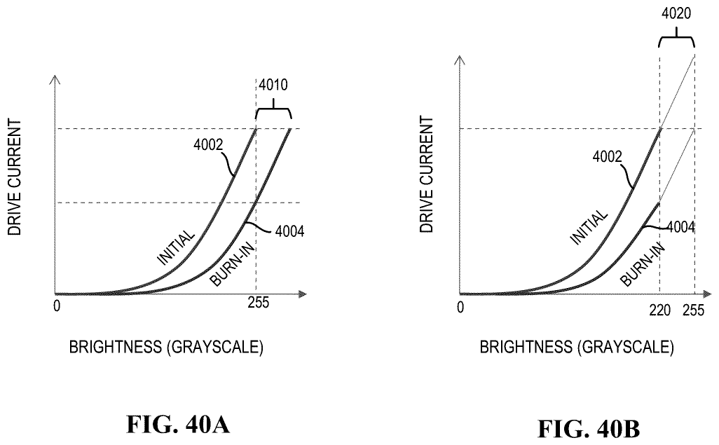

FIG. 40A shows example gamma curves representing brightness as a function of the input value to a pixel. The brightness levels may be expressed digitally and, in this example, are grayscale values ranging from 0 to 255. Thus, a total of 256 brightness levels are possible. The pixel input in this example is a drive current. Other types of input may be used depending on how the display is implemented. For example, the emitters in the display may be voltage-controlled. As shown in FIG. 40A, the display system may be configured with an initial gamma curve 4002 that maps each brightness (grayscale) level to a corresponding drive current.

FIG. 40A illustrates another challenge to burn-in compensation, due to the fact that after a pixel has degraded, the pixel should no longer be controlled in the same manner. To compensate for burn-in, the input is increased in order to achieve the same brightness as would be produced when the pixel is non-degraded. For example, to produce a brightness associated with grayscale 255, a lower drive current may be applied initially in accordance with an initial gamma curve 4002. After burn-in, a higher drive current (or voltage) may be applied and the gamma curve 4002 may be replaced with a gamma curve 4004 in which the grayscale values are mapped to current values different from the initial mapping. However, this may require adding more grayscale values to fully represent the gamma curve 4004. Although the display system may be capable of producing a higher input, there is a limit on the number of brightness levels that can be represented digitally (e.g., 256 levels). To address this problem of limited digital representation, the gamma curve 4004 can be extended through rescaling as shown in FIG. 40B.

FIG. 40B shows an example of gamma curve rescaling, which can be used to implement one or more of the embodiments disclosure herein. In FIG. 40B, the post-burn-in gamma curve 4004 has been rescaled so that a current level that initially mapped to grayscale 255 now maps to a lower grayscale value (e.g., 220). The rescaling effectively extends the gamma curve along the input axis (e.g., drive current/voltage) while compressing the gamma curve along the brightness axis so that a portion 4010 of the gamma curve 4004 in FIG. 40A that would have exceeded the maximum grayscale value of 255 fits within the 0 to 255 grayscale range, e.g., to cover a portion 4020 ranging from 220 to 255. In this manner, an 8-bit grayscale encoding can be maintained so that the display system continues to operate based on 256 grayscale levels, without the need for additional bits of representation after the display has been compensation for burn-in.

FIG. 41 shows an example of artifacts that may be produced as a result of compensation using block-averaging. In FIG. 41, a burn-in image 4100 is presented on a display for an extended period of time to cause the pixels of the display to degrade non-uniformly. As with the burn-in image 3810 in FIG. 38, the burn-in image 4100 is a simplified representation of a display image that might be used in practice. In the example of FIG. 41, the burn-in image 4100 is a 16×16 image divided into four 8×8 regions 4102, 4104, 4106, and 4108. Block-averaging based on an 8×8 block size is applied separately to each of the four regions to compute a corresponding compensation parameter for each region. In particular, a stress value 4112 is computed for region 4102, a stress value 4114 is computed for region 4104, a stress value 4116 is computed for region 4106, and a stress value 4118 is computed for region 4108. The stress values 4112, 4114, 4116, and 4118 are depicted visually as shaded blocks, but may be represented numerically for purposes of determining the extent of a compensation adjustment. The block size may be different in other implementations (e.g., 3×3, 5×5, or 7×7 blocks). Additionally, the example shown in FIGS. 45A and 45B (discussed below) features a mix of different block sizes, with smaller blocks being used for the center of the display panel.

In FIG. 41, the burn-in image 4100 is non-uniform. Of the four regions, the region 4106 has the greatest number of bright pixels, followed by region 4108, region 4104, and lastly region 4102. Accordingly, the pixels of the region 4106 are subjected to the most stress compared to the other regions. Compensation parameters 4120 can be computed by averaging stress values of pixels based on a configured block size. In this example, the block-averaging is performed for an 8×8 block. Thus, the stress value 4112 may correspond to an average of the stress values for the pixels in the region 4102. Similarly, the stress values 4114, 4116, and 4118 may correspond to averages of the stress values for the pixels in the region 4104, the region 4106, and the region 4108, respectively. Since the pixels in the region 4106 are subjected to the most stress, the stress value 4116 may be higher than the other stress values. For example, the stress values in descending order from highest to lowest may be the stress value 4116 (shown as lightest), followed by the stress value 4118, the stress value 4114, and lastly the stress value 4112 (shown as darkest).

When an input image is subsequently displayed using the compensation parameters 4120 to compensate for the degradation produced by the burn-in image 4100, the resulting output image may have visual artifacts. For example, when a uniformly bright (e.g., completely white) input image similar to the input image 3820 in FIG. 38 is displayed, a block-average compensated output image 4130 may be produced. The block-average compensation is applied uniformly for each pixel in a given region. Since each region is compensated by applying its corresponding stress value, the region 4106 will have the greatest amount of adjustment. Although the pixels in any particular region are compensated in the same manner, the brightness of the pixels will still be non-uniform. Taking the region 4106 as an example, output image pixels corresponding to bright areas of the region 4106 in the burn-in image 4100 will be slightly darker compared to output image pixels corresponding to dark areas of the region 4106, due to having degraded more. Further, it can be seen in a circled area 4150 that some pixels in the region 4102 are not as well-compensated compared to neighboring pixels in the region 4106, appearing much darker in comparison. This is because the stress value 4112 that was applied to the region 4102 is a value that represents a lower level of stress, so the pixels of the region 4102 are adjusted to a lesser extent compared to the pixels of the other regions 4104, 4106, and 4108. Therefore, the brightness of the pixels in output image 4130 can vary significantly, seen most noticeably as brightness discontinuities between adjacent regions, but also within individual regions. For example, the area 4150 circled in the output image 4130 comprises pixels that have a step function luminance

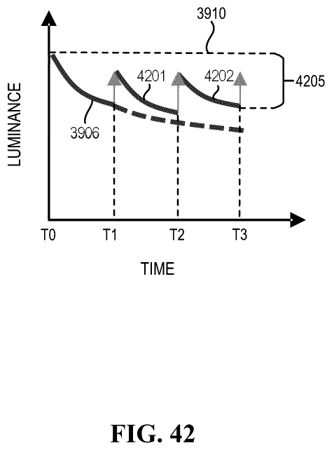

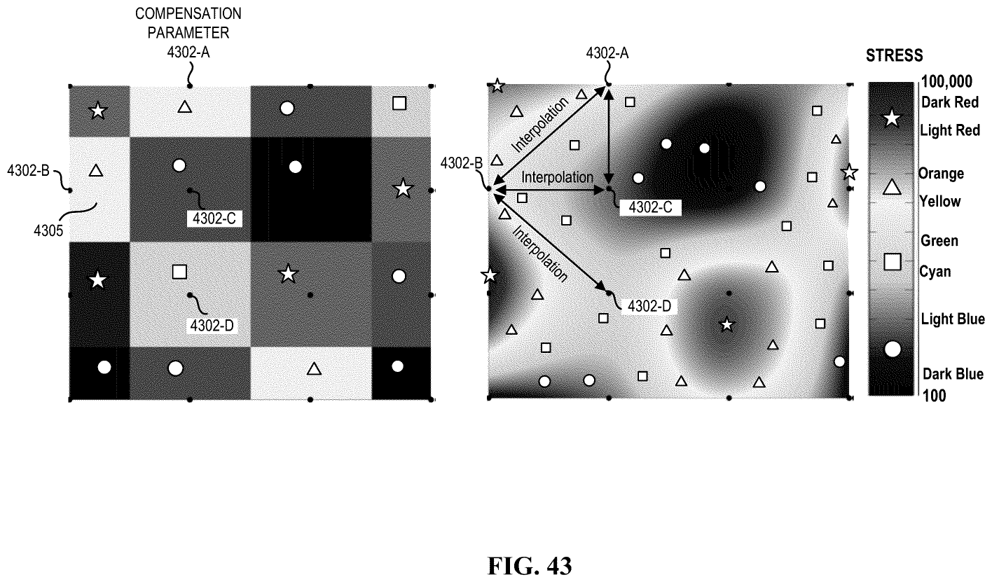

In some embodiments, block-based compensation can be combined with local compensation (e.g., for individual pixels) using compensation parameters determined through interpolation. For instance, the interpolated compensation parameters 3714 in FIG. 37 may be determined based on the interpolation technique discussed below in connection with FIG. 43. Combining block-based compensation with interpolation can address some of the drawbacks of using block-based compensation alone, e.g., step function luminance as discussed above in connection with FIG. 41. Block-based compensation and interpolation can also be combined with other techniques to improve image quality and/or reduce memory consumption. For example, memory use can be further reduced through computing compensation parameters for only a sub-region of a display panel. In FIGS. 45A and 45B (discussed below), the sub-region is lens shaped and sub-divided into a first region corresponding to an inner eye space and a second region corresponding to an outer eye space. As another example, the frequency and/or amount of compensation can be varied, e.g., to bring pixels back to less than 100% of their initial brightness, as shown in FIG. 42.

FIG. 42 shows example luminance curves for a group of pixels over the course of several compensation operations. The compensation operations are performed at times T1, T2, and T3, resulting in a luminance curve 4201 after the compensation at T1, and a luminance curve 4202 after the compensation at T2. Depending on the frequency with which compensation is performed, the duration between compensation operations may be uniform (e.g., spaced every ten minutes) or non-uniform, e.g., when compensation is performed in response to estimated pixel brightness falling below a threshold. At TO, the pixels begin degrading in the same manner as in FIG. 39B, following the luminance curve 3906. In contrast to the example in FIG. 39B, the compensation in FIG. 42 does not bring the pixels back to 100% of the initial brightness level 3910. For example, each of the compensation operations at T1, T2, and T3 may increase the brightness of the pixels by half of a difference 4205 between the initial brightness level 3910 and the brightness of the pixels at the time of the compensation.

It should be noted that the luminance curves shown in the drawings represent maximum possible brightness. The actual brightness of a display pixel depends on the input image being displayed, since each display pixel is set to a brightness of a corresponding pixel in the input image. Thus, the initial brightness level 3910 may correspond to the brightness of a non-degraded pixel when the pixel is set to the highest brightness level (e.g., grayscale 255 or white). Likewise, the difference 4205 may correspond to a difference between the maximum possible initial brightness and the maximum possible brightness of a pixel at the time of a compensation operation.

Increasing the brightness to a level less than 100% of the initial brightness may reduce the appearance of ghost images when performed in conjunction with global compensation. Because every pixel is compensated using the same compensation parameter, a 100% adjustment may result in some pixels being severely overcompensated (too bright) and other pixels being severely undercompensated (too dark). Therefore, 100% adjustment could potentially create undesirable brightness contrasts that make a ghost image (essentially the inverse of a burn-in image) especially noticeable. By performing a less than 100% adjustment (e.g., 50% or some other fraction of the difference 4205), there will be less of such contrast, and ghost images will be less noticeable compared to global compensation at 100%. Ghost images are also expected to be less noticeable compared to pure block-based compensation such as depicted in FIG. 41.

FIG. 43 shows an example of compensation parameter interpolation, according to certain embodiments. In the example of FIG. 43, the compensation parameters being interpolated are block-based parameters (e.g., the compensation parameters 3704 in FIG. 37). For instance, the display panel may be divided into different blocks, and a compensation parameter may be determined for each individual block using block-averaging as discussed above in connection with FIG. 41. For simplicity, only a representative portion of the display is depicted in FIG. 43. As shown on the left side of FIG. 43, each block has a corresponding compensation parameter 4302, e.g., 4302-A, 4302-B, 4302-C, or 4302-D. For instance, the compensation parameter 4302-B is assigned to a block 4305. Each compensation parameter 4302 is depicted as a dot centered in the middle of its corresponding block. The value of a compensation parameter 4302 is indicative of overall stress level within the corresponding block and can be calculated as an optimal value for the block, e.g., an average or median stress value representing an overall degradation of pixels within the block.

In this example, the compensation parameters range on a scale from 10 to 100,000, which is arbitrary. The values of the compensation parameters are higher for those pixels or regions subjected to more stress and lower for pixels or regions subjected to less stress. The compensation parameters can be fitted to any desired scale through normalization. As such, the range of compensation parameter values is not limited to 100 to 100,000 but instead depends on implementation. The scale in FIG. 43 is shown using color gradation, with 100 being dark blue and 100,000 being dark red. The scale is annotated with a shape legend to indicate the color correspondence. Stars denote red (light or dark), triangles denote orange and yellow, squares denote green and cyan, and circles denote blue (light or dark).

The right side of FIG. 43 shows a result of interpolating the compensation parameters 4302 to generate interpolated compensation parameters, which are represented using shading in accordance with the scale mentioned above. Interpolation provides for smooth, gradual transitions between the compensation parameters of neighboring blocks. This reduces the number of image artifacts (e.g., step discontinuities in luminance) that arise when the compensation parameters are applied to form a display image. Interpolated compensation parameters are determined based on the compensation parameters 4302 of neighboring blocks. For instance, the value of compensation parameter 4302-B can be fitted to an interpolation function (e.g., a first-degree polynomial) representing a transition from the location associated with the compensation parameter 4302-B (the block 4305) to the location of an adjacent block (e.g., any of the blocks associated with the compensation parameters 4302-A, 4302-C, and 4302-D). Example interpolation directions are shown with doubled-ended arrows. The interpolation functions can be estimated using a traditional interpolation method. Interpolation does not necessarily involve evaluating different pairs of blocks independently, e.g., one pair at a time. For instance, an interpolation function could be determined based on the compensation parameters of several (e.g., three or more) neighboring blocks.

If each compensation parameter 4302 represents the stress level in the middle of a block, then an interpolation function may characterize how the stress level changes as a function of distance from the middle of the block to the middle of an adjacent block. As such, the compensation parameter for a point (e.g., a single pixel) halfway or some other distance between two blocks could be computed using a corresponding interpolation function. The resulting interpolated compensation parameters are therefore much greater in number compared to the total number of block-based compensation parameters 4302. However, to avoid increasing the amount of storage memory, the interpolated compensation parameters need not be stored together with the compensation parameters 4302.

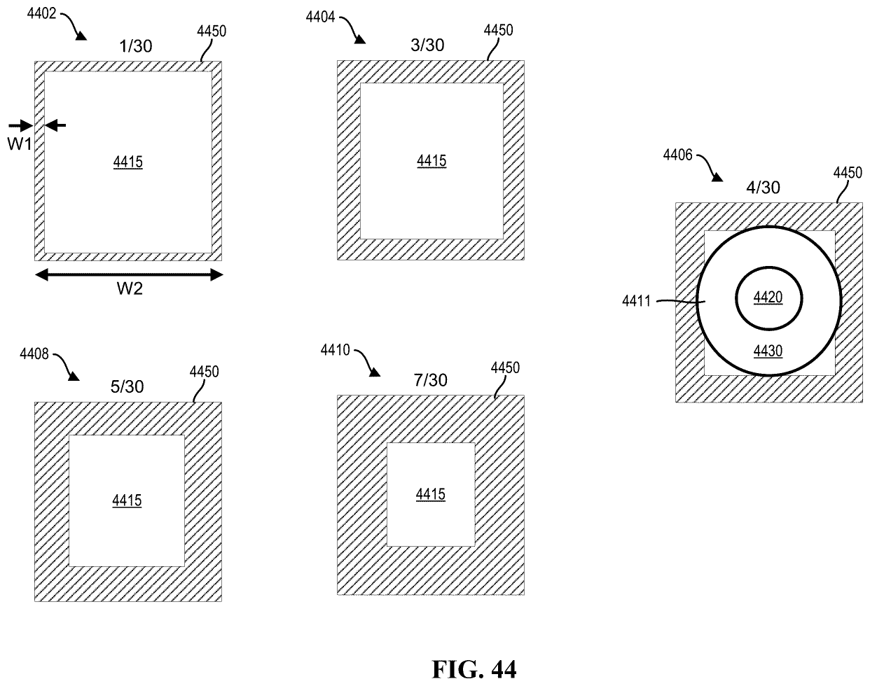

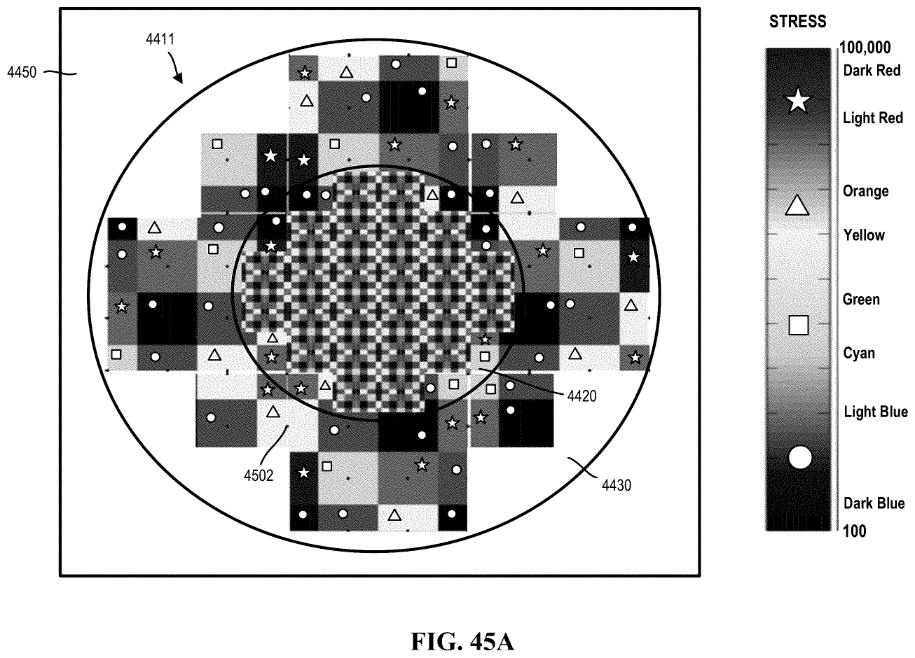

FIG. 44 shows examples of different compensation window configurations. Each compensation window configuration specifies the boundaries of a central region 4415 of a display relative to a peripheral region 4450 of the display. The central region 4415 is a region where a user tends to focus their attention. As such, burn-in compensation is less important for the peripheral region 4450. To conserve computing resources, block-based compensation can be applied to the central region 4415 while applying a less resource-intensive compensation method to the peripheral region 4450. In fact, no compensation whatsoever may be applied to the peripheral region 4450 in some implementations.

As shown in FIG. 44, the compensation window configurations vary with respect to the size of the peripheral region 4450. For instance, a first configuration 4402 features a 1:30 ratio between a width W1 of the peripheral region 4450 along one side and an overall width W2 of the display. A second configuration 4404 features a 3:30 ratio. Additional configurations 4406, 4408, and 4410 feature ratios of 4:30, 5:30, and 7:30, respectively. An optimal configuration providing the best trade-off between viewing angle and memory size can be determined experimentally. For example, the optimal compensation window configuration for a virtual reality HMD could be the configuration 4406, which has a 4:30 ratio between W1 and W2.

In order to further conserve memory resources, the number of block-based compensation parameters to be stored can be reduced by approximating the central region 4415 as a lens-shaped (e.g., circular, oval, or elliptical) region 4411. The shape of the lens-shaped region 4411 can vary and, in some implementations, may be based on the shape of an optical lens coupled to the display panel, e.g., a collimating lens configured to direct light from the display to an eye of a user. For instance, the lens-shaped region 4411 may correspond to areas of the display panel from which light can be collected by the optical lens and projected onto the user's eye. Areas outside of the lens-shaped region 4411 may not provide light to the lens and, as such, would not be visible to the user. Accordingly, compensation parameters need not be stored for the areas outside the lens-shaped region 4411. This can result in significant memory savings since the lens-shaped region 4411 is smaller than the display itself, e.g., half the number of display pixels.

As shown in FIG. 44, the lens-shaped region 4411 may be divided into an inner region 4420 and an outer region 4430, which correspond to an inner eye space and an outer eye space, respectively. Image quality can be improved through using smaller block sizes in the inner eye space in combination with larger block sizes in the outer eye space. Smaller block sizes permit more precise compensation in the inner region 4420. Additionally, as discussed below in connection with FIGS. 45A and 45B, interpolation can be performed on the block-based compensation parameters of the outer region 4430 to increase the number of compensation parameters available for use in the outer region 4430. The interpolation at least partially makes up for the coarser compensation that would otherwise result from using larger block sizes.

FIGS. 45A and 45B show an example of block-based interpolation, according to certain embodiments. In FIG. 45A, the display panel is divided into the lens-shaped region 4411 and the peripheral region 4450 discussed above in connection with FIG. 44. The blocks which form the inner region 4420 are smaller, and therefore more densely concentrated, than the blocks which form the outer region 4430. Consequently, the inner region 4420 has a greater number of compensation parameters compared to the outer region 4430. This enables compensation to be performed with greater accuracy (truer to actual pixel degradation) and precision (higher resolution) in the inner region 4420. Additionally, as illustrated in FIG. 45B, compensation with respect to pixels in the outer region 4430 can be performed using interpolated compensation parameters, e.g., the interpolation technique described in connection with FIG. 43. The compensation parameters for the blocks within the lens-shaped region 4411 are shown using the same scale and shape guides as in FIG. 43. However, the shape guides are omitted from the inner region 4420 for ease of illustration.

FIG. 45B shows the compensation parameters of FIG. 45A after interpolation. FIG. 45A represents the compensation parameters that would be stored in memory (e.g., the memory 3730 in FIG. 37). For example, a compensation parameter 4502 for a representative block in the outer region 4430 may be one of the block-based compensation parameters stored in memory. The display controller may perform interpolation to compute a separate compensation parameter for each pixel in the outer region 4430. This would permit local burn-in compensation on a smaller (sub-block) scale in the outer region 4430, based on values derived from block-level compensation parameters stored in memory. Thus, the number of compensation parameters available for use with the pixels of the outer region 4430 can be increased without incurring the cost of storing those additional compensation parameters in memory.

In FIG. 45B, only the compensation parameters in the outer region 4430 (outer eye space) are shown as being interpolated. However, the compensation parameters in the inner region 4420 (inner eye space) can also be interpolated. Whether or not interpolation is applied to the inner region 4420 may depend on the sizes of the blocks in the inner region. When the block size is sufficiently small, interpolation does not provide for a significantly smoother image (e.g., fewer artifacts) compared to using non-interpolated compensation parameters.

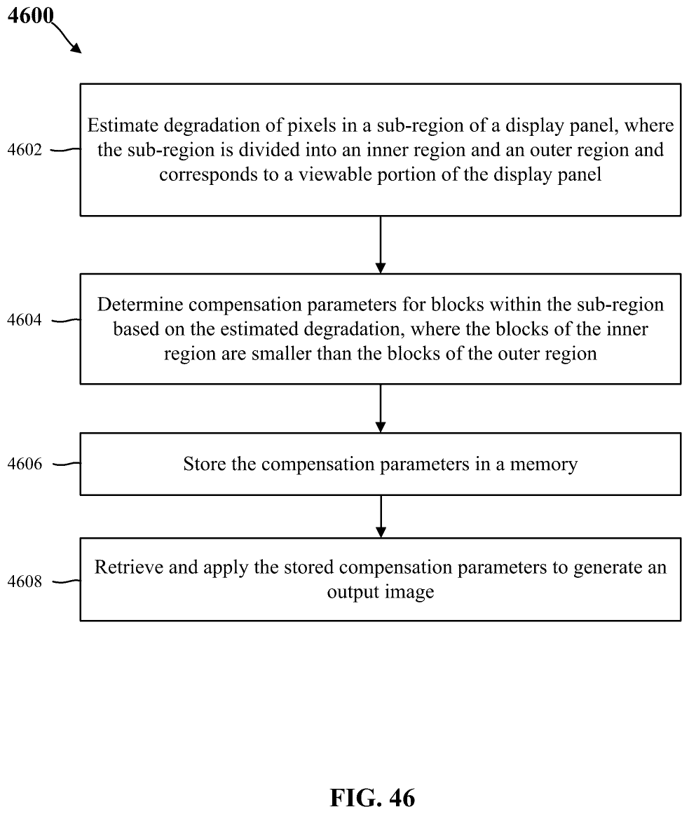

FIG. 46 is a flow diagram of a process 4600 for determining block-based compensation parameters, according to certain embodiments. Process 4600 can be performed using a display controller of a display system, e.g., the display driver 3710 in FIG. 37. At 4602, the degradation of pixels in a sub-region of a display panel is estimated. The sub-region is divided into an inner region and an outer region and corresponds to a viewable portion of the display panel. For instance, the sub-region in 4602 can be the lens-shaped region 4411, which includes inner region 4420 and outer region 4430.

At 4604, compensation parameters are determined for blocks within the sub-region based on the estimated degradation of the pixels in the sub-region. The blocks of the inner region are smaller than the blocks of the outer region, resulting in a greater number of compensation parameters being determined for the inner region in comparison to the outer region.

At 4606, the compensation parameters determined in 4604 are stored in a memory. The memory can be a local memory of the display system (e.g., memory 3730) and, in some instances, may be internal to the display controller. As discussed above, compensation can be performed at various points (e.g., T1, T2, and T3 in FIG. 42) over the lifetime of the display system. Therefore, the functionality in 4602, 4604, and 4606 may be repeated to update the compensation parameters stored in the memory.

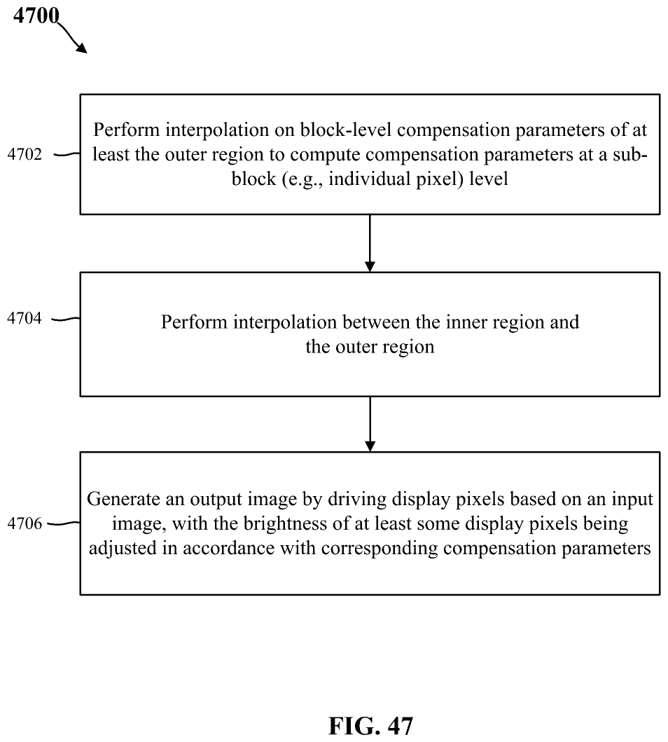

At 4608, the stored compensation parameters are retrieved from the memory and applied to generate an output image. The stored compensation parameters can be directly applied to determine brightness adjustments for driving the display panel. Alternatively, the stored compensation parameters can be used to derive additional compensation parameters through interpolation, e.g., in accordance with the process shown in FIG. 47.

FIG. 47 is a flow diagram of a process 4700 for burn-in compensation through interpolation of block-based compensation parameters, according to certain embodiments. Process 4700 is an extension of the process 4600 and can be performed using the same display controller, e.g., display driver 3710. At 4702, interpolation is performed on block-level compensation parameters of at least the outer region (e.g., outer region 4430). The interpolation involves computing compensation parameters at a sub-block level, e.g., for individual pixels. Thus, the functionality in 4702 may involve estimating interpolation functions and using the interpolation functions to compute interpolated compensation parameters.

At 4704, interpolation is performed between the inner region and the outer region. For example, the interpolation in 4704 can be performed along the perimeter or edges of the inner region 4420 to smooth the transition between compensation parameters of the inner region 4420 (e.g., block-based compensation parameters retrieved from memory) and compensation parameters of the outer region 4430 (e.g., the compensation parameters computed in 4702). Thus, the compensation parameters of the inner region 4420 and/or the outer region 4430 may be adjusted to produce a final set of compensation parameters for both regions. This final set of compensation parameters can be reused until the block-level compensation parameters are updated, at which time the interpolation in 4702 and 4704 may be repeated.

At 4706, an output image is generated by driving display pixels based on an input image, with the brightness of at least some display pixels being adjusted in accordance with corresponding compensation parameters. The display pixels for which brightness is adjusted can include pixels in the inner region 4420 and pixels in the outer region 4430. However, as discussed above in reference to FIG. 44, pixels located outside of these two regions need not be compensated.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

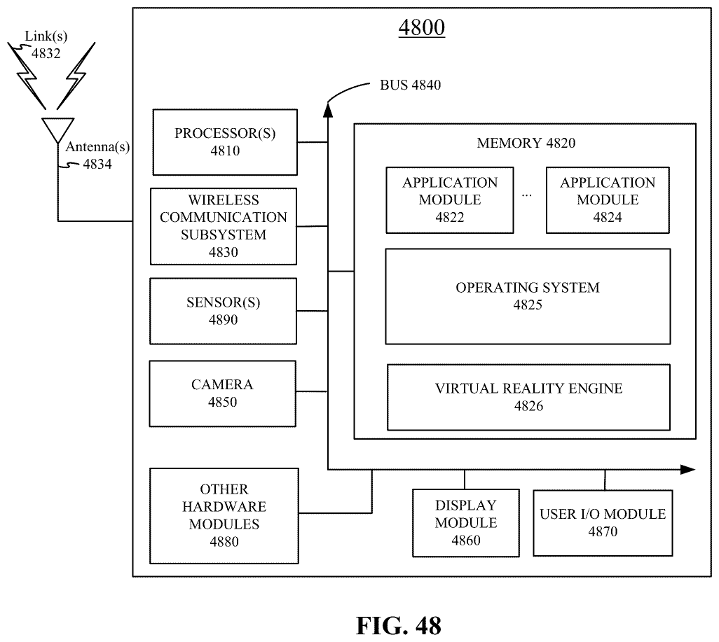

FIG. 48 is a simplified block diagram of an example electronic system 4800 of an example near-eye display (e.g., HMD device) for implementing some of the examples disclosed herein. Electronic system 4800 may be used as the electronic system of an HMD device or other near-eye displays described above. In this example, electronic system 4800 may include one or more processor(s) 4810 and a memory 4820. Processor(s) 4810 may be configured to execute instructions for performing operations at a number of components, and can be, for example, a general-purpose processor or microprocessor suitable for implementation within a portable electronic device. Processor(s) 4810 may be communicatively coupled with a plurality of components within electronic system 4800. To realize this communicative coupling, processor(s) 4810 may communicate with the other illustrated components across a bus 4840. Bus 4840 may be any subsystem adapted to transfer data within electronic system 4800. Bus 4840 may include a plurality of computer buses and additional circuitry to transfer data.

Memory 4820 may be coupled to processor(s) 4810. In some embodiments, memory 4820 may offer both short-term and long-term storage and may be divided into several units. Memory 4820 may be volatile, such as static random access memory (SRAM) and/or dynamic random access memory (DRAM) and/or non-volatile, such as read-only memory (ROM), flash memory, and the like. Furthermore, memory 4820 may include removable storage devices, such as secure digital (SD) cards. Memory 4820 may provide storage of computer-readable instructions, data structures, program modules, and other data for electronic system 4800.

In some embodiments, memory 4820 may store a plurality of application modules 4822 through 4824, which may include any number of applications. Examples of applications may include gaming applications, conferencing applications, video playback applications, or other suitable applications. The applications may include a depth sensing function or eye tracking function. Application modules 4822-4824 may include particular instructions to be executed by processor(s) 4810. In some embodiments, certain applications or parts of application modules 4822-4824 may be executable by other hardware modules 4880. In certain embodiments, memory 4820 may additionally include secure memory, which may include additional security controls to prevent copying or other unauthorized access to secure information.

In some embodiments, memory 4820 may include an operating system 4825 loaded therein. Operating system 4825 may be operable to initiate the execution of the instructions provided by application modules 4822-4824 and/or manage other hardware modules 4880 as well as interfaces with a wireless communication subsystem 4830 which may include one or more wireless transceivers. Operating system 4825 may be adapted to perform other operations across the components of electronic system 4800 including threading, resource management, data storage control and other similar functionality.

Wireless communication subsystem 4830 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 4800 may include one or more antennas 4834 for wireless communication as part of wireless communication subsystem 4830 or as a separate component coupled to any portion of the system. Depending on desired functionality, wireless communication subsystem 4830 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 4830 may permit data to be exchanged with a network, other computer systems, and/or any other devices described herein. Wireless communication subsystem 4830 may include a means for transmitting or receiving data, such as identifiers of HMD devices, position data, a geographic map, a heat map, photos, or videos, using antenna(s) 4834 and wireless link(s) 4832.

Embodiments of electronic system 4800 may also include one or more sensors 4890. Sensor(s) 4890 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor.

Electronic system 4800 may include a display module 4860. Display module 4860 may be a near-eye display, and may graphically present information, such as images, videos, and various instructions, from electronic system 4800 to a user. Such information may be derived from one or more application modules 4822-4824, virtual reality engine 4826, one or more other hardware modules 4880, a combination thereof, or any other suitable means for resolving graphical content for the user (e.g., by operating system 4825). Display module 4860 may use LCD technology, LED technology (including, for example, OLED, ILED, μ-LED, AMOLED, TOLED, etc.), light emitting polymer display (LPD) technology, or some other display technology.

Electronic system 4800 may include a user input/output module 4870. User input/output module 4870 may allow a user to send action requests to electronic system 4800. An action request may be a request to perform a particular action. For example, an action request may be to start or end an application or to perform a particular action within the application. User input/output module 4870 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 4800. In some embodiments, user input/output module 4870 may provide haptic feedback to the user in accordance with instructions received from electronic system 4800. For example, the haptic feedback may be provided when an action request is received or has been performed.

Electronic system 4800 may include a camera 4850 that may be used to take photos or videos of a user, for example, for tracking the user's eye position. Camera 4850 may also be used to take photos or videos of the environment, for example, for VR, AR, or MR applications. Camera 4850 may include, for example, a complementary metal-oxide-semiconductor (CMOS) image sensor with a few millions or tens of millions of pixels. In some implementations, camera 4850 may include two or more cameras that may be used to capture 3-D images.

In some embodiments, electronic system 4800 may include a plurality of other hardware modules 4880. Each of other hardware modules 4880 may be a physical module within electronic system 4800. While each of other hardware modules 4880 may be permanently configured as a structure, some of other hardware modules 4880 may be temporarily configured to perform specific functions or temporarily activated. Examples of other hardware modules 4880 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 4880 may be implemented in software.

In some embodiments, memory 4820 of electronic system 4800 may also store a virtual reality engine 4826. Virtual reality engine 4826 may execute applications within electronic system 4800 and receive position information, acceleration information, velocity information, predicted future positions, or any combination thereof of the HMD device from the various sensors. In some embodiments, the information received by virtual reality engine 4826 may be used for producing a signal (e.g., display instructions) to display module 4860. For example, if the received information indicates that the user has looked to the left, virtual reality engine 4826 may generate content for the HMD device that mirrors the user's movement in a virtual environment. Additionally, virtual reality engine 4826 may perform an action within an application in response to an action request received from user input/output module 4870 and provide feedback to the user. The provided feedback may be visual, audible, or haptic feedback. In some implementations, processor(s) 4810 may include one or more GPUs that may execute virtual reality engine 4826.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or any combination of A, B, and/or C, such as AB, AC, BC, AA, ABC, AAB, AABBCCC, etc.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A display device comprising a die stack that includes:
a backplane die comprising light-emitting diode (LED) drive circuits,
a first LED die bonded to the backplane die and including micro-LEDs configured to emit light of a first wavelength; and
a second LED die bonded to the first LED die and including micro-LEDs configured to emit light of a second wavelength that is shorter than the first wavelength.

2. The display device of claim 1, wherein the first LED die includes:
p-connectors and n-connectors for electrically connecting the micro-LEDs on the first LED die to the drive circuits on the backplane die; and
p-connectors and n-connectors for electrically connecting the micro-LEDs on the second LED die to the drive circuits on the backplane die.

3. The display device of claim 2, wherein the p-connectors for electrically connecting the micro-LEDs on the first LED die to the drive circuits on the backplane die and the p-connectors for electrically connecting the micro-LEDs on the second LED die to the drive circuits on the backplane die are shared in the first LED die.

4. The display device of claim 2, wherein the n-connectors for electrically connecting the micro-LEDs on the first LED die to the drive circuits on the backplane die and the n-connectors for electrically connecting the micro-LEDs on the second LED die to the drive circuits on the backplane die are shared in the first LED die.

5. The display device of claim 1, wherein:
the micro-LEDs on the first LED die are configured to emit red light; and
the micro-LEDs on the second LED die are configured to emit green or blue light.

6. The display device of claim 1, wherein each micro-LED of the micro-LEDs on the second LED die is aligned with a respective micro-LED of the micro-LEDs on the first LED die to form a pixel of the display device.

7. The display device of claim 1, wherein the die stack further comprises a third LED die bonded to the second LED die and including micro-LEDs configured to emit light of a third wavelength that is shorter than the second wavelength.

8. The display device of claim 7, wherein the second LED die includes:
p-connectors and n-connectors for electrically connecting the micro-LEDs on the second LED die to the drive circuits on the backplane die through the first LED die; and
p-connectors and n-connectors for electrically connecting the micro-LEDs on the third LED die to the drive circuits on the backplane die through the first LED die.

9. The display device of claim 8, wherein the p-connectors for electrically connecting the micro-LEDs on the second LED die to the drive circuits on the backplane die and the p-connectors for electrically connecting the micro-LEDs on the third LED die to the drive circuits on the backplane die are shared in the second LED die.

10. The display device of claim 7, wherein each micro-LED of the micro-LEDs on the third LED die is aligned with a respective micro-LED of the micro-LEDs on the second LED die and a respective micro-LED of the micro-LEDs on the first LED die form a pixel of the display device that includes three subpixels.

11. The display device of claim 1, wherein the first LED die is bonded to the backplane die by hybrid bonding.

12. The display device of claim 1, wherein the second LED die is bonded to the first LED die by hybrid bonding.

13. The display device of claim 1, wherein active regions of the micro-LEDs on the first LED dies include a first semiconductor material different from a second semiconductor material of the active regions of the micro-LEDs on the second LED dies.

14. The display device of claim 1, wherein the LED drive circuits include complementary metal-oxide-semiconductor (CMOS) circuits.

15. The display device of claim 1, further comprising an array of micro-lenses above the second LED die.

16. The display device of claim 15, wherein each micro-lens of the array of micro-lenses is on a respective micro-LED of the micro-LEDs on the second LED die and a respective micro-LED of the micro-LEDs on the first LED die.

17. The display device of claim 1, wherein a lateral size of each micro-LED of the micro-LEDs on the first LED die and the micro-LEDs on the second LED die is less than 5 μm.

18. A method of fabricating a display micro-light emitting diode (micro-LED) device, the method comprising:
bonding a first light emitting diode (LED) wafer to a backplane wafer by hybrid bonding, the first LED wafer including micro-LEDs configured to emit light of a first wavelength;
bonding a first dielectric material layer at a surface of the first LED wafer to a second dielectric material layer at a surface of a second LED wafer at room temperature, the second LED wafer including micro-LEDs configured to emit light of a second wavelength that is shorter than the first wavelength; and
bonding metal contacts at the surface of the first LED wafer to metal contacts at the surface of the second LED wafer using a laser beam.

19. The method of claim 18, wherein the laser beam includes a focused laser beam illuminating the metal contacts at a localized area.

20. The method of claim 18, wherein the laser beam illuminates the metal contacts at a localized area from a surface-normal direction or at a tilted angle.
